(19) United States
(12) Patent Application Publication
(10) Pub. No.: US 2015/0061942 A1
(43) Pub. Date: Mar. 5, 2015

(54) TRANSLUCENT CONDUCTIVE PATTERNED MEMBER, AND TRANSLUCENT ELECTROMAGNETIC SHIELD - ANTENNA MEMBER USING SAME

(71) Applicant: Konica Minolta, Inc., Tokyo (JP)

(72) Inventor: Hirokazu Koyama, Tokyo (JP)

(21) Appl. No.: 14/394,922

(22) PCT Filed: Apr. 5, 2013
(86) PCT No.: PCT/JP2013/060535

§ 371 Date: Oct. 16, 2014

(30) Foreign Application Priority Data
Apr. 18, 2012 (JP) 2012-094984

(51) Int. Cl. H05K 9/00; H05K 1/02; H05K 3/14; H05K 1/09; H05K 3/06; H01Q 1/36; H05K 1/03

(52) U.S. Cl. CPC H05K 9/0094; H01Q 1/364; H05K 1/0274; H05K 1/0346; H05K 1/097; H05K 3/06; H05K 3/146; H05K 3/143
USPC 343/700 MS; 174/255; 174/253; 174/392; 427/96.8; 216/13

(57) ABSTRACT

Provided is a translucent conductive patterned member in which, as the metal pattern portion itself has a translucency, the metal pattern portion is hardly visible, and scattering caused by a moiré or diffraction is reduced, and in which it is also provided with sufficient conductivity.

The translucent conductive patterned member is provided with a base layer formed by using a compound containing a nitrogen atom and a conductive pattern portion having a translucency in which the conductive pattern portion is formed on at least one part of the base layer by using silver or an alloy containing silver as a main component.

### TECHNICAL FIELD

The present invention relates to a translucent conductive patterned member in which the conductive portion itself has a translucency, a method for manufacturing the same, and also a translucent electromagnetic shield member, a translucent frequency selective electromagnetic shield member, a translucent antenna member, and a touch panel using the same.

### BACKGROUND ART

A translucent conductive patterned member is used for electromagnetic shielding of a plasma display panel, for example.

Further, in accordance with ever-widening wireless environment in recent years, to maintain security of wireless data or maintain communication quality like then to prevent interference when plural IC tags are used, attempts have been made like adding an electromagnetic shielding function to a glass pane or transparent partition plate between registers for handling a commercial product attached with an IC tag or lanes for identifying a commercial product. By a simple shielding, however, electromagnetic wave from cellular phones or public wireless system is also shielded, and thus frequency selective surface (FSS) allowing frequency-selective electromagnetic shielding receives attention. Characteristic of FSS lies in that an independent pattern having conductivity depending on the frequency of electromagnetic wave to be shielded is formed on a substrate surface. Because those patterns are not continuously in contact in a plane, the surface resistance is high but each pattern itself requires high conductivity to reflect electromagnetic wave.

The translucent conductive patterned member can be also used as a transparent receiver antenna of a television, a radio, or wireless LAN, and it is possible to add a transparent receiver antenna to a glass pane, for example. It is also possible that, by applying a translucent conductive patterned member to an antenna of a contactless IC card or a transmitter and receiver antenna of a wireless tag, an antenna is provided on a surface of an IC card or a transparent wireless tag is manufactured.

For such translucent conductive patterned member, translucent conductive members formed by following methods are known: a method for physical development or plating after forming a silver core in a pattern according to application of a relating to photosensitive materials of silver halide photography technique (Patent Literature 1), a method of coating ink containing a palladium catalyst to have a pattern by a printing method such as inkjet or screen followed by electroless plating (Patent Literature 2), a method of electroless plating on a coating film containing conductive polymers that are formed in a pattern (Patent Literature 3), and also a translucent conductive patterned member formed by a method for manufacturing a thin metal film in a pattern by photolithography.

However, in the metal patterned member manufactured by plating or photolithography, a portion without the metal pattern has a translucency and the metal pattern portion itself has no translucency. As such, the metal pattern portion is thinned. Nevertheless, the pattern portion is still visible or, depending on pattern, light diffraction occurs in the pattern portion then external light is strongly scattered in selective direction or a moiré occurs. Further, when the metal portion is thinned to the level at which the metal pattern itself transmits light, conductivity is not exhibited.

As a method of exhibiting conductivity of a metal portion while maintaining translucency of the metal portion based on metal thinning, an electromagnetic shield member in which ITO/silver/ITO are laminated is known (Patent Literature 4).

### CITATION LIST

### Patent Literature

Patent Literature 1: Japanese Patent Application Laid-Open No. 2008-277675
Patent Literature 2: Japanese Patent Application Laid-Open No. 11-170420
Patent Literature 3: Japanese Patent Application Laid-Open No. 2009-16496
Patent Literature 4: Japanese Patent Application Laid-Open No. 2005-277228

### SUMMARY OF INVENTION

### Technical Problem

However, since indium as a rare metal is used, ITO has high material cost and, to lower the resistance, it needs to be subjected to an annealing treatment at 300° C. or so after forming a film. As such, large scale facilities for high temperature annealing or energy for the treatment is required. Further, it cannot be applied to a common film base material, which doesn't have heat resistance. Even with constitution including laminating ITO/silver/ITO, it remains difficult to achieve both sufficient conductivity and translucency.

Accordingly, an object of the present invention is to provide a translucent conductive patterned member, which has a hardly visible metal pattern portion, and has reduced scattering by moiré (interference fringe) or diffraction and also sufficient conductivity, by making the metal pattern portion itself translucent, and a translucent electromagnetic shield member, a translucent frequency selective electromagnetic shield member, a translucent antenna member, and a touch panel, which improve performance by using the translucent conductive patterned member.

### Solution to Problem

The aforementioned object of the present invention is achieved by the following constitutions.

Specifically, the present invention is achieved by a translucent conductive patterned member including a base layer formed by using a compound containing a nitrogen atom and a conductive pattern portion having a translucency formed on at least one part of the base layer by using silver or an alloy containing silver as a main component.

The present invention is also achieved by a method for manufacturing a translucent conductive patterned member including a base layer formed by using a compound containing a nitrogen atom and a conductive pattern portion having a translucency formed on at least one part of the base layer by using silver or an alloy containing silver as a main component, wherein the silver or alloy layer containing silver as a main component, which is formed on the base layer, is formed as a conductive pattern portion based on vapor deposition method using a mask with formed pattern.

The present invention is also achieved by a translucent electromagnetic shield member, a translucent frequency selective electromagnetic shield member, and a translucent antenna member, wherein they are obtained by using the translucent conductive patterned member described above.

The translucent conductive patterned member of the present invention which is formed as described has a constitution that a conductive pattern portion having a translucency, in which silver or an alloy containing silver as a main component is used, is provided on at least a part of a base layer that is formed by using a compound containing a nitrogen atom.

When it is tried to form a thin silver film layer, the film generally grows in nucleus growth mode (Volmer Weber; VW mode), and thus a group of fine silver portions that are isolated in an island-like is yielded. Thus, the fine silver portions have a film thickness thicker than expected, and they have a significantly reduced optical transparency. As each of the fine silver portions remains in an isolated state, the conductive pattern portion does not exhibit conductivity. For exhibiting the conductivity, it is necessary to grow the silver until the fine silver portions that are isolated in an island-like are connected to each other. However, when the silver is grown to that level, the transmittance of the silver layer itself is more significantly lowered.

According to the present invention, silver atoms forming the conductive pattern portion interact with a compound containing a nitrogen atom which forms the base layer, when a conductive pattern portion is formed as a film on top of the base layer, and thus the diffusion distance of the silver atoms on a surface of the base layer is reduced, yielding suppressed silver aggregation. As such, the silver layer is formed as a film according to film growth of monolayer growth mode (Frank-van der Merwe: FW mode). Accordingly, a conductive pattern portion having thin but even film thickness can be obtained. As a result, a conductive pattern portion with reduced film thickness, which has an optical transparency and yet secures conductivity, can be manufactured.

### BRIEF DESCRIPTION OF DRAWINGS

FIG. 1A is a planar schematic diagram illustrating the constitution of one embodiment of a translucent conductive patterned member of the present invention. FIG. 1B is a cross-sectional schematic diagram along the line 1B-1B of FIG. 1A.

FIG. 2A is a cross-sectional schematic diagram illustrating the constitution of another embodiment of a translucent conductive patterned member of the present invention. FIG. 2B is a cross-sectional schematic diagram illustrating transferring of the translucent conductive patterned member of FIG. 2A to a substrate body side (mating side) by adhesion and peeling of a base material having a releasing property.

FIGS. 3A to 3C are diagrams illustrating several exemplary shapes of the conductive pattern portion. Among the several shapes, FIG. 3A is a diagram illustrating a conductive pattern in a linear shape. FIG. 3B is a diagram illustrating a conductive pattern in a triangular shape among mesh-shaped patterns. FIG. 3C is a diagram illustrating a conductive pattern in a circular shape.

FIG. 4 illustrates an antenna pattern with an open end, which is given as an example of a conductive pattern portion.

FIG. 5 is a perspective view illustrating an outline constitution of the touch panel 21 in which the translucent conductive patterned member of the embodiment of the present invention is used as the transparent electrodes 1-1 and 1-2 for a touch panel.

FIG. 6 is a planar view of two pieces of the transparent electrode 1-1 and 1-2 (a translucent conductive patterned member of the embodiment of the present invention), which illustrates the electrode configuration of the touch panel 21.

FIG. 7 is a planar view of the transparent electrodes 1-1 and 1-2 (a translucent conductive patterned member of the embodiment of the present invention), in which a diamond-like pattern portion being a constituent of each y electrode pattern 5y1, 5y2, . . . is arranged at a non-overlapping position when viewed from the plane of a diamond-like pattern portion being a constituent of x electrode pattern 5x1, 5x2, . . . so that the diamond-like pattern portion can occupy as much area as possible in the range of not allowing any overlap.

FIG. 8 is a cross-sectional view illustrating an outline constitution of the touch panel 21 in which the translucent conductive patterned member of the embodiment of the present invention is used as the transparent electrodes 1-1 and 1-2 for a touch panel.

FIG. 9 is a planar schematic diagram illustrating a mesh-shaped conductive pattern portion including silver of Sample 101, which is formed on top of abase layer including TPD formed on top of PET base by using an aluminum mask pattern, and a solid portion including silver, which is formed for evaluation.

FIG. 10A is a planar schematic diagram for describing L/S of the mesh-shaped (lattice-shaped) pattern portion. FIG. 10B is a cross-sectional schematic diagram of FIG. 10A (after plating) along the line 10B-10B for illustrating the constitution of the pattern portion of Comparative Sample 205.

FIG. 11 is a schematic diagram illustrating the arrangement of an apparatus for evaluation of attenuation rate.

### DESCRIPTION OF EMBODIMENTS

Hereinbelow, preferred embodiments of the present invention are described.

<Translucent Conductive Patterned Member>

The translucent conductive patterned member according to one embodiment of the present invention is characterized in that it comprises a base layer formed by using a compound containing a nitrogen atom and a conductive pattern portion having a translucency formed on at least one part of the base layer by using silver or an alloy containing silver as a main component. By having the translucent conductive patterned member with the aforementioned constitution, not only the metal pattern portion itself in the translucent conductive patterned member can have an optical transparency but also it has the conductivity of the metal pattern portion at once. It is also possible to improve the performance of a translucent electromagnetic shield member, a translucent frequency selective electromagnetic shield member, or a translucent antenna member in which the translucent conductive patterned member is used.

Hereinbelow, the embodiments of the present invention are described in view of the drawings attached hereto. Meanwhile, for explanation of the drawings, the same element is given with the same symbol so as to omit the overlapped explanations. The size ratio in the drawings is exaggerated for the sake of explanation and may be different from the actual ratio.

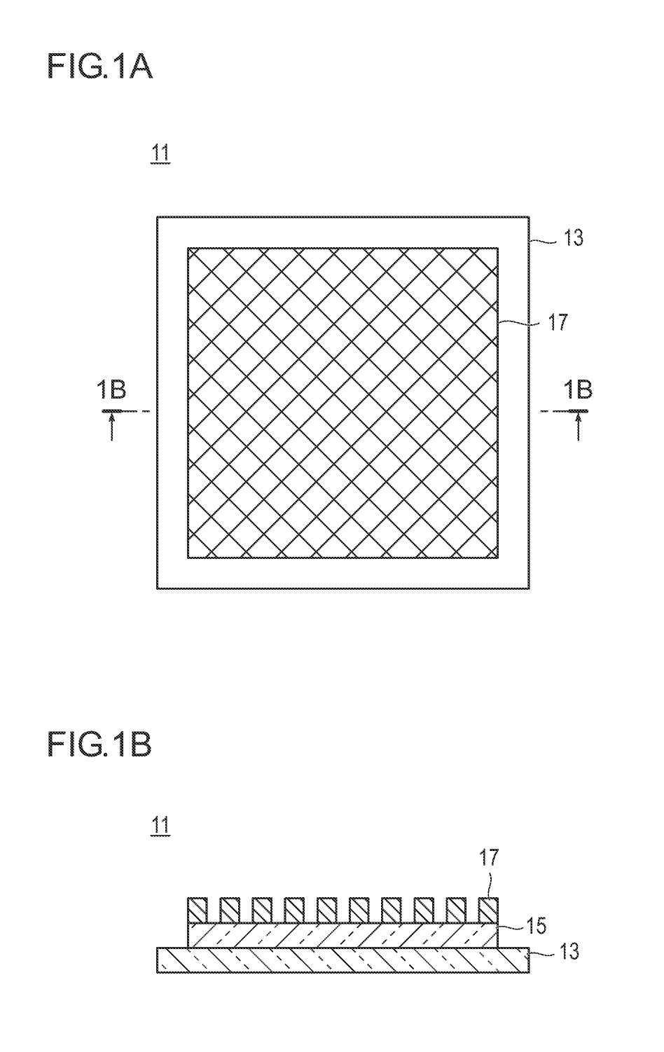

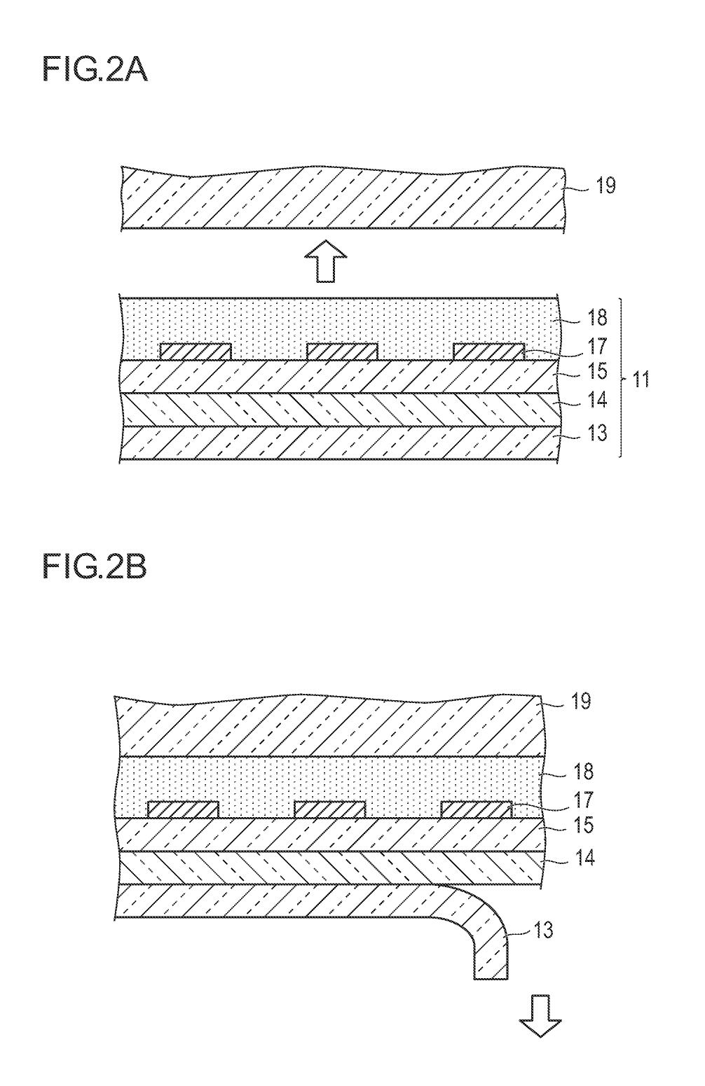

FIG. 1A is a planar schematic diagram illustrating the constitution of one embodiment of a translucent conductive patterned member of the present invention. FIG. 1B is a cross-sectional schematic diagram along the line 1B-1B of FIG. 1A. FIG. 2A is a cross-sectional schematic diagram illustrating the constitution of another embodiment of a translucent conductive patterned member of the present invention. FIG. 2B is a cross-sectional schematic diagram illustrating transferring of the translucent conductive patterned member of FIG. 2A to a substrate body side (mating side) by adhesion and peeling of a base material having a releasing property. As illustrated in FIGS. 1A and 1B, the translucent conductive patterned member 11 has a structure in which the base layer 15 and the conductive pattern portion 17 having a translucency, which is formed as a film on at least part of the top of the base layer, are laminated, and the base layer 15 and the conductive pattern portion 17 having a translucency are provided in the order on top of the base 13, for example. Among them, the base layer 15 is a layer formed by using a compound containing a nitrogen atom, and the conductive pattern portion 17 having a translucency is a layer formed by using silver or an alloy having silver as a main component. As illustrated in FIGS. 2A and 2B, the translucent conductive patterned member 11 may also have a constitution in which, on top of the base 13 having a releasing property, the protective layer 14, the base layer 15, the conductive pattern portion 17 having a translucency, and the adhesive layer 18 are provided in the order, then, used after transferring on a suitable substrate body 19 (transfer object, such as, glass pane or rear glass of a vehicle). It is preferable for all of the base 13, the protective layer 14, the base layer 15, the conductive pattern portion 17 having a translucency, the adhesive layer 18, and the substrate body 19 to have a high optical transparency.

Next, explanations are given with regard to the detailed constitution of the base 13, the base layer 15, and the conductive pattern portion 17 in the order, which are used for the translucent conductive patterned member 11.

(Base)

For the translucent conductive patterned member 11 of the present invention, the base 13 is preferably used. The base 13 is a transparent base. The transparent base is not particularly limited when it has a high optical transparency. For example, a transparent resin film or glass can be used. However, it is more preferably a transparent resin film from the viewpoint of flexibility or the like. Since a high temperature treatment for laminating ITO/silver/ITO is not required in the present invention, it can be preferably used.

The transparent resin film is not particularly limited, and any one can be suitably selected from well-known ones in terms of the material, shape, structure, and thickness. Examples thereof include a biaxially stretched polyester film such as polyethylene terephthalate (PET), polyethylene naphthalate, or modified polyester, a polyolefin resin film such as polyethylene (PE) resin film, polypropylene (PP) resin film, polystyrene resin film, or cyclic olefin resin, a vinyl resin film such as polyvinyl chloride or polyvinylidene chloride, polyether ether ketone (PEEK) resin film, polysulfone (PSF) resin film, polyether sulfone (PES) resin film, polycarbonate (PC) resin film, polyamide resin film, polyimide resin film, acrylic resin film, and triacetyl cellulose (TAC) resin film, or the like.

<Base Layer>

The base layer 15 is a layer which is formed by using a compound containing a nitrogen atom. When the base layer 15 is formed as a film on top of the base 13, examples of the method forming a film include a method of using wet process such as application method, inkjet method, coating method, or dipping method and a method of using dry process such as a vapor deposition method (resistance heating, electronic beam vapor deposition (EB method) or the like), sputtering method, or chemical vapor deposition method (CVD method). Among them, vapor deposition method is preferably used.

Thickness of the base layer 15 is not critical as long as the effect of the present invention is exhibited. Preferably, it is required to be 0.1 nm or more (one molecular film or more). Although the upper limit of the base layer 15 is not particularly limited, it is preferably 1 μm or less, and more preferably 100 nm or less. When the thickness of the base layer 15 is 0.1 nm or more (one molecular film or more), the silver atoms forming the conductive pattern portion interact with the compound containing a nitrogen atom forming the base layer so that the diffusion distance of the silver atoms on a surface of the base layer is reduced, and as a result, silver aggregation is suppressed. Accordingly, the silver layer grows as a film based on film growth of monolayer growth mode (FW mode). When the thickness of the base layer 15 is 1 μm or less, the aforementioned effect can be exhibited without inhibiting the high translucency.

The compound containing a nitrogen atom to form the base layer 15 is not particularly limited when it is a compound containing a nitrogen atom in the molecule. However, it is preferably a compound having a heterocycle in which nitrogen atom is contained as a hetero atom. Examples of the heterocycle in which nitrogen atom is contained as a hetero atom include aziridine, azirine, azetidine, azet, azolidone, azole, azinane, pyridine, azepane, azepine, imidazole, pyrazole, oxazole, thiazole, imidazoline, pyrazine, morpholine, thiazine, indole, isoindole, benzimidazole, purine, quinoline, isoquinoline, quinoxaline, cinnoline, phteridine, acridine, carbazole, benzo-C-cinnoline, porphyrin, chlorine, and choline, or the like. Among them, a compound having a pyridine ring is preferable. The heterocycle in which nitrogen atom is contained as a hetero atom is preferably included at a terminal of the compound.

Examples of the particularly preferred heterocycle in which nitrogen atom is contained as a hetero atom include the compounds represented by the following General Formulas (1) to (3).

[General Formula (1)]

(Ar1)n1-Y1 General Formula (1)

In the formula of General Formula (1), n1 is an integer of 1 or more, Y1 represents a substituent group when n1 is 1 or a simple bonding arm or a linking group of valency of n1 when n1 is 2 or more. Ar1 represents a group represented by General Formula (A) to be described below, and when n1 is 2 more, plural Ar1 may be the same or different from each other. Meanwhile, the compound represented by General Formula (1) has, in the molecule, at least two condensed aromatic heterocycles that are formed by condensation of three or more rings.

Examples of the substituent group represented by Y1 in General Formula (1) include an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, a pentadecyl group or the like), a cycloalkyl group (for example, a cyclopentyl group, a cyclohexyl group or the like), an alkenyl group (for example, a vinyl group, an allyl group or the like), an alkynyl group (for example, an ethynyl group, a propargyl group or the like), an aromatic hydrocarbon group (also referred to as an aromatic carbocycle group or an aryl group or the like, and examples thereof include a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, and a biphenylyl group), an aromatic heterocycle group (for example, a furyl group, a thienyl group, a pyridyl group, a pyridazinyl group, a pyrimidinyl group, a pyrazinyl group, a triazinyl group, an imidazolyl group, a pyrazolyl group, a thiazolyl group, a quinazolinyl group, a carbazolyl group, a carbolinyl group, a diazacarbazolyl group (a carbolinyl group in which any one carbon atom constituting the carboline ring is substituted with a nitrogen atom), a phthalazinyl group or the like), a heterocycle group (for example, a pyrrolidyl group, an imidazolyl group, a morpholyl group, an oxazolidyl group or the like), an alkoxy group (for example, a methoxy group, an ethoxy group, a propyloxy group, a pentyloxy group, a hexyloxy group, an octyloxy group, a dodecyloxy group or the like), a cycloalkoxy group (for example, a cyclopentyloxy group, a cyclohexyloxy group or the like), an aryloxy group (for example, a phenoxy group, a naphthyloxy group or the like), an alkylthio group (for example, a methylthio group, an ethylthio group, a propylthio group, a pentylthio group, a hexylthio group, an octylthio group, a dodecylthio group or the like), a cycloalkylthio group (for example, a cyclopentylthio group, a cyclohexylthio group or the like), an arylthio group (for example, a phenylthio group, a naphthylthio group or the like), an alkoxycarbonyl group (for example, a methyloxycarbonyl group, an ethyloxycarbonyl group, a butyloxycarbonyl group, an octyloxycarbonyl group, a dodecyloxycarbonyl group or the like), an aryloxycarbonyl group (for example, a phenyloxycarbonyl group, a naphthyloxycarbonyl group or the like), a sulfamoxyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, a 2-pyridylaminosulfonyl group or the like), an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, a pyridylcarbonyl group or the like), an acyloxy group (for example, an acetyloxy group, an ethylcarbonyloxy group, a butylcarbonyloxy group, an octylcarbonyloxy group, a dodecylcarbonyloxy group, a phenylcarbonyloxy group or the like), an amide group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, a naphthylcarbonylamino group or the like), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, a 2-pyridylaminocarbonyl group or the like), an ureido group (for example, a methylureido group, an ethylureido group, a pentylureido group, a cyclohexylureido group, an octylureido group, a dodecylureido group, a phenylureido group, a naphthylureido group, a 2-pyridylaminoureido group or the like), a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, a 2-pyridylsulfinyl group or the like), an alkylsulfonyl group (for example, a methylsulfonyl group, an ethylsulfonyl group, a butylsulfonyl group, a cyclohexylsulfonyl group, a 2-ethylhexylsulfonyl group, a dodecylsulfonyl group or the like), an aryl sulfonyl group or a heteroarylsulfonyl group (for example, a phenylsulfonyl group, a naphthylsulfonyl group, a 2-pyridylsulfonyl group or the like), an amino group (for example, an amino group, an ethylamino group, a dimethylamino group, a butylamino group, a cyclopentylamino group, a 2-ethylhexylamino group, a dodecylamino group, an anilino group, a naphthylamino group, a 2-pyridylamino group, a piperidyl group (also referred to as a piperidinyl group), a 2,2,6,6-tetramethylpiperidinyl group or the like), a halogen atom (for example, a fluorine atom, a chlorine atom, and a bromine atom), a fluorohydrocarbon group (for example, a fluoromethyl group, a trifluoromethyl group, a pentafluoroethyl group, a pentafluorophenyl group or the like), a cyano group, a nitro group, a hydroxy group, a mercapto group, a silyl group (for example, a trimethylsilyl group, a triisopropylsilyl group, a triphenylsilyl group, a phenyldiethylsilyl group or the like), a phosphoric acid ester group (for example, a dihexylphosphoryl group or the like), a phosphorus acid ester group (for example, diphenylphospinyl group or the like), a phosphono group or the like.

Those substituent groups may be further substituted with the aforementioned substituent group. Further, those substituent groups may forma ring by binding among plural substituent groups.

Specific examples of the linking group with valency of n1 as represented by Y1 in General Formula (1) include a divalent linking group, a trivalent linking group, and a tetravalent linking group.

Examples of the divalent linking group which is represented by Y1 in General Formula (1) include an alkylene group (for example, an ethylene group, a trimethylene group, a tetramethylene group, a propylene group, an ethylethylene group, a pentamethylene group, a hexamethylene group, a 2,2,4-trimethylhexamethylene group, a heptamethylene group, an octamethylene group, a nonamethylene group, a decamethylene group, a undecamethylene group, a dodecamethylene group, a cyclohexylene group (for example, a 1,6-cyclohexanediyl group or the like), a cyclopentylene group (for example, a 1,5-cyclopentanediyl group or the like)), an alkenylene group (for example, a vinylene group, a propenylene group, a butenylene group, a pentenylene group, a 1-methylvinylene group, a 1-methylpropenylene group, a 2-methylpropenylene group, a 1-methylpentenylene group, a 3-methylpentenylene group, a 1-ethylvinylene group, a 1-ethylpropenylene group, a 1-ethylbutenylene group, a 3-ethylbutenylene group or the like), an alkynylene group (for example, an ethynylene group, a 1-propynylene group, a 1-butynylene group, a 1-pentynylene group, a 1-hexynylene group, a 2-butynylene group, a 2-pentynylene group, a 1-methylethynylene group, a 3-methyl-1-propynylene group, a 3-methyl-1-butynylene group or the like), an arylene group (for example, an o-phenylene group, a p-phenylene group, a naphthalenediyl group, an anthracenediyl group, a naphthacenediyl group, a pyrenediyl group, a naphthyl naphthalenediyl group, a biphenyldiyl group (for example, a [1,1′-biphenyl]-4,4′-diyl group, a 3,3′-biphenyldiyl group, a 3,6-biphenyldiyl group or the like), terpenyldiyl group, a quaterpenyldiyl group, a quincphenyldiyl group, a sexyphenyldiyl group, a septyphenyldiyl group, an octyphenyldiyl group, a nobiphenyldiyl group, a deciphenyldiyl group or the like), a heteroarylene group (for example, a divalent group or the like derived from a group including a carbazole ring, a carboline ring, a diazacarbazole ring (also referred to as a monoazacarboline ring, which represents a ring configuration in which one carbon atom constituting the carboline ring is substituted with a nitrogen atom), a triazole ring, a pyrrole ring, a pyridine ring, a pyrazine ring, a quinoxaline ring, a thiophene ring, an osadiazole ring, a dibenzofuran ring, a dibensothiophene ring, and an indole ring), a chalcogenide atom such as oxygen or sulfur, a group derived from a condensed aromatic heterocycle obtained by condensation of three or more rings (herein, the condensed aromatic heterocycle obtained by condensation of three or more rings is preferably an aromatic hetero condensed ring containing a hetero atom selected from N, O, and S as an element for constituting the condensed ring, and specific examples thereof include an acridine ring, a benzoquinoline ring, a carbazole ring, a phenazine ring, a phenanthridine ring, a phenanthroline ring, a carboline ring, a cyclazine ring, a quindoline ring, a terpenidine ring, a quinindoline ring, a triphenodithiazine ring, a triphenodioxazine ring, a phenantrazine ring, an anthrazine ring, a perimidine ring, a diazacarbazole ring (which represents a carboline ring of which any one carbon atom constituting the carboline ring is substituted with a nitrogen atom), a phenanthroline ring, a dibenzofuran ring, a dibenzothiophene ring, a naphthafuran ring, a naphthothiophene ring, a benzodifuran ring, a benzodithiophene ring, a naphthodifuran ring, a naphthodithiophene ring, an anthrafuran ring, an anthradifuran ring, an anthrathiophene ring, an anthradithiophene ring, a thianthrene ring, a phenoxazine ring, and a thiophanethrene ring (naphthothiophene ring) or the like).

Examples of the trivalent linking group which is represented by Y1 in General Formula (1) include an ethanetriyl group, a propanetriyl group, a butanetriyl group, a pentanetriyl group, a hexanetriyl group, a heptanetriyl group, an octanetriyl group, a nonanetriyl group, a decanetriyl group, a undecanetriyl group, a dodecanetriyl group, a cyclohexanetriyl group, a cyclopentanetriyl group, a benzenetriyl group, a naphthalenetriyl group, a pyridinetriyl group, and a carbazoletriyl group, or the like.

The tetravalent linking group which is represented by Y1 in General Formula (1) is the aforementioned trivalent group added with one more binding group, and examples thereof include a propane diylidene group, a 1,3-propanediyl-2-ylidene group, a butane diylidene group, a pentane diylidene group, a hexane diylidene group, a heptane diylidene group, an octane diylidene group, a nonane diylidene group, a decane diylidene group, a undecane diylidene group, a dodecane diylidene group, a cyclohexane diylidene group, a cyclopentane diylidene group, a benzene tetrayl group, a naphthalene tetrayl group, a pyridine tetrayl group, and a carbazole tetrayl group.

Meanwhile, each of the divalent linking group, trivalent linking group, and tetravalent linking group described above may also have a substituent group represented by Y1 in General Formula (1).

According to a preferred embodiment of the compound represented by General Formula (1), Y1 represents a group derived from a condensed aromatic heterocycle which is obtained by condensation of three or more rings. As for the condensed aromatic heterocycle which is obtained by condensation of three or more rings, a dibenzo furan ring or a dibenzothiophene ring is preferable. n1 is preferably 2 or more.

The compound represented by General Formula (1) has, in the molecule, at least two condensed aromatic heterocycles which are obtained by condensation of three or more rings.

Further, when Y1 represents a linking group with valency of n1, Y1 is preferably non-conjugated so that the compound represented by General Formula (1) can maintain the triplet excitation energy at high level, and also Y1 is preferably composed of an aromatic ring (aromatic hydrocarbon ring+aromatic heterocycle) from the viewpoint of increasing Tg (also referred to as glass transition point or glass transition temperature).

As described herein, the “non-conjugated” means a case in which the linking group cannot be described as a repetition of a single bond (also referred to as a mono bond) and a double bond, or, conjugation between aromatic rings for constituting the linking group is sterically cleaved.

[Group Represented by General Formula (A)]

Ar1 in General Formula (1) indicates the group represented by the following General Formula (A).

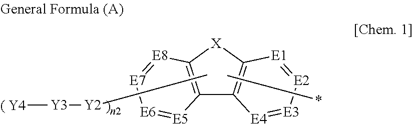

In the formula, X represents —N(R)—, —O—, —S—, or —Si(R)(R′)—, E1 to E8 represent —C(R1)= or —N═, and R, R′ and R1 represent hydrogen atom, a substituent group, or a linking site to Y1. * represents a linking site to Y1. Y2 represents a simple bonding arm or a divalent linking group. Each of Y3 and Y4 represents a group derived from a 5-membered or 6-membered aromatic ring, in which at least one of Y3 and Y4 represents a group derived from an aromatic heterocycle containing a nitrogen atom as a ring-constituting atom. n2 represents an integer of from 1 to 4.

Herein, the substituent group represented by R, R′ and R1, respectively, in —N(R)— or —Si(R)(R′)— represented by X and —C(R1)=represented by E1 to E8 in General Formula (A) has the same meaning as the substituent group represented by Y1 in General Formula (1).

Further, the divalent linking group represented by Y2 in General Formula (A) has the same meaning as the divalent linking group which is represented by Y1 in General Formula (1).

Further, examples of the 5-membered or 6-membered aromatic ring which is used for forming a group derived from a 5-membered or 6-membered aromatic ring, which is represented by Y3 and Y4, respectively, in General Formula (A) include a benzene ring, an oxazole ring, a thiophene ring, a furan ring, a pyrrole ring, a pyridine ring, a pyridazine ring, a pyrimidine ring, a pyrazine ring, a diazine ring, a triazine ring, an imidazole ring, an isoxazole ring, a pyrazole ring, and a triazole ring, or the like.

Further, at least one of the groups derived from a 5-membered or 6-membered aromatic ring, which is represented by Y3 and Y4, represents a group derived from an aromatic heterocycle which contains a nitrogen atom as a constituent atom of the ring, and examples of the aromatic heterocycle which contains a nitrogen atom as a constituent atom of the ring include an oxazole ring, a pyrrole ring, a pyridine ring, a pyridazine ring, a pyrimidine ring, a pyrazine ring, a diazine ring, a triazine ring, an imidazole ring, an isoxazole ring, a pyrazole ring, and a triazole ring, or the like.

(Preferred Embodiment of Group Represented by Y3)

The group represented by Y3 in General Formula (A) is preferably a group which is derived from the aforementioned 6-membered aromatic ring, and Y3 is more preferably a group derived from a benzene ring.

(Preferred Embodiment of Group Represented by Y4)

The group represented by Y4 in General Formula (A) is preferably a group which is derived from the aforementioned 6-membered aromatic ring, and it is more preferably a group derived from an aromatic heterocycle which contains a nitrogen atom as a constituent atom of the ring. Particularly preferably, Y4 is a group derived from a pyridine ring.

(Preferred Embodiment of Group Represented by General Formula (A))

Examples of the preferred embodiment of the group represented by General Formula (A) include a group which is represented by any one of the following General Formulas (A-1), (A-2), (A-3) and (A-4).

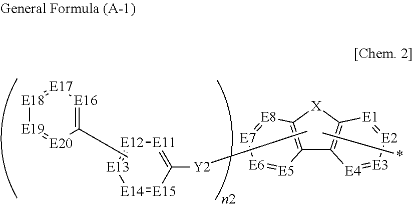

In the formula of General Formula (A-1), X represents —N(R)—, —O—, —S—, or —Si(R)(R′)—, E1 to E8 represent —C(R1)= or —N═, and R, R′ and R1 represent hydrogen atom, a substituent group, or a linking site to Y1. Y2 represents a simple bonding arm or a divalent linking group. E11 to E20 represent —C(R2)= or —N═, and at least one of E11 to E20 represents —N═. R2 represents hydrogen atom, a substituent group, or a linking site. Meanwhile, at least one of E11 and E12 represents —C(R2)= and R2 represents a linking site. n2 represents an integer of from 1 to 4. * represents a linking site to Y1 of General Formula (1).

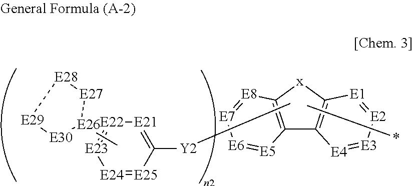

In the formula of General Formula (A-2), X represents —N(R)—, —O—, —S—, or —Si(R)(R′)—, E1 to E8 represent —C(R1)= or —N═, and R, R′ and R1 represent hydrogen atom, a substituent group, or a linking site to Y1. Y2 represents a simple bonding armor a divalent linking group. E21 to E25 represent —C(R2)= or —N═, E26 to E30 represent —C(R2)=, —N═, —O—, —S—, or —Si(R3)(R4)- in which at least one of E21 to E30 represents —N═. R2 represents hydrogen atom, a substituent group, or a linking site. R3 and R4 represent hydrogen atom or a substituent group. Meanwhile, at least one of E21 and E22 represents —C(R2)= and R2 represents a linking site. n2 represents an integer of from 1 to 4. * represents a linking site to Y1 of General Formula (1).

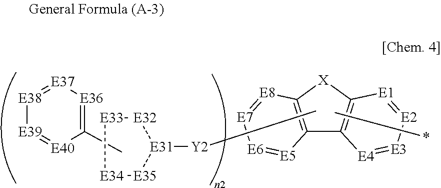

In the formula of General Formula (A-3), X represents —N(R)—, —O—, —S—, or —Si(R)(R′)—, E1 to E8 represent —C(R1)= or —N═, and R, R′ and R1 represent hydrogen atom, a substituent group, or a linking site to Y1. Y2 represents a simple bonding armor a divalent linking group. E31 to E35 represent —C(R2)=, —N═, —O—, —S—, or —Si(R3)(R4)-, E36 to E40 represent —C(R2)= or —N═ in which at least one of E31 to E40 represents —N═. R2 represents hydrogen atom, a substituent group, or a linking site. R3 and R4 represent hydrogen atom or a substituent group. Meanwhile, at least one of E32 and E33 represents —C(R2)= and R2 represents a linking site. n2 represents an integer of from 1 to 4. * represents a linking site to Y1 of General Formula (1).

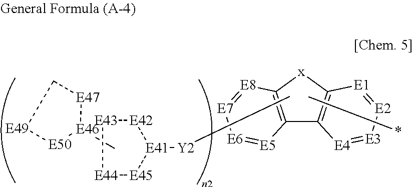

In the formula of General Formula (A-4), X represents —N(R)—, —O—, —S—, or —Si(R)(R′)—, E1 to E8 represent —C(R1)= or —N═, and R, R′ and R1 represent hydrogen atom, a substituent group, or a linking site to Y1. Y2 represents a simple bonding arm or a divalent linking group. E41 to E50 represent —C(R2)=, —N═, —O—, —S—, or —Si(R3)(R4)- in which at least one of E41 to E50 represents —N═. R2 represents hydrogen atom, a substituent group, or a linking site. R3 and R4 represent hydrogen atom or a substituent group. Meanwhile, at least one of E42 and E43 represents —C(R2)= and R2 represents a linking site. n2 represents an integer of from 1 to 4. * represents a linking site to Y1 of General Formula (1).

Hereinbelow, the group represented by any one of General Formulas (A-1) to (A-4) is described.

The substituent group represented by R, R′ and R1, respectively, in —N(R)— or —Si(R)(R′)— represented by any one of X and —C(R1)=represented by E1 to E8 in General Formula (A-1) to (A-4) has the same meaning as the substituent group represented by Y1 in General Formula (1).

With regard to any one of the groups represented by General Formulas (A-1) to (A-4), the divalent linking group represented by Y2 has the same meaning as the divalent linking group represented by Y1 in General Formula (1).

The substituent group represented by R2 of —C(R2)=, which is represented by E11 to E20 of General Formula (A-1), E21 to E30 of General Formula (A-2), E31 to E40 of General Formula (A-3), or E41 to E50 of General Formula (A-4), respectively, has the same meaning as the substituent group represented by Y1 in General Formula (1).

Next, more preferred embodiment of the compound represented by General Formula (1) of the present invention is described.

[Compound Represented by General Formula (2)]

According to the present invention, the compound represented by the following General Formula (2) is preferred among the compounds represented by General Formula (1) described above. Hereinbelow, the compound represented by General Formula (2) is described.

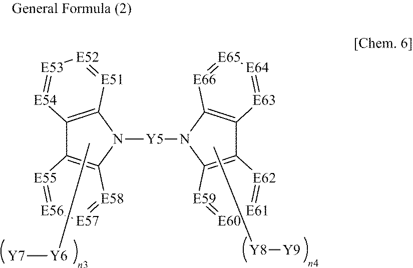

In the formula of General Formula (2), Y5 represents an arylene group, a heteroarylene group, or a divalent linking group including a combination thereof. Each of E51 to E66 represents —C(R3)= or —N═ and R3 represents hydrogen atom or a substituent group. Each of Y6 to Y9 represents a group derived from an aromatic hydrocarbon ring or a group derived from an aromatic heterocycle, and at least one of Y6 and Y7 and at least one of Y8 and Y9 represents a group derived from an aromatic heterocycle containing an N atom. n3 and n4 represent an integer of from 0 to 4, in which n3+n4 is an integer of 2 or more.

The arylene group and heteroarylene group represented by Y5 in General Formula (2) have the same meaning as the arylene group and heteroarylene group that are described as an example of a divalent linking group represented by Y1 in General Formula (1).

As for the preferred embodiment of an arylene group, a heteroarylene group, or a divalent linking group including a combination thereof represented by Y5, it is preferable to contain, among the heteroarylene groups, a group derived from a condensed aromatic heterocycle which is obtained by condensation of three or more rings. As for the group derived from the condensed aromatic heterocycle which is obtained by condensation of three or more rings, a group derived from a dibenzo furan ring or a group derived from a dibenzothiophene ring is preferable.

The substituent group represented by R3 of —C(R3)=, which is represented by each of E51 to E66 of General Formula (2), has the same meaning as the substituent group represented by Y1 in General Formula (1).

With regard to the substituent group represented by E51 to E66 of General Formula (2), respectively, it is preferable that each of 6 or more of E51 to E58 and 6 or more of E59 to E66 is represented by —C(R3)=.

With regard to Y6 to Y9 of General Formula (2), examples of the aromatic hydrocarbon ring used for forming a group each derived from an aromatic hydrocarbon ring include a benzene ring, a biphenyl ring, a naphthalene ring, an azulene ring, an anthracene ring, a phenanthrene ring, a pyrene ring, a chrysene ring, a naphthacene ring, a triphenylene ring, an o-terpenyl ring, a m-terpenyl ring, a p-terpenyl ring, an acenaphthene ring, a coronene ring, a fluorene ring, a fluoranthrene ring, a naphthacene ring, a pentacene ring, a perylene ring, a pentaphene ring, a pycene ring, a pyrene ring, a pyranthrene ring, and an anthraanthrene ring, or the like.

The aforementioned aromatic hydrocarbon ring may have a substituent group represented by Y1 in General Formula (1).

With regard to Y6 to Y9 of General Formula (2), examples of the aromatic heterocycle used for forming a group each derived from an aromatic heterocycle include a furan ring, a thiophene ring, an oxazole ring, a pyrrole ring, a pyridine ring, a pyridazine ring, a pyrimidine ring, a pyrazine ring, a triazine ring, a benzoimidazole ring, an oxadiazole ring, a triazole ring, an imidazole ring, a pyrazole ring, a thiazole ring, an indole ring, an indazole ring, a benzoimidazole ring, a benzothiazole ring, a benzooxazole ring, a quinoxline ring, a quinazoline ring, a cinnoline ring, a quinoline ring, an isoquinoline ring, a phthalazine ring, a naphthiridine ring, a carbazole ring, a carboline ring, and a diazacarbazole ring (which represents a ring having one carbon atom constituting carboline ring is further substituted with a nitrogen atom), or the like.

Further, the aforementioned aromatic heterocycle may have a substituent group represented by Y1 in General Formula (1).

With regard to the aromatic heterocycle containing an N atom which is used for forming a group derived from an aromatic heterocycle containing an N atom as represented by at least one of Y6 and Y7 and at least one of Y8 and Y9 in General Formula (2), examples thereof include an oxazole ring, a pyrrole ring, a pyridine ring, a pyridazine ring, a pyrimidine ring, a pyrazine ring, a triazine ring, a benzoimidazole ring, an oxadiazole ring, a triazole ring, an imidazole ring, a pyrazole ring, a thiazole ring, an indole ring, an indazole ring, a benzoimidazole ring, a benzothiazole ring, a benzooxazole ring, a quinoxline ring, a quinazoline ring, a cinnoline ring, a quinoline ring, an isoquinoline ring, a phthalazine ring, a naphthiridine ring, a carbazole ring, a carboline ring, and a diazacarbazole ring (which represents a ring having one carbon atom constituting carboline ring is further substituted with a nitrogen atom), or the like.

Each group represented by Y7 and Y9 in General Formula (2) preferably represents a group derived from pyridine ring.

Further, each group represented by Y6 and Y8 in General Formula (2) preferably represents a group derived from benzene ring.

Among the compounds represented by General Formula (2) according to the present invention, a more preferred embodiment is described hereinbelow.

[Compound Represented by General Formula (3)]

According to the invention, the compound represented by the following General Formula (3) is more preferred among the compounds represented by General Formula (2) described above. Hereinbelow, the compound represented by General Formula (3) is described.

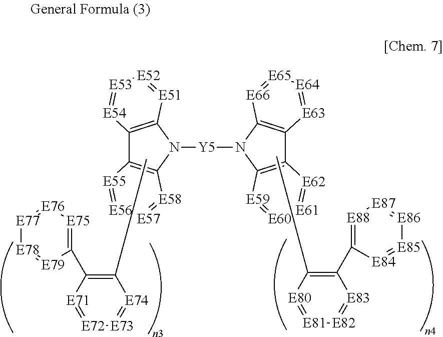

In the formula of General Formula (3), Y5 represents an arylene group, a heteroarylene group, or a divalent linking group including a combination thereof. Each of E51 to E66 and E71 to E88 represents —C(R3)= or —N═ and R3 represents hydrogen atom or a substituent group. Meanwhile, at least one of E71 to E79 and at least one of E80 to E88 represents —N═. n3 and n4 represent an integer of from 0 to 4, in which n3+n4 is an integer of 2 or more.

The arylene group and heteroarylene group represented by Y5 in General Formula (3) have the same meaning as the arylene group and heteroarylene group that are described as an example of a divalent linking group represented by Y1 in General Formula (1).

As for the preferred embodiment of an arylene group, a heteroarylene group, or a divalent linking group including a combination thereof represented by Y5, it is preferable to contain, among the heteroarylene groups, a group derived from a condensed aromatic heterocycle which is obtained by condensation of three or more rings. As for the group derived from the condensed aromatic heterocycle which is obtained by condensation of three or more rings, a group derived from dibenzo furan ring or a group derived from dibenzothiophene ring is preferable.

The substituent group represented by R3 of —C(R3)=, which is represented by each of E51 to E66 and E71 to E88 of General Formula (3), has the same meaning as the substituent group represented by Y1 in General Formula (1).

With regard to General Formula (3), it is preferable that each of 6 or more of E51 to E58 and 6 or more of E59 to E66 is represented by —C(R3)=.

With regard to General Formula (3), it is preferable that at least one of E75 to E79 and at least one of E84 to E88 represents —N═.

Further, with regard to General Formula (3), it is preferable that any one of E75 to E79 and any one of E84 to E88 represent —N═.

Preferred embodiment includes that, in General Formula (3), each of E71 to E74 and E80 to E83 is represented by —C(R3)=.

Further, it is preferred that, in the compound represented by General Formula (2) or General Formula (3), E53 is represented by —C(R3)= and R3 represents a linking site, and it is also preferred that E61 is also at once represented by —C(R3)= and R3 represents a linking site.

Further, it is preferred that, E75 and E84 are represented by —N═ and each of E71 to E74 and E80 to E83 is represented by —C(R3)=.

[Specific Examples of Compound]

Hereinbelow, the specific examples (1 to 112) of the compound represented by General Formula (1), (2), or (3) according to the present invention are described, but the invention is not limited to them.

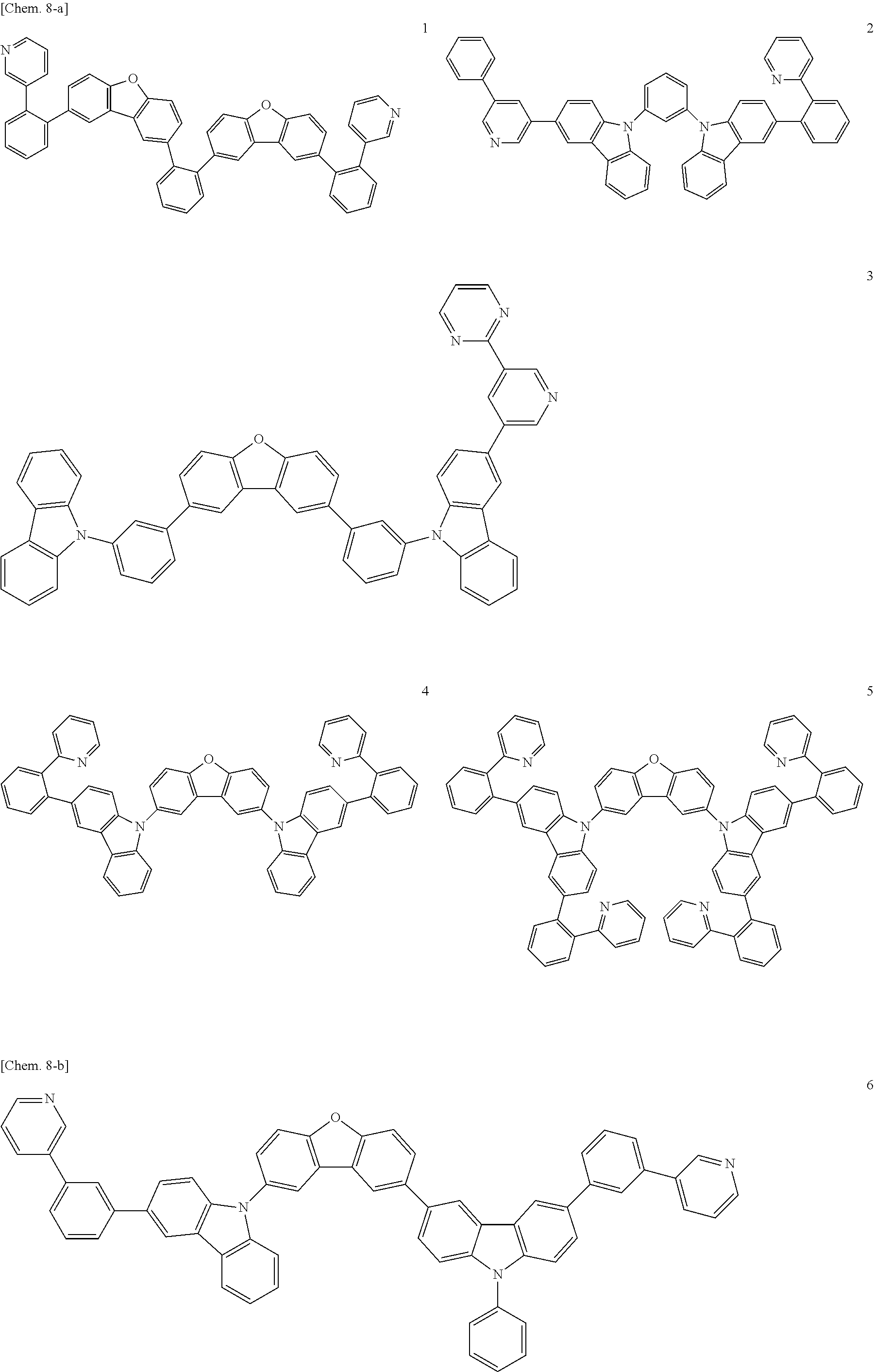

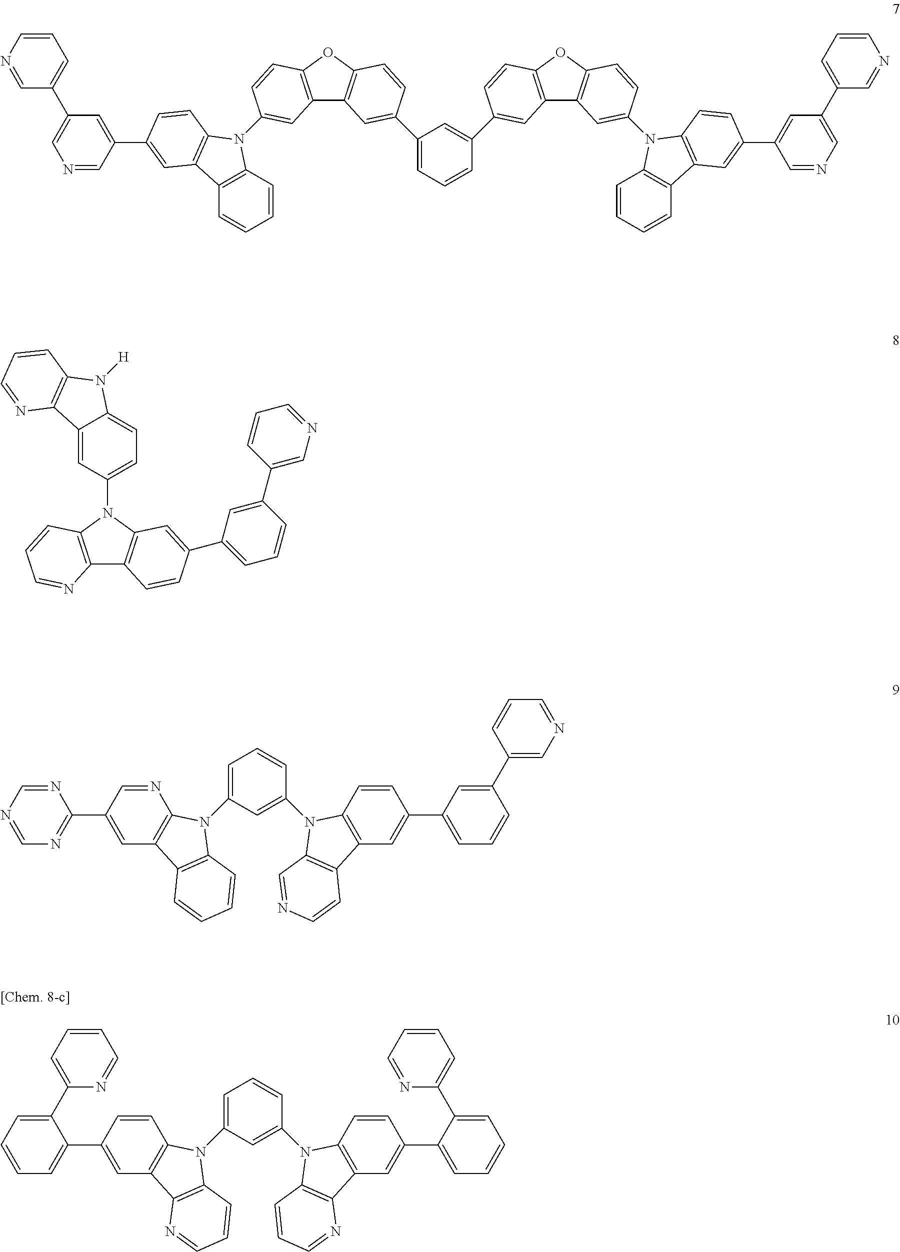

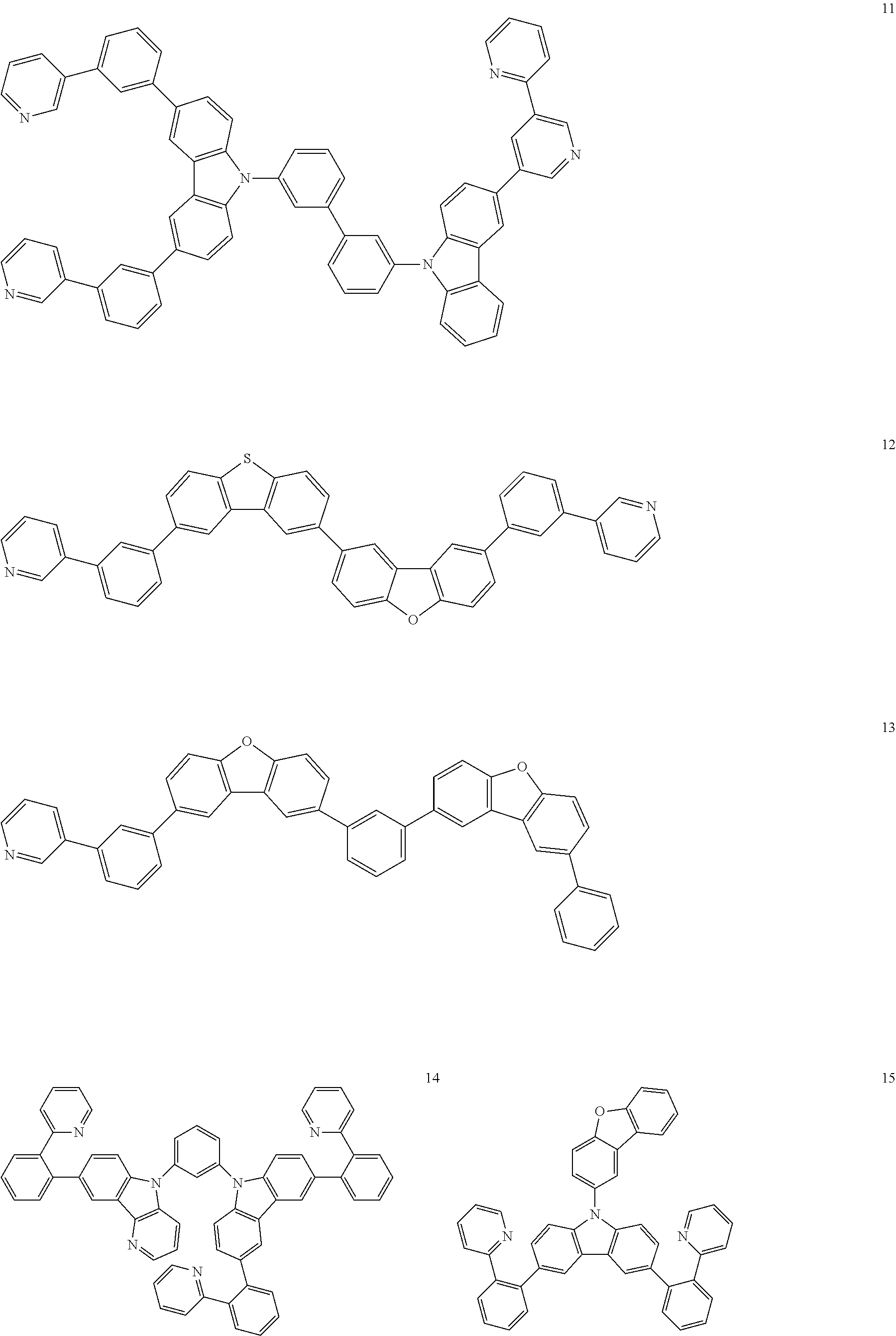

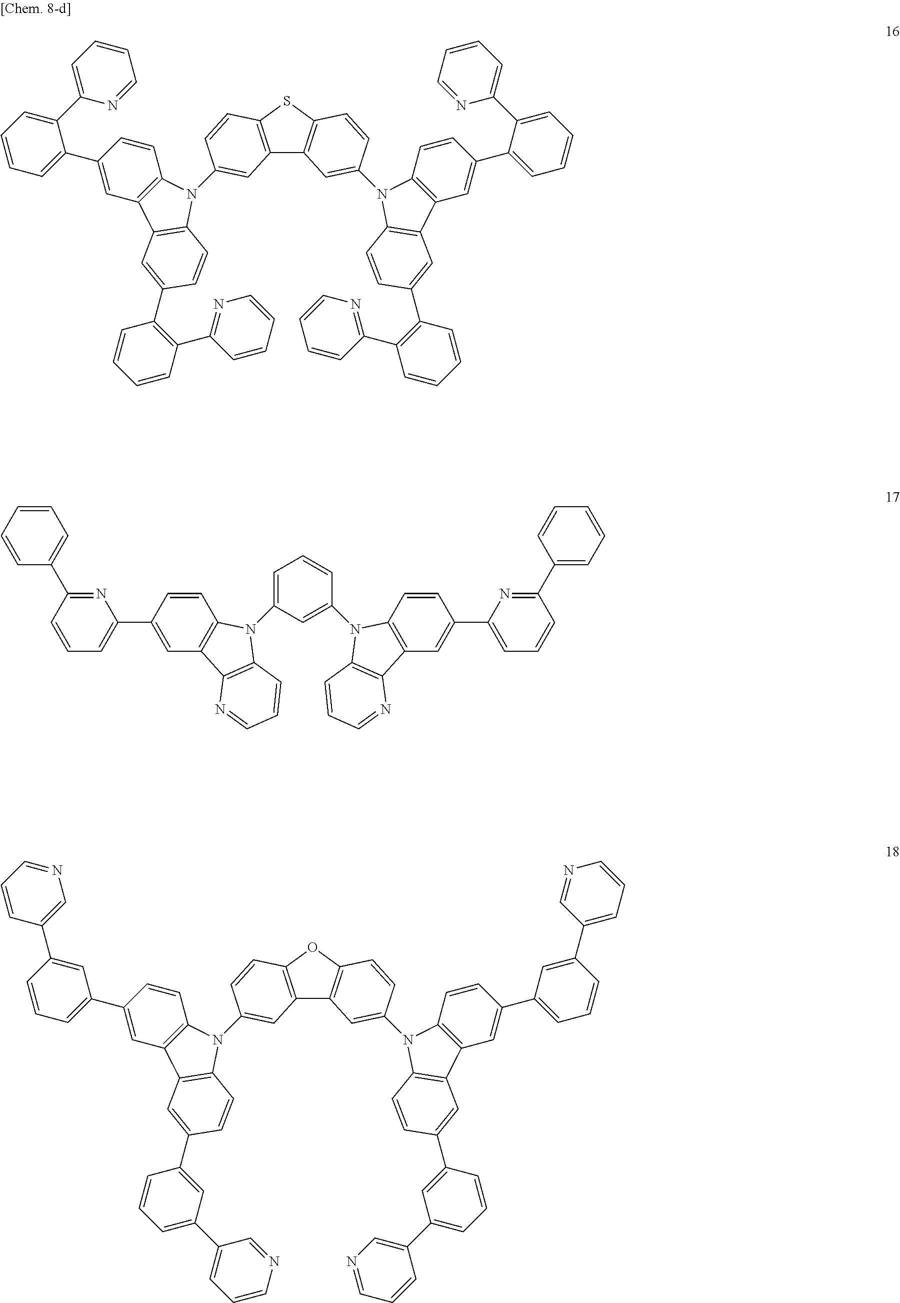

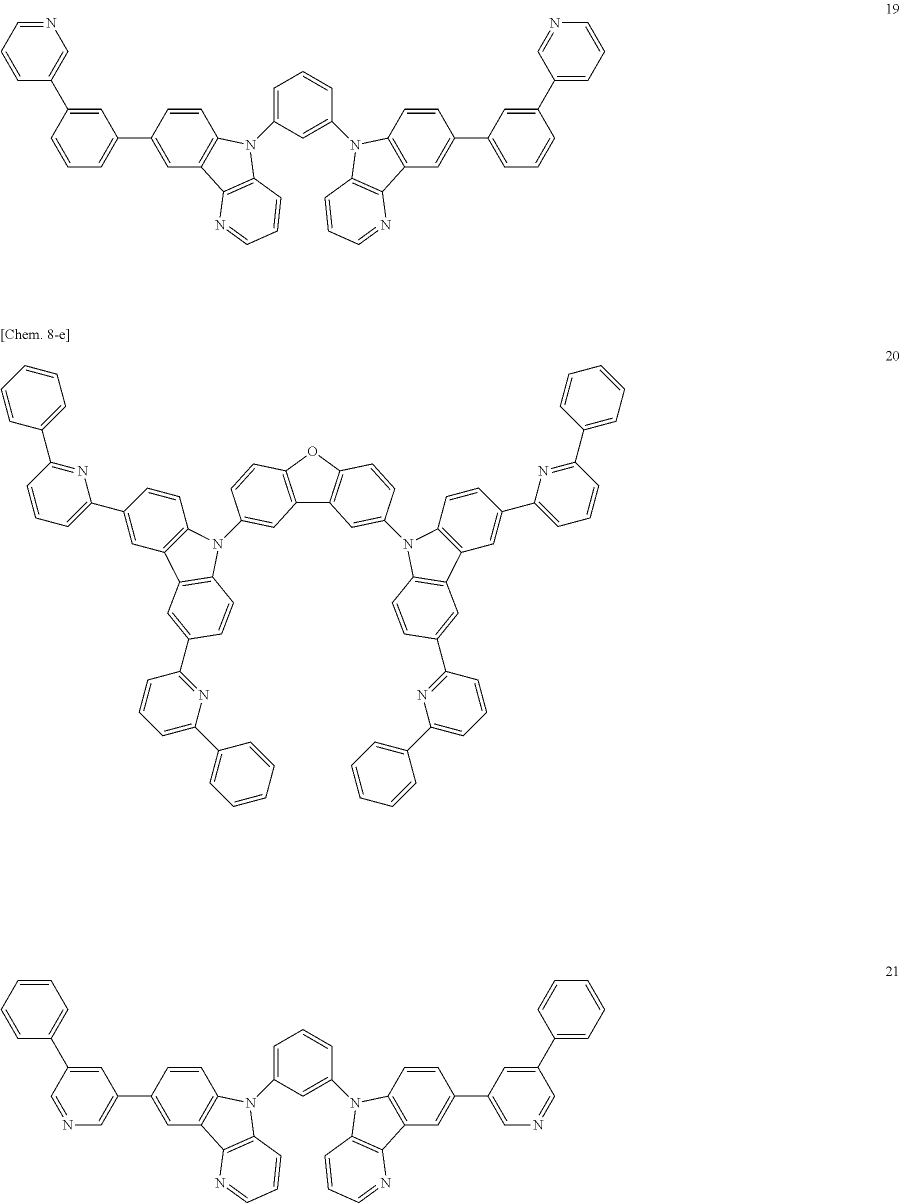

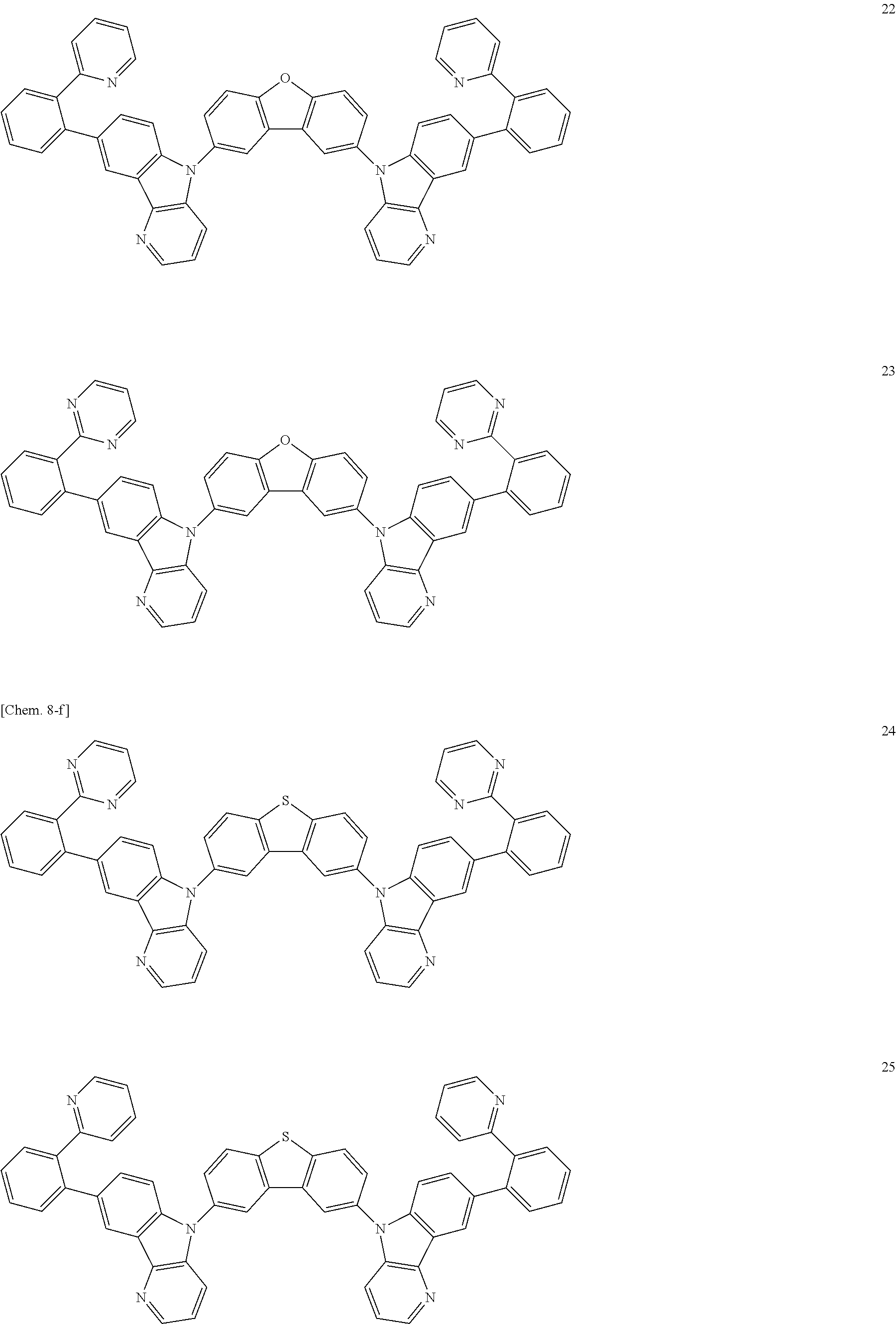

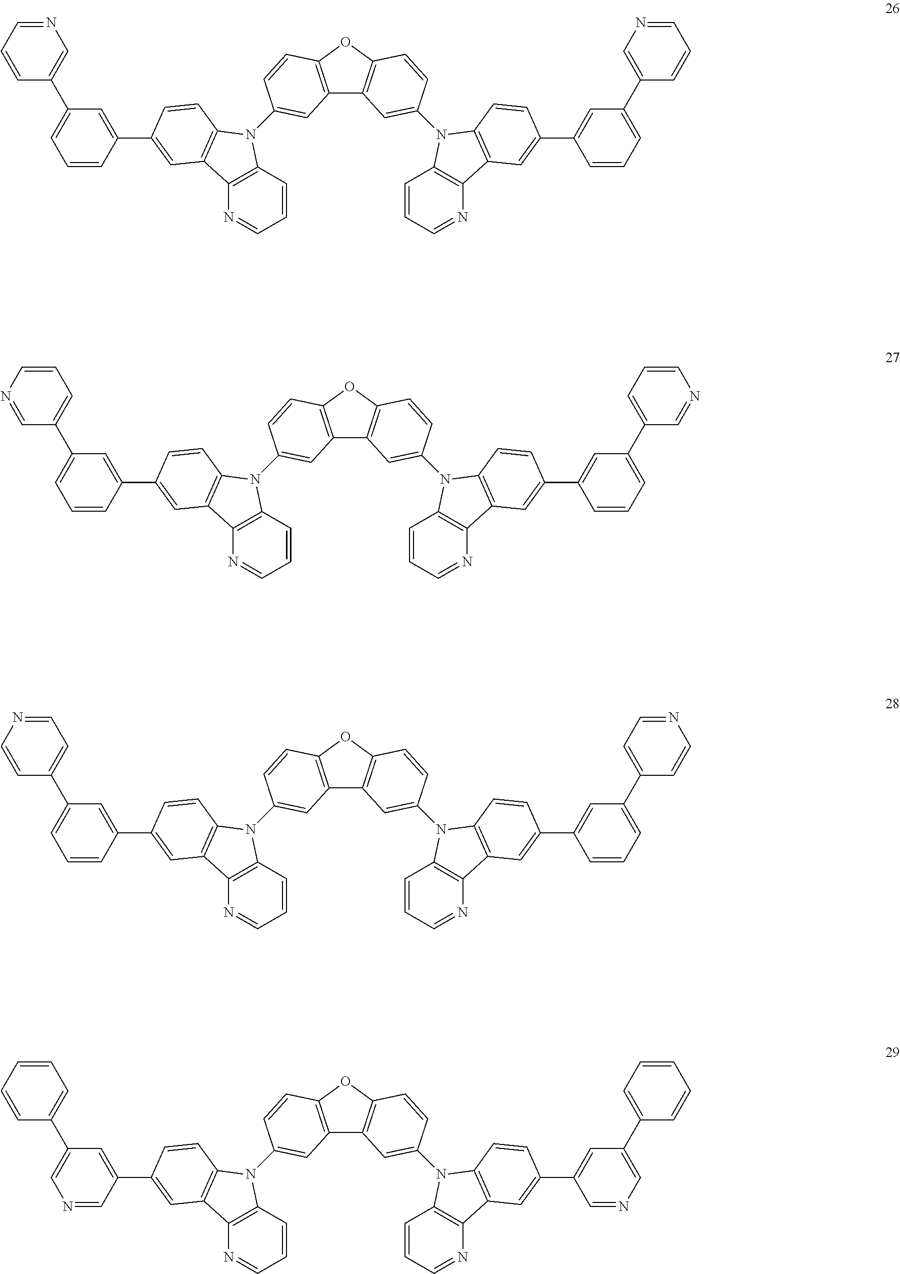

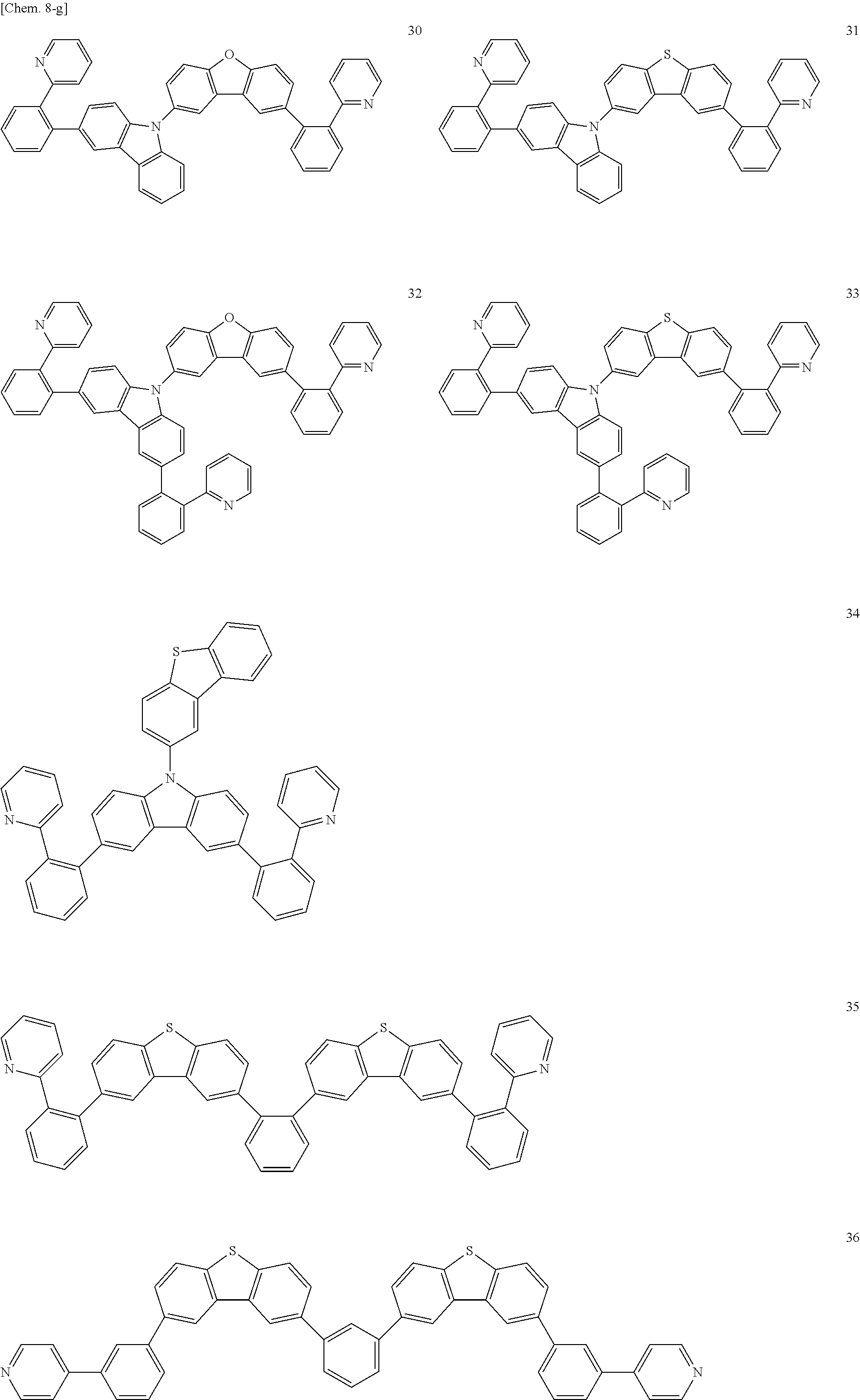

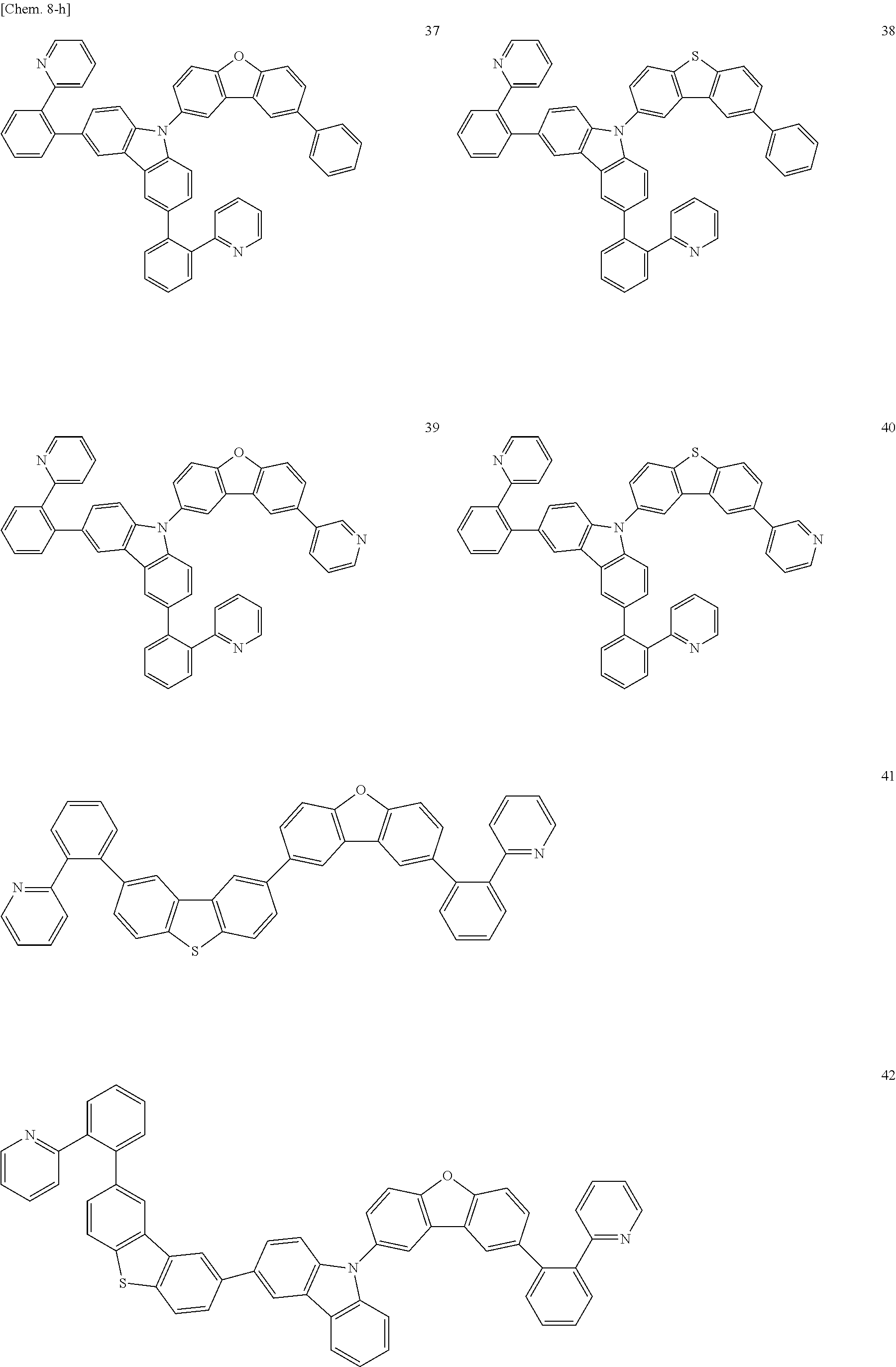

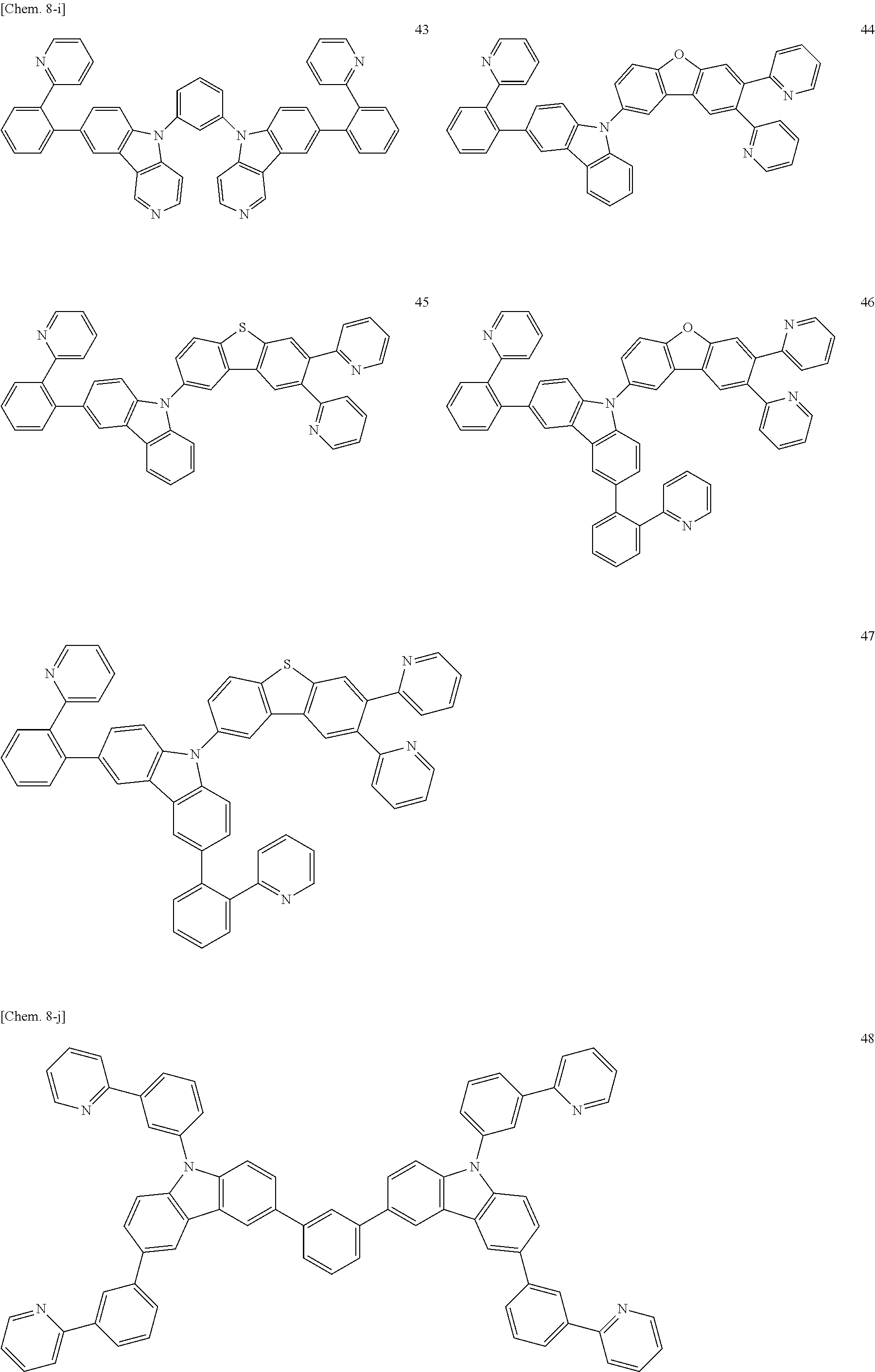

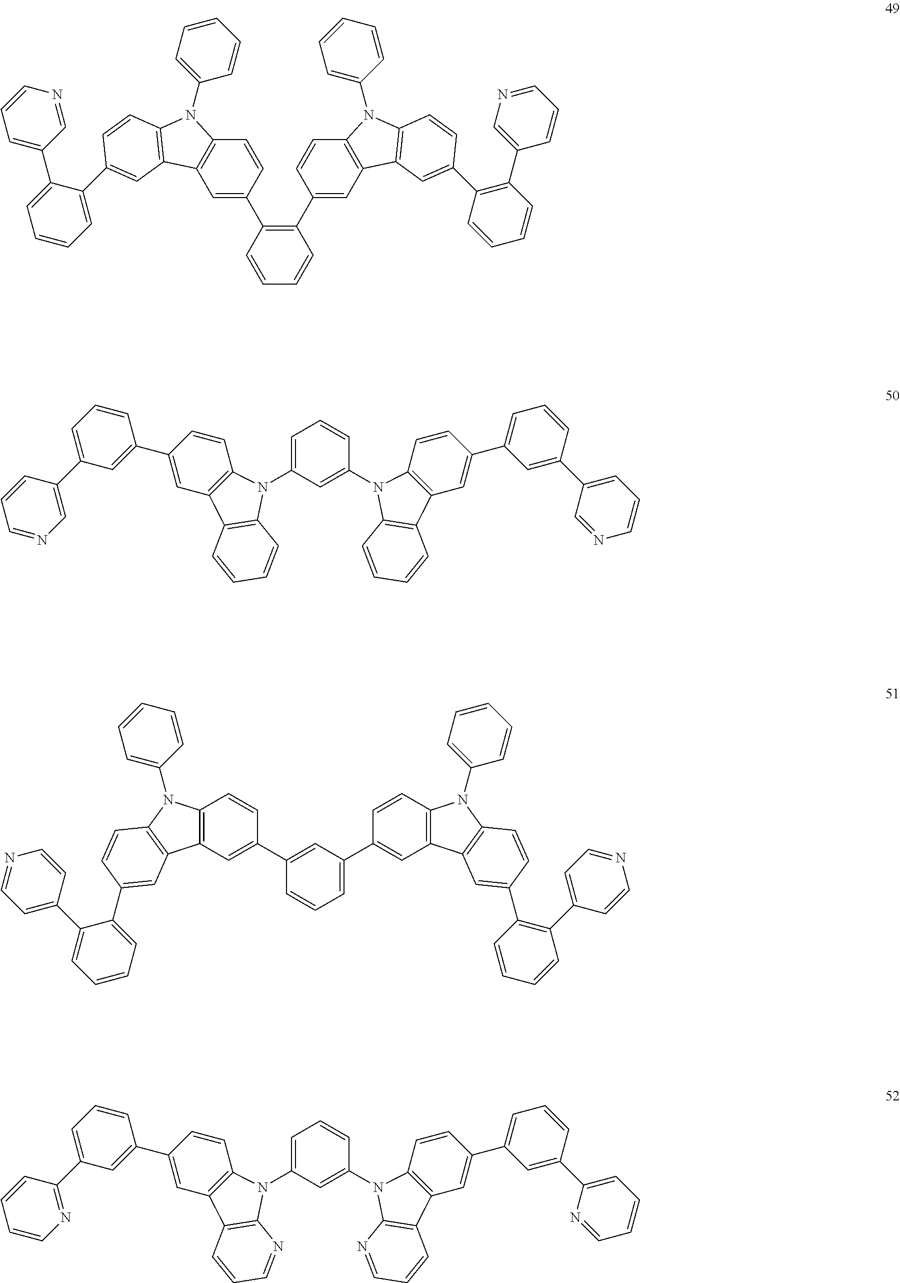

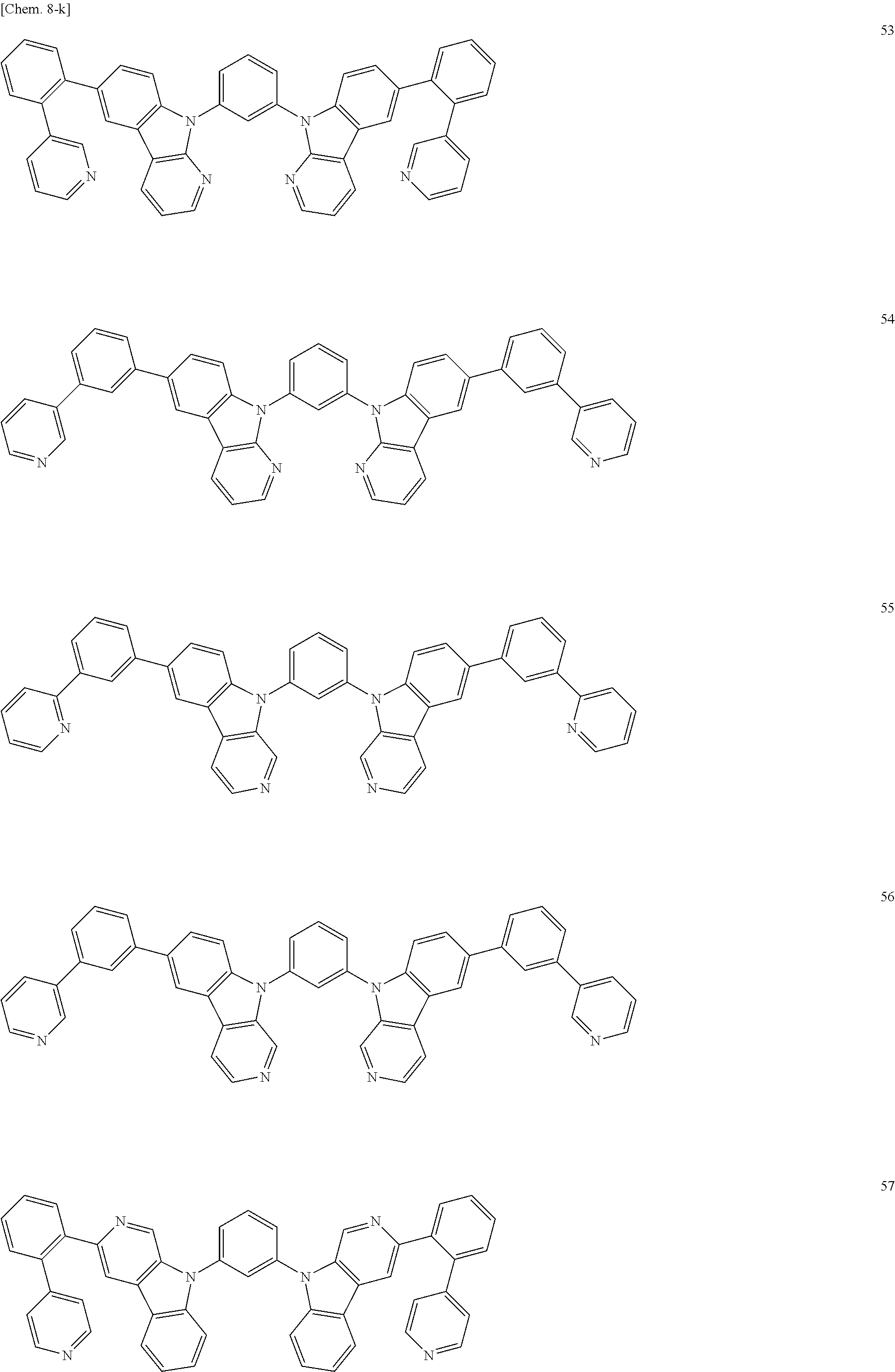

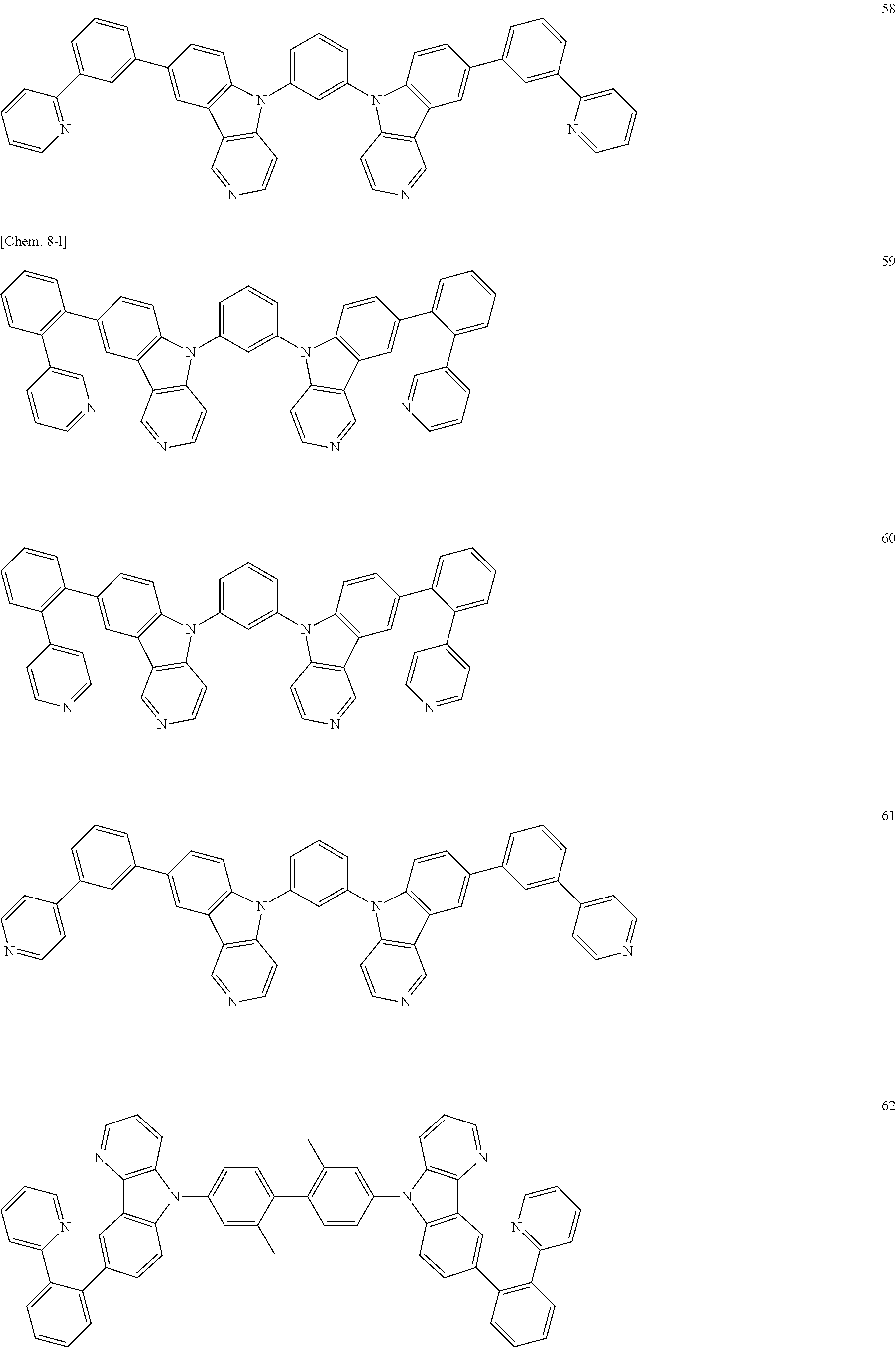

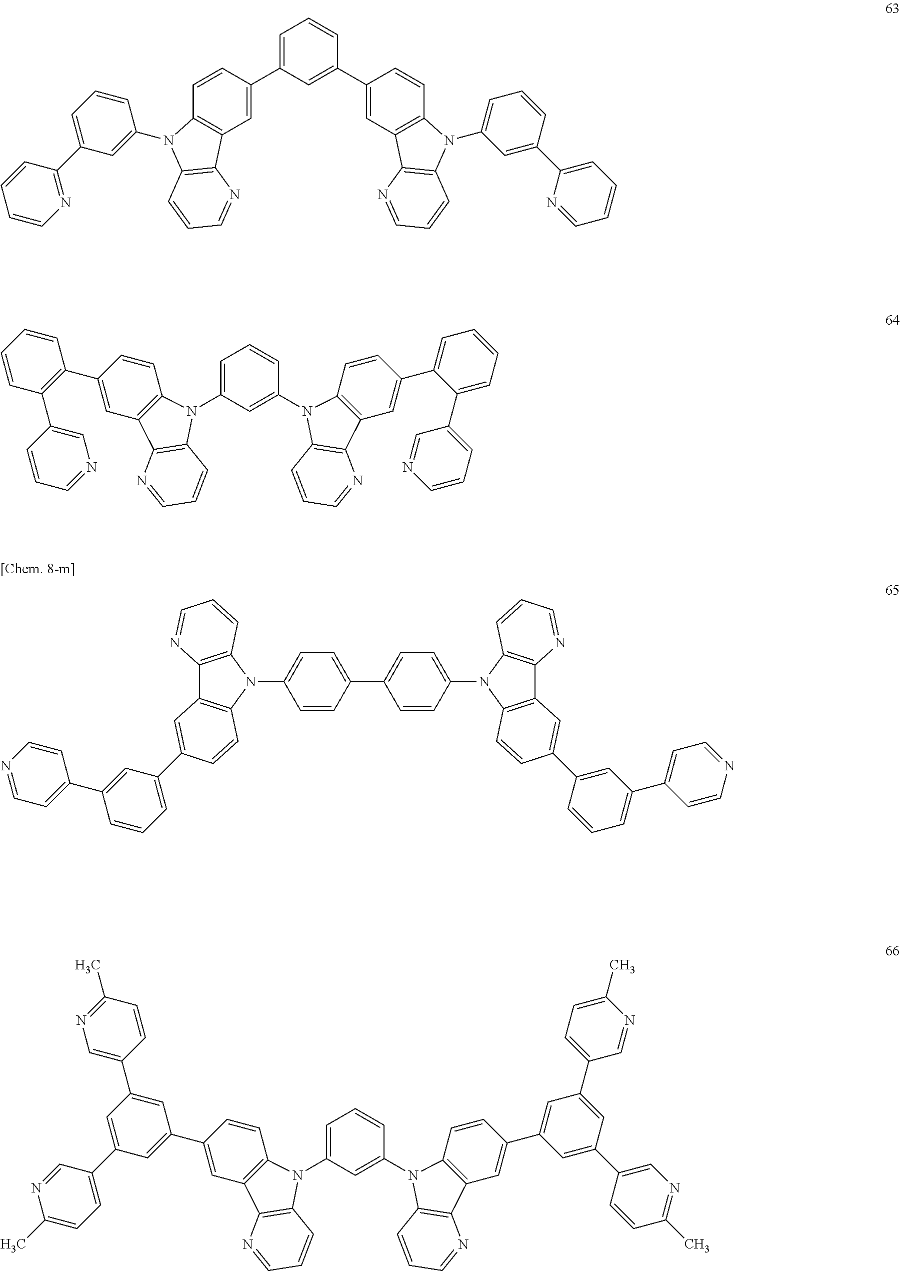

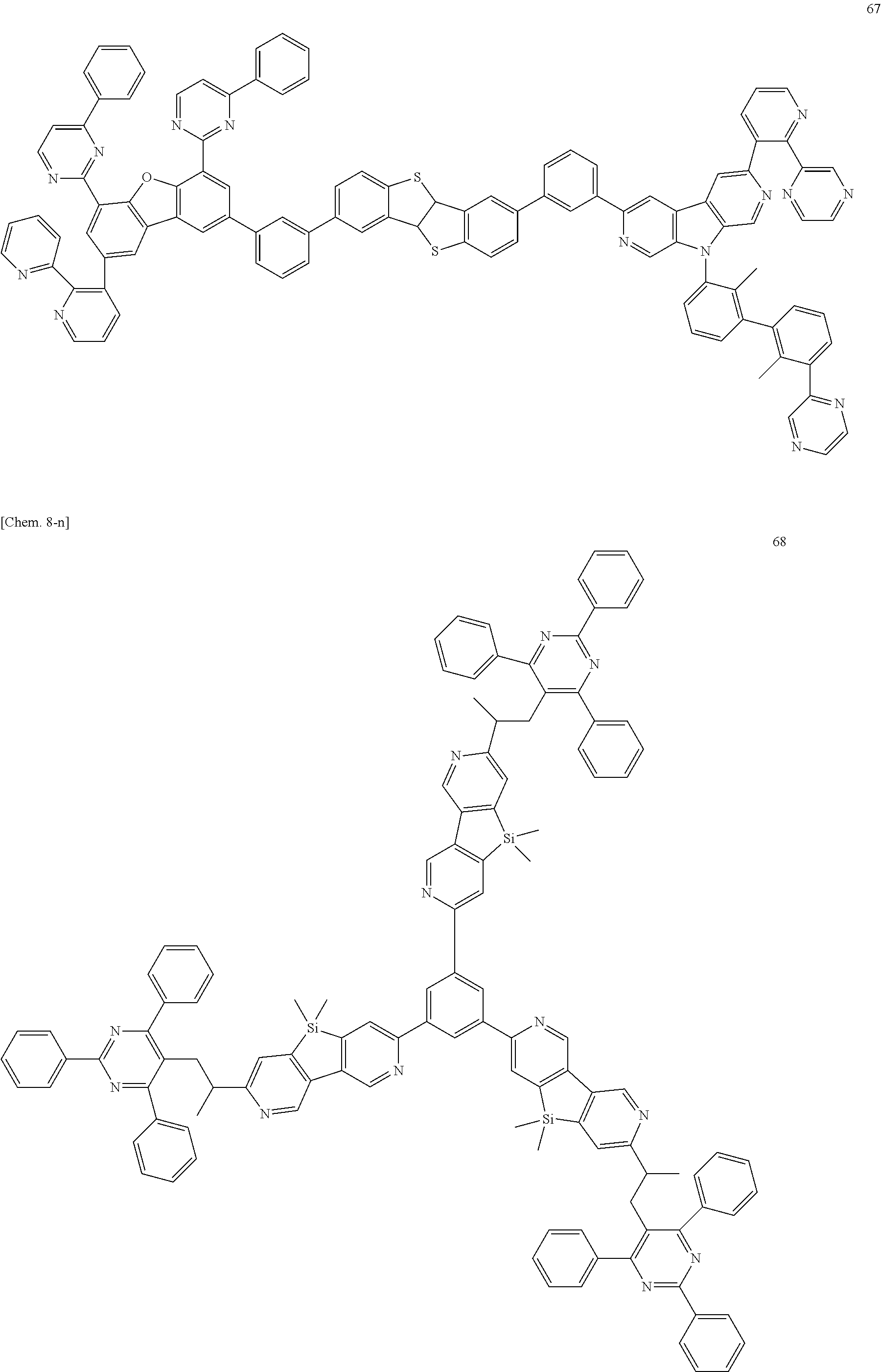

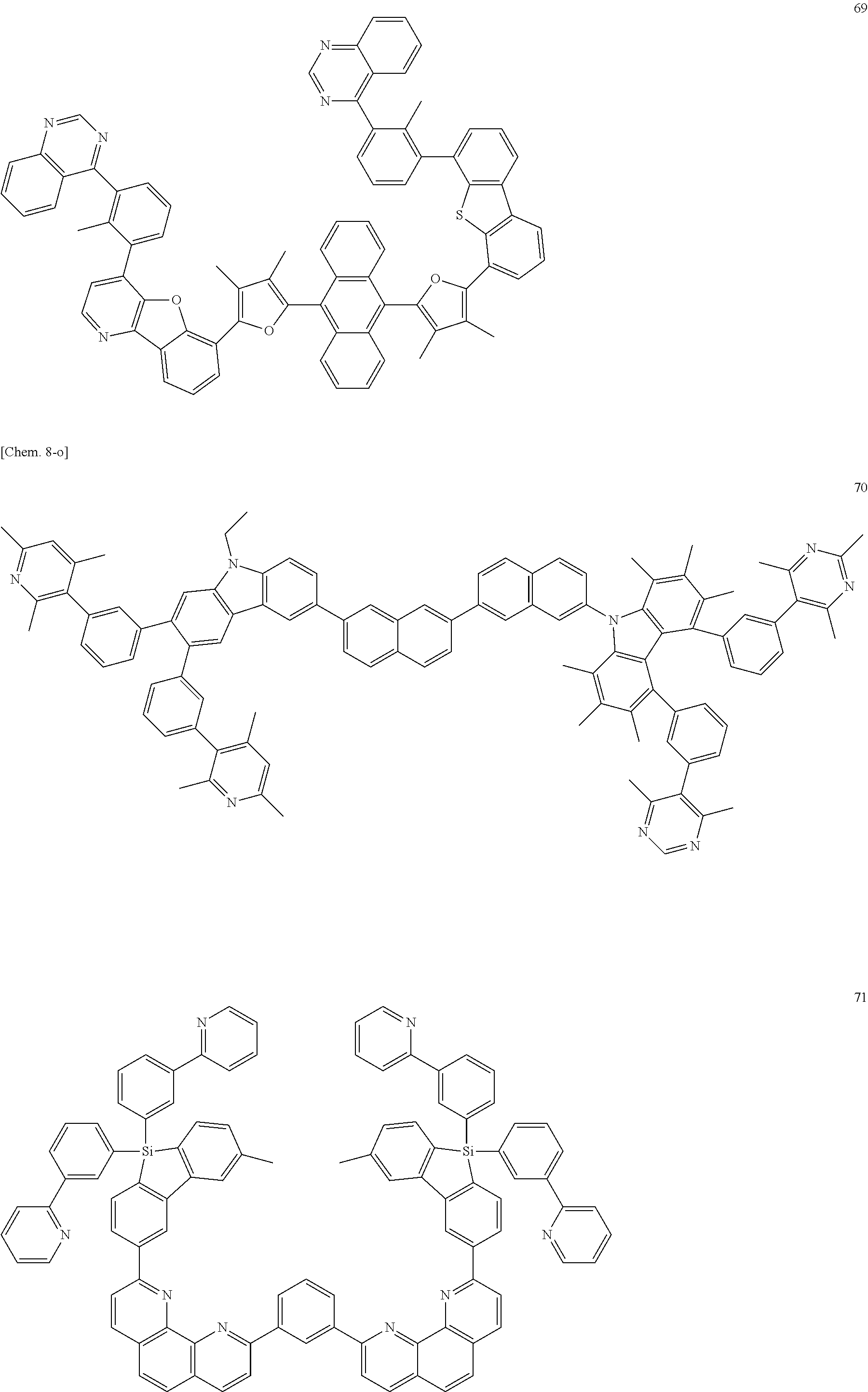

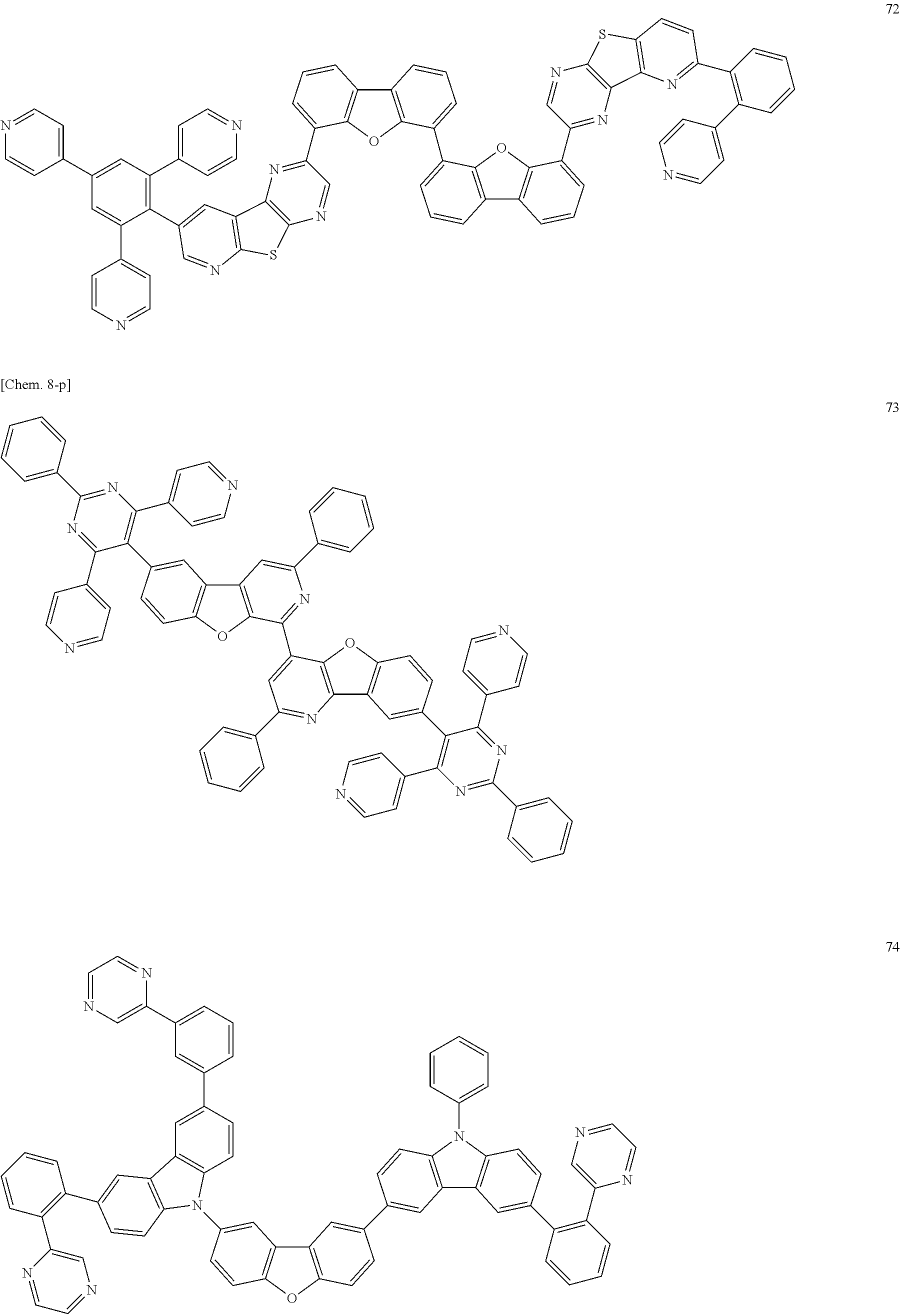

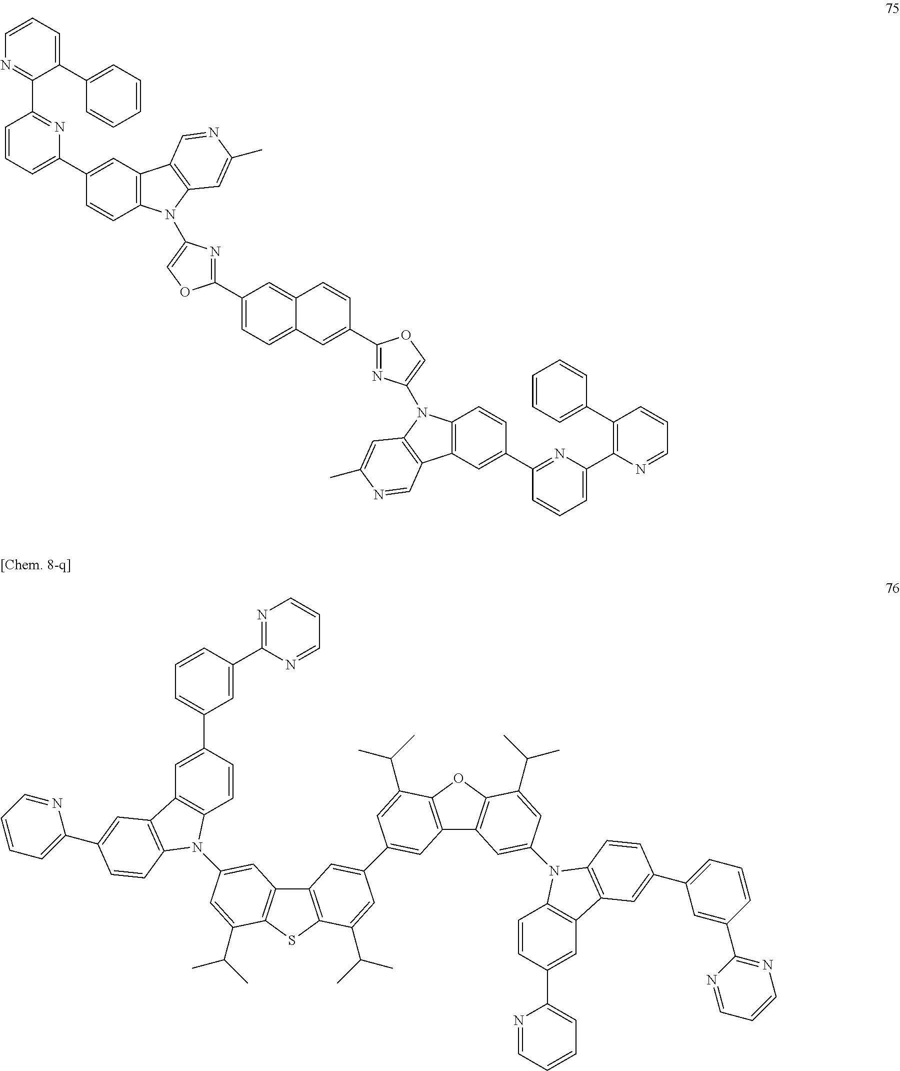

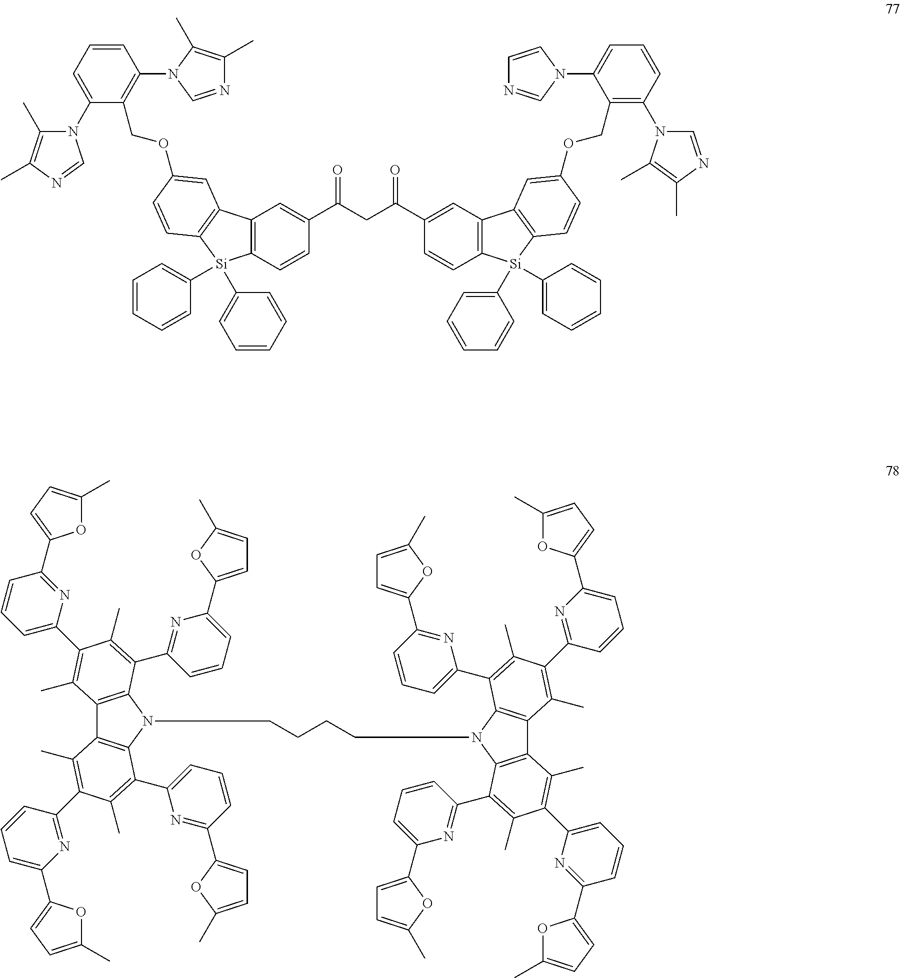

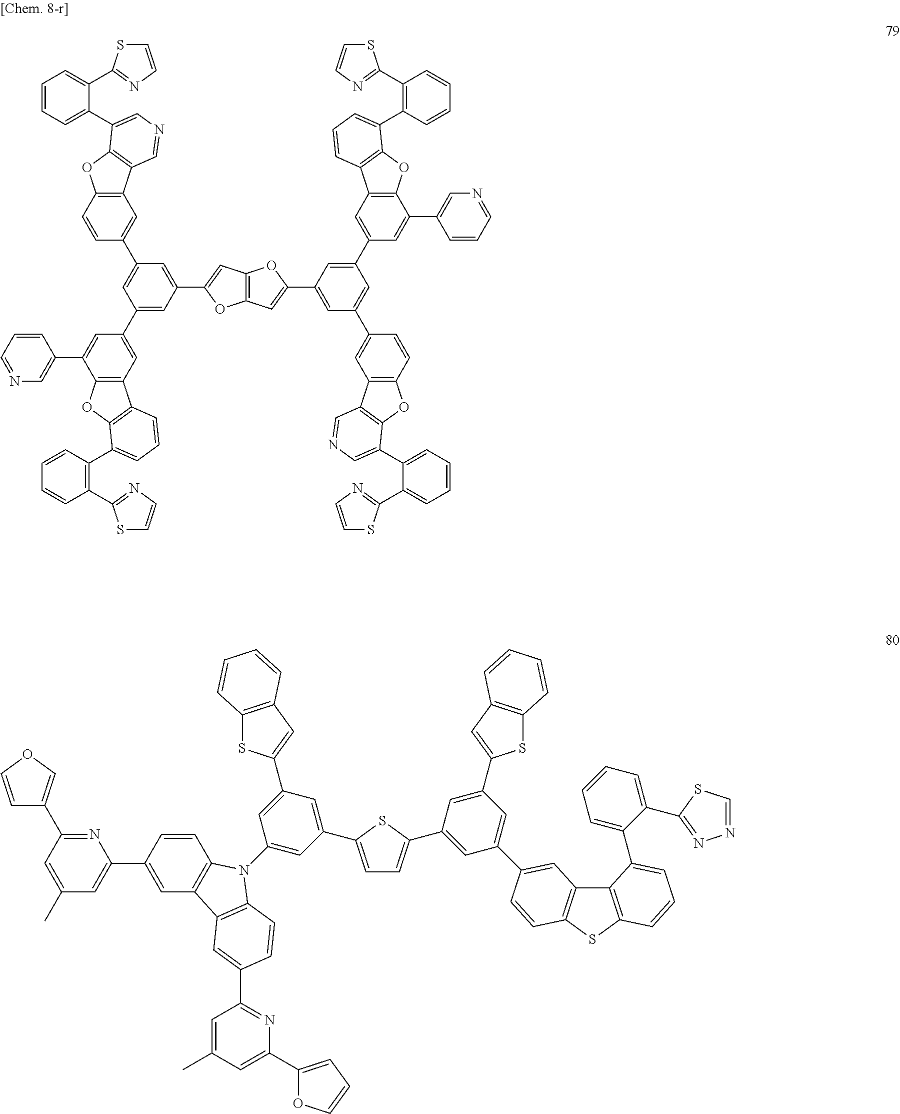

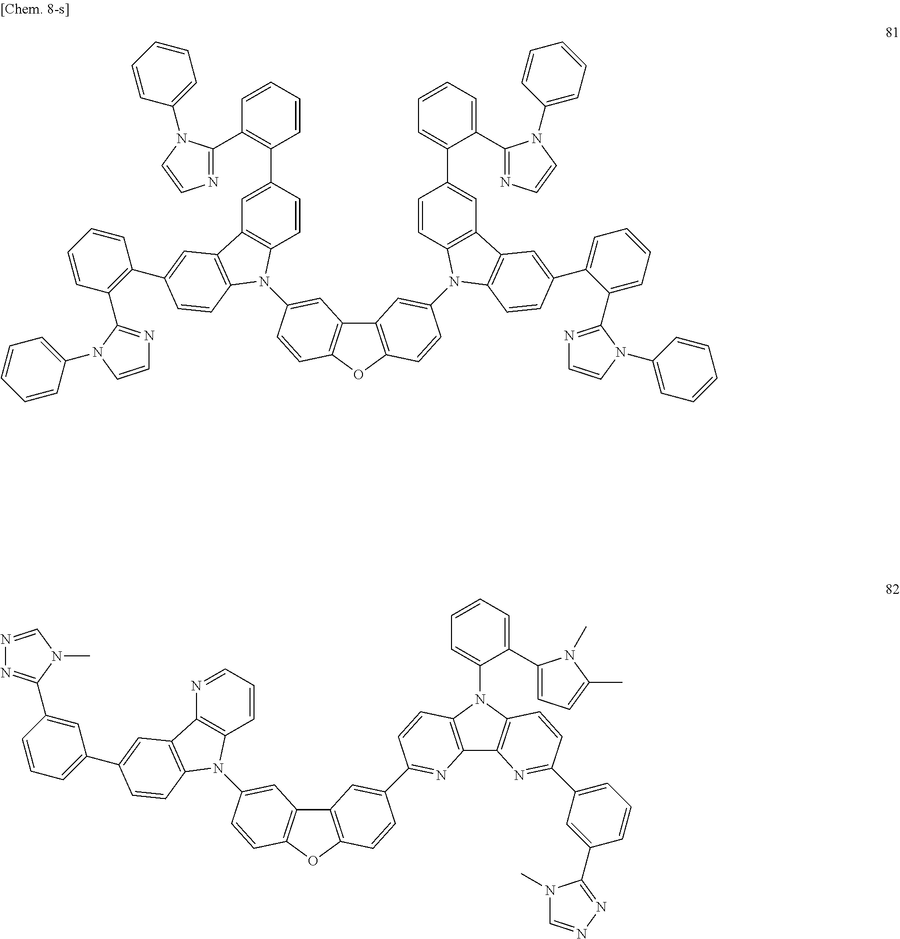

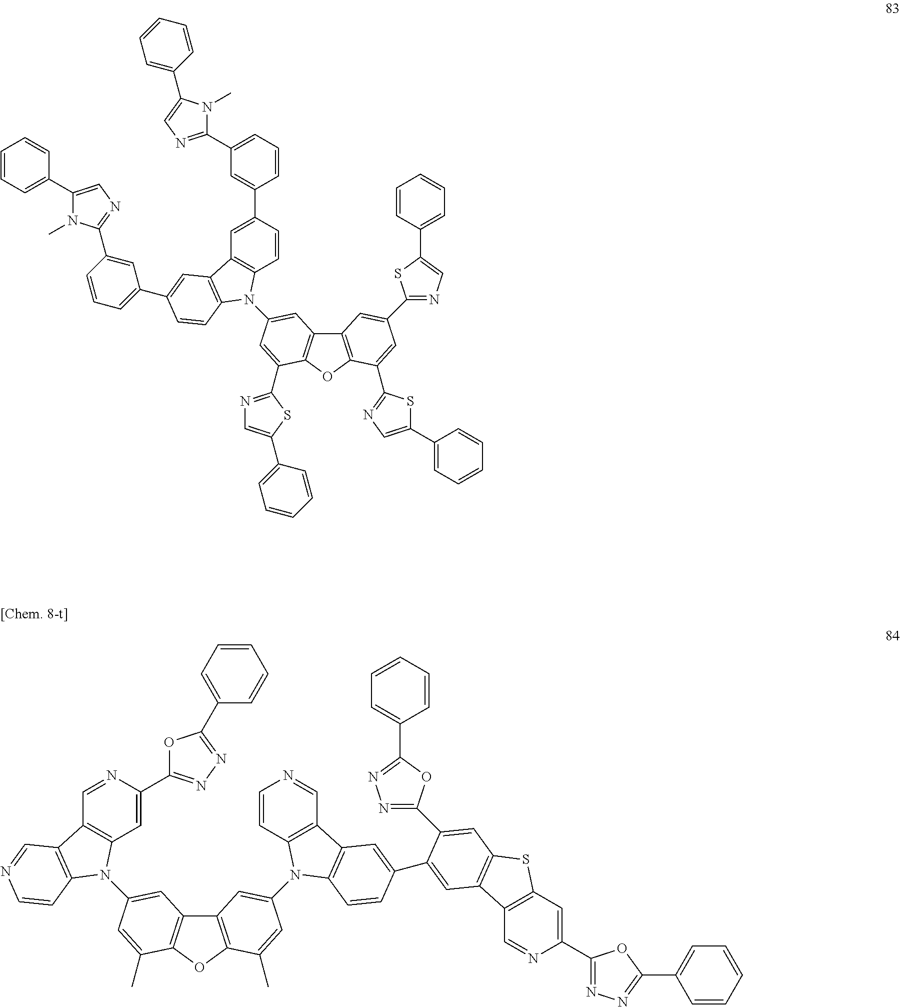

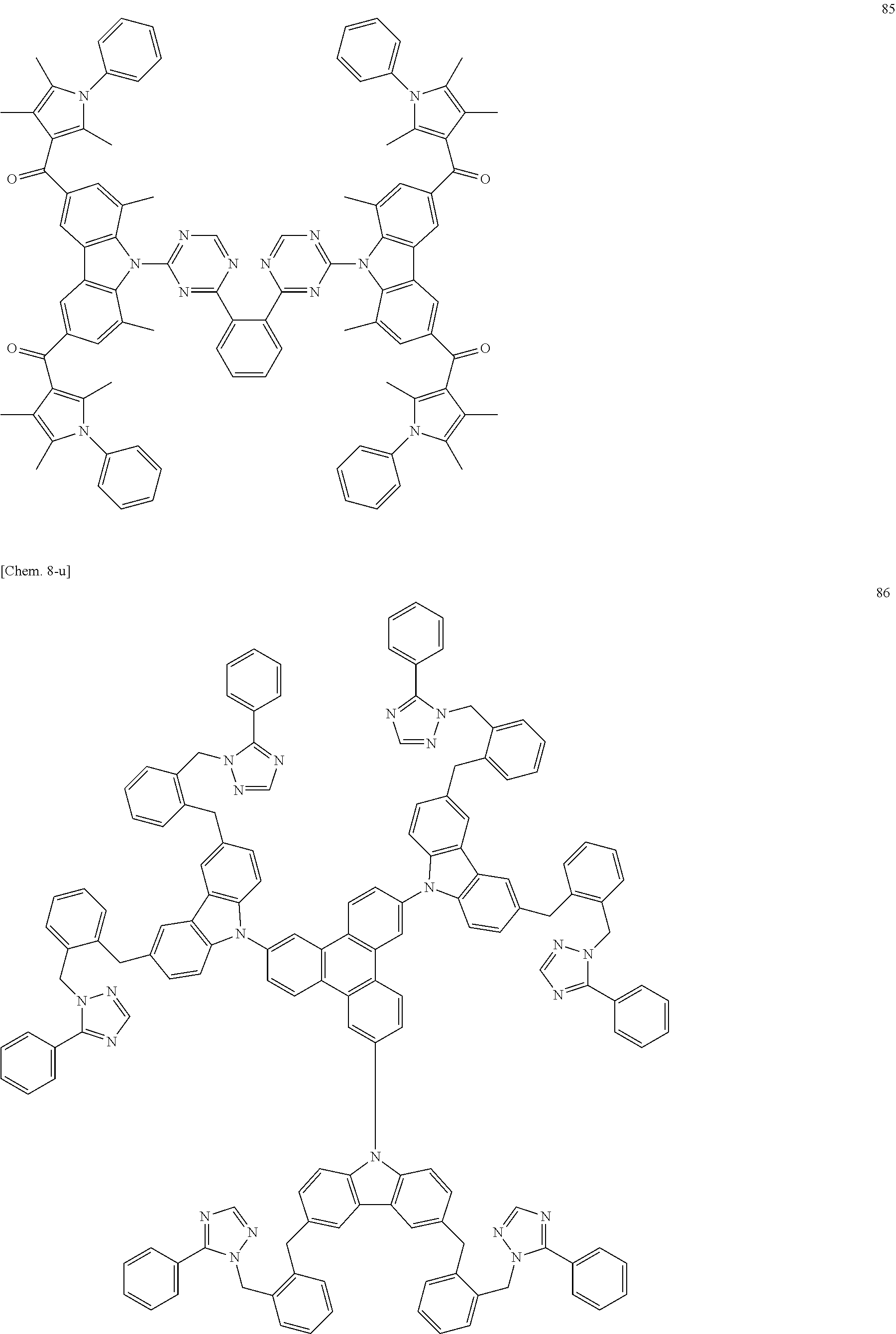

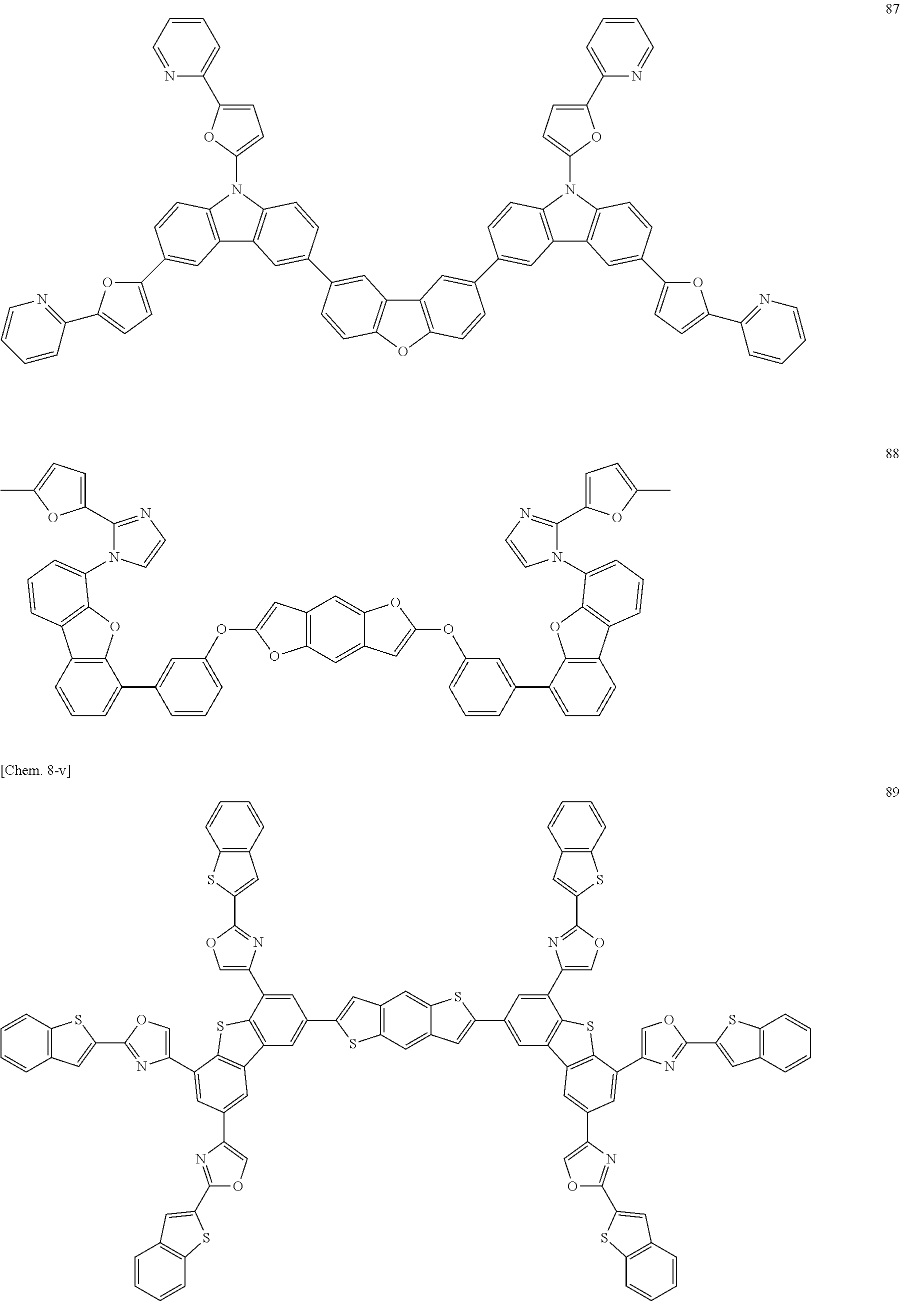

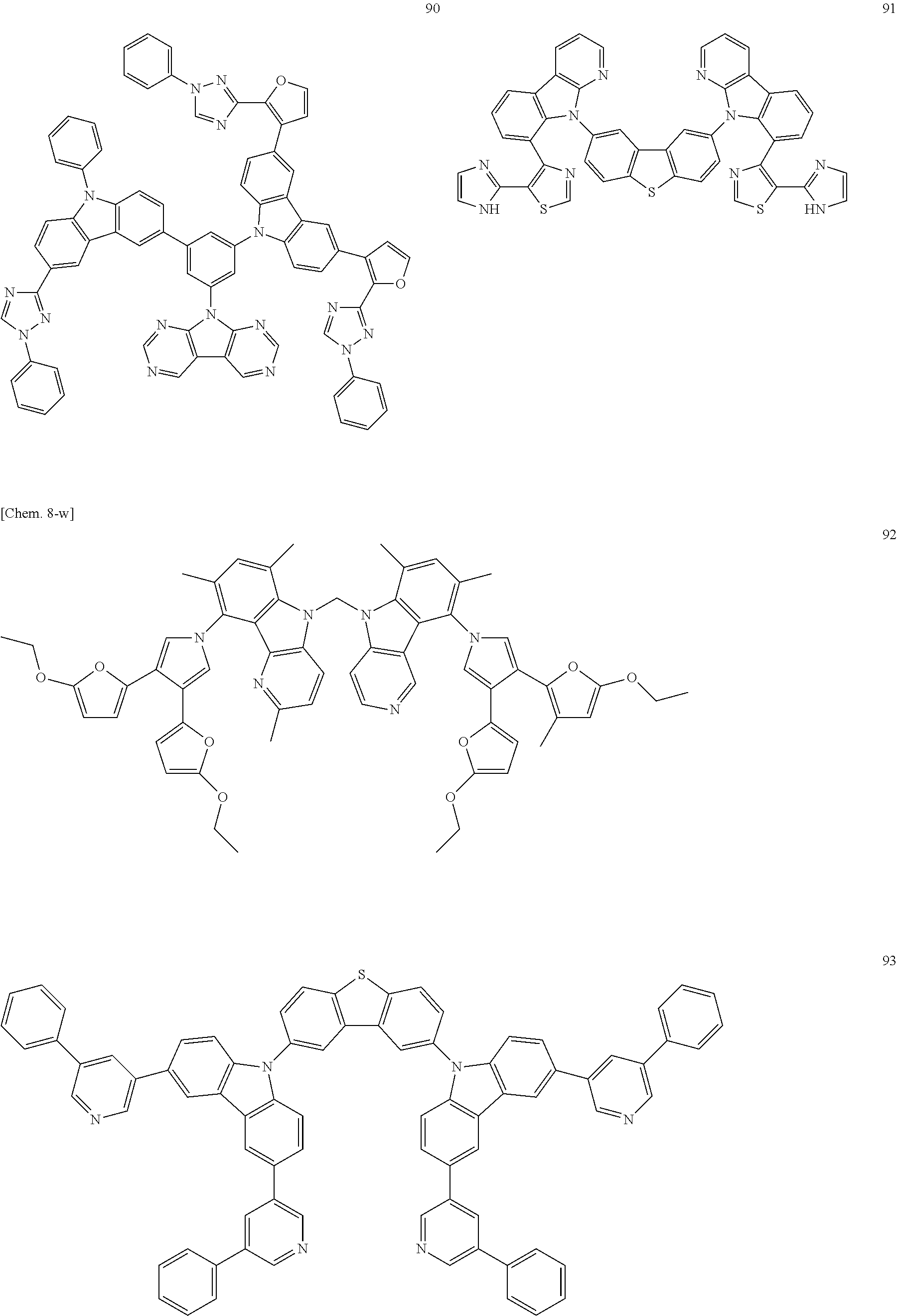

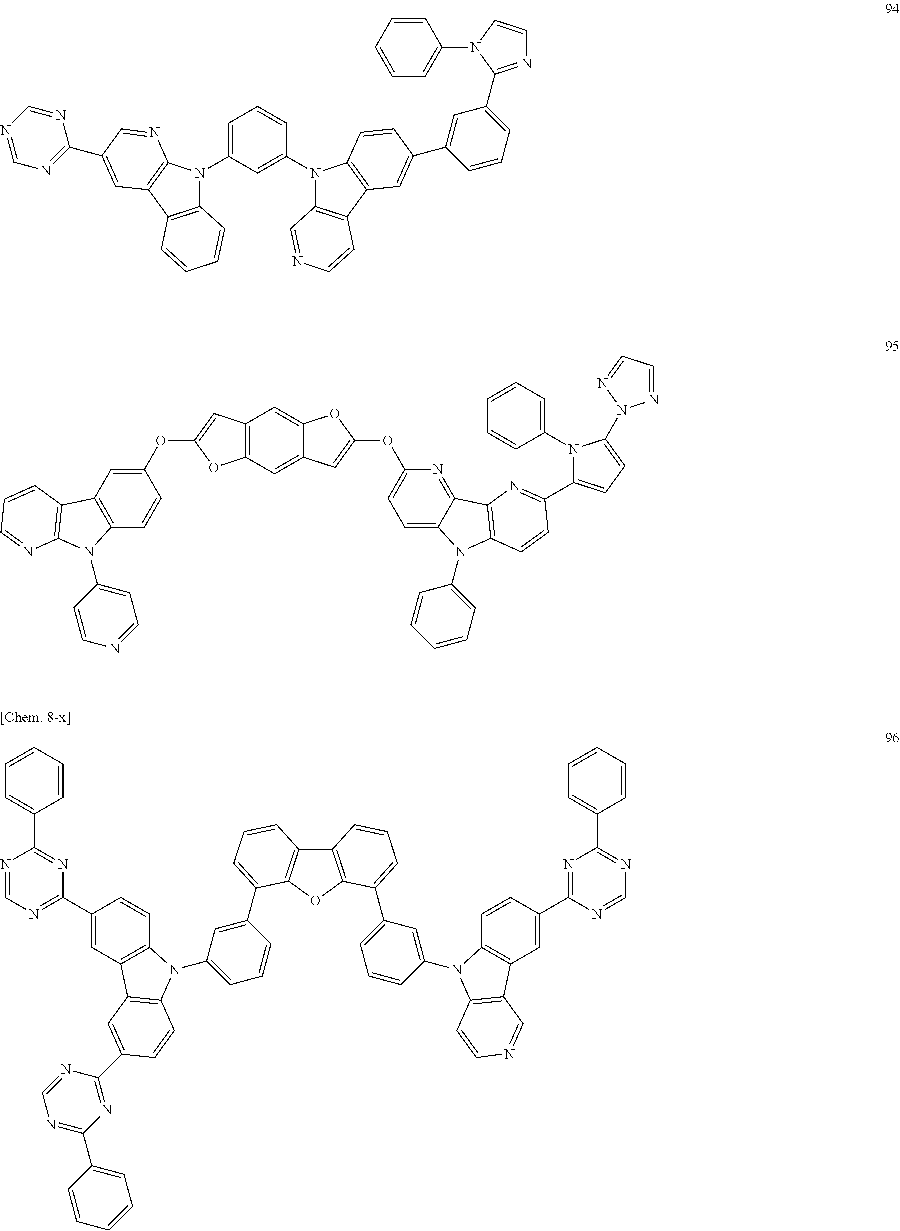

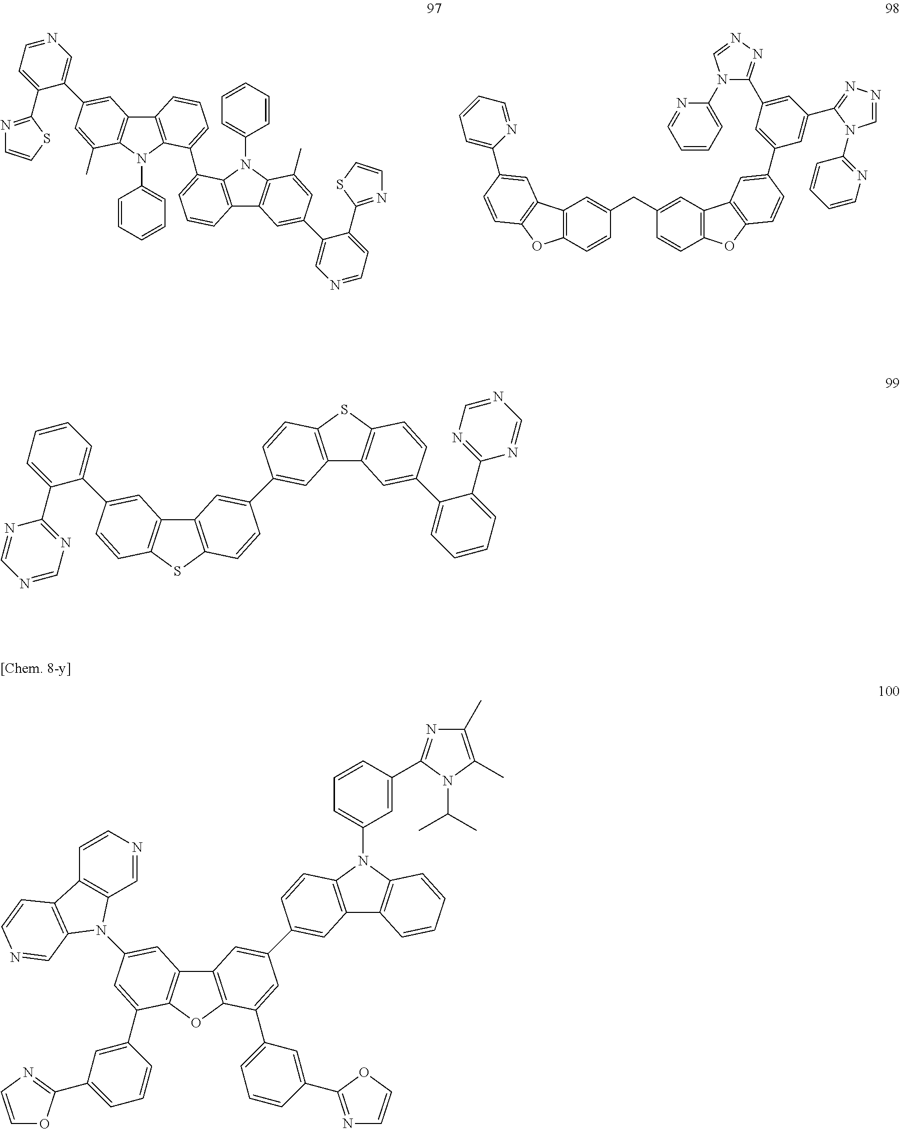

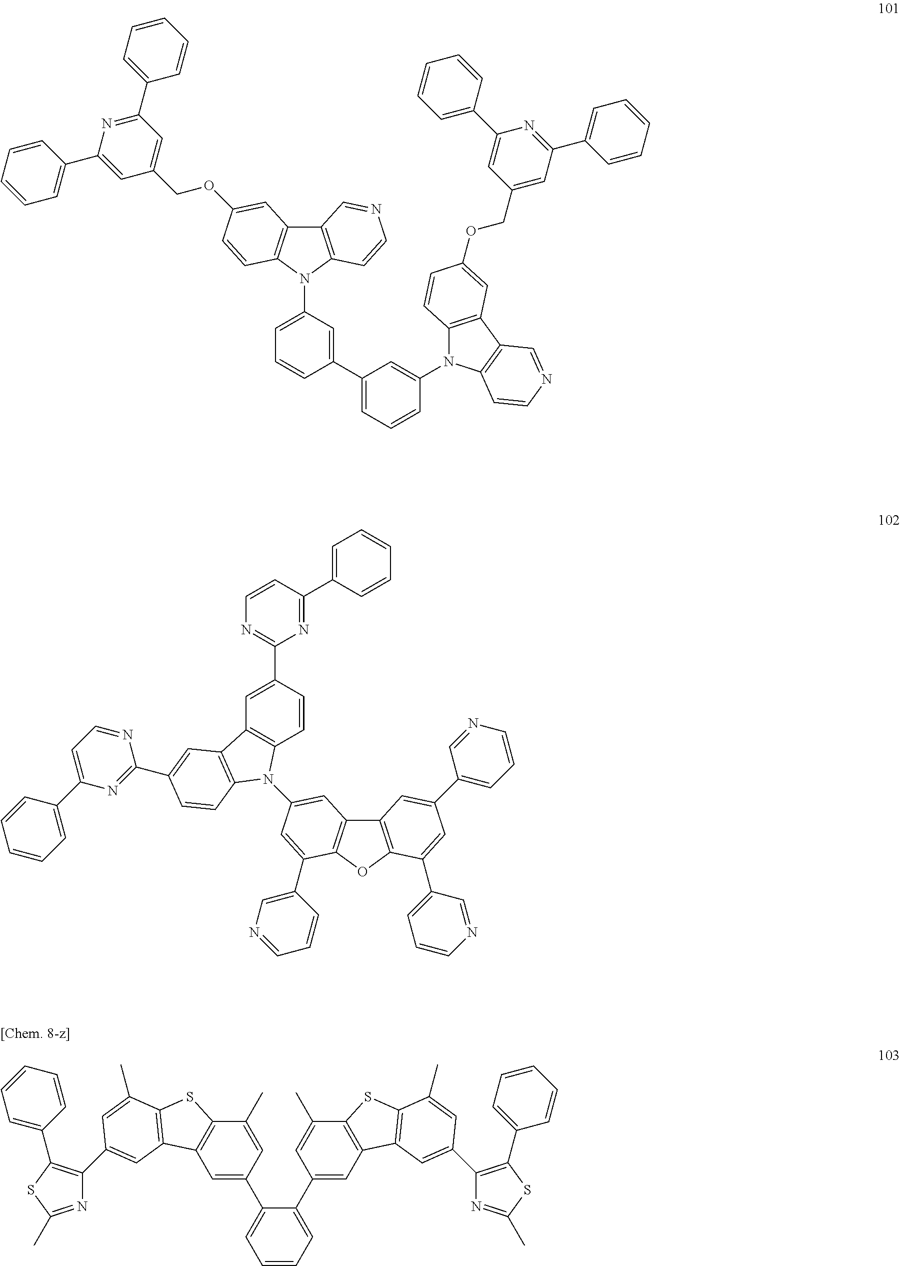

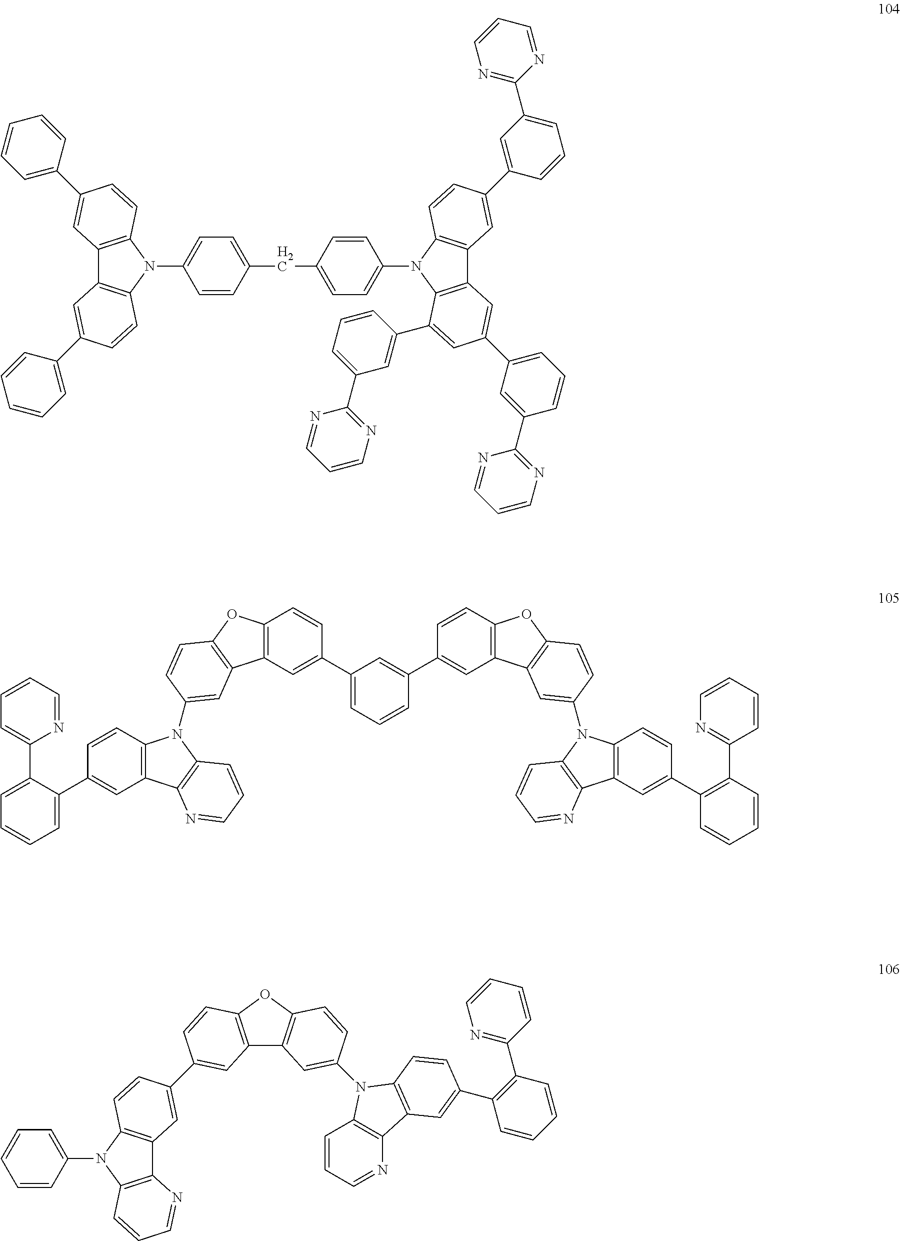

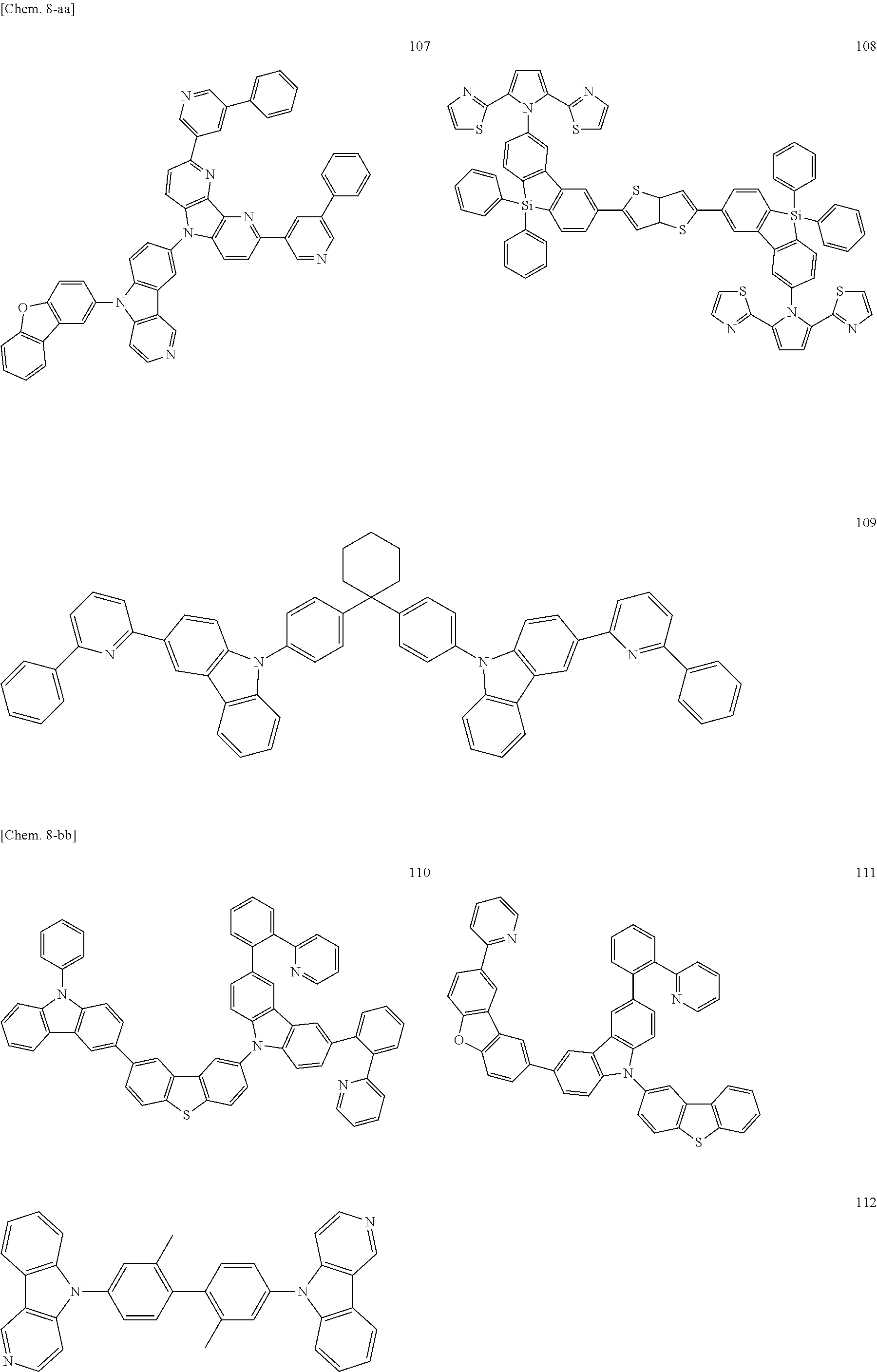

[Synthesis Examples of Compound]

Hereinbelow, the specific synthesis example of Compound 5 is given as a representative compound synthesis example, but the present invention is not limited to it.

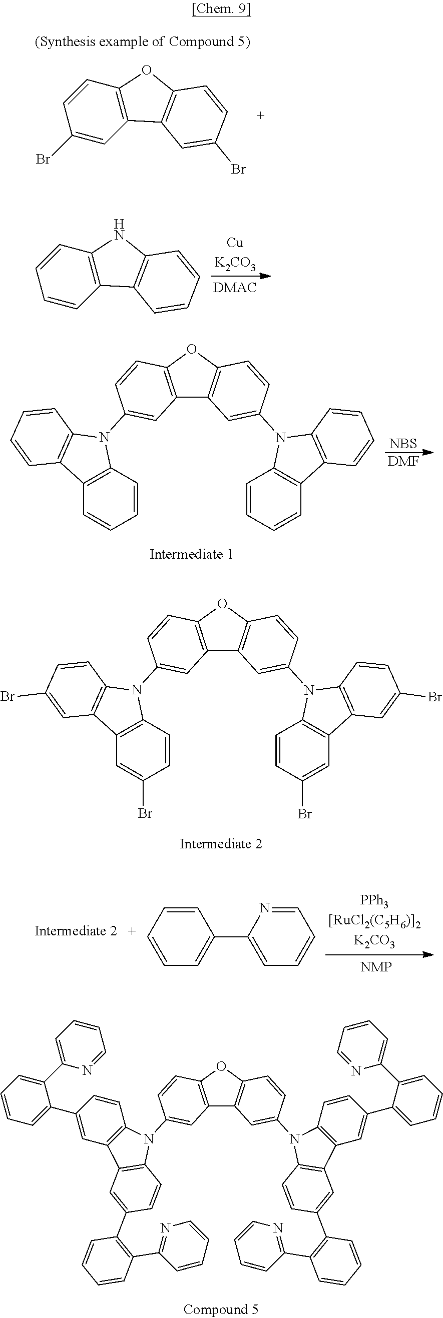

### Step 1: (Synthesis of Intermediate 1)

Under nitrogen atmosphere, 3,6-dibromodibenzofuran (1.0 mol), carbazole (2.0 mol), copper powder (3.0 mol), and potassium carbonate (1.5 mol) were admixed with one another in 300 ml of dimethyl acetamide (DMAc) and stirred for 24 hours at 130° C. The reaction solution obtained accordingly was cooled to room temperature, added with 1 L of toluene, and washed three times with distilled water. The solvent was distilled off from the organic phase under reduced pressure. The residues were purified by silica gel flash chromatography (n-heptane:toluene=4:1 to 3:1 (mass ratio)), obtaining Intermediate 1 with yield of 85%.

### Step 2: (Synthesis of Intermediate 2)

Under atmospheric conditions and room temperature, Intermediate 1 (0.5 mol) was dissolved in 100 ml of dimethyl formamide (DMF) and added with N-bromosuccinicimide (NBS) (2.0 mol) and stirred overnight at room temperature. The obtained precipitate was filtered and washed with methanol, obtaining Intermediate 2 with yield of 92%.

### Step 3: (Synthesis of Compound 5)

Under nitrogen atmosphere, Intermediate 2 (0.25 mol), 2-phenylpyridine (1.0 mol), ruthenium complex [(η6-C₆H₆)RuCl₂]₂ (0.05 mol), triphenylphosphine (0.2 mol), and potassium carbonate (12 mol) were admixed with one another in 3 L of N-methyl-2-pyrrolidone (NMP) and stirred overnight at 140° C.

After cooling the reaction solution to room temperature, it was added with 5 L of dichloromethane. The reaction solution was then filtered. The filtered solution was subjected to distillation under reduced pressure for removing the solvent (800 Pa, 80° C.), N-methyl-2-pyrrolidone (NMP) residues were purified by silica gel flash chromatography (CH₂Cl₂:Et₃N (triethylamine)=20:1 to 10:1 (mass ratio)).

Each fraction (residuals) was collected and the solvent was distilled off under reduced pressure. The residue was dissolved again in dichloromethane and washed three times with water. The organic phase was dried over anhydrous magnesium sulfate and the solvent was distilled off under reduced pressure, obtaining Compound 5 with yield of 68%.

[Conductive Pattern Portion with Translucency]

Having the translucency for the conductive pattern portion 17 of the present invention means that the total light transmittance of the conductive pattern portion 17 is 50% or more, and accordingly, it is difficult for the pattern portion to be visible and external scattering by moiré or scattering can be reduced. To achieve such performances, the film thickness of the conductive pattern portion 17 having a translucency, which is formed of silver or an alloy having silver as a main component, is preferably in the range of 4 to 9 nm. Meanwhile, as described herein, the film thickness of the conductive pattern portion 17 indicates a film thickness which is obtained by assumption that silver or an alloy having silver as a main component forms even film thickness. The film thickness can be obtained by calculation based on vapor deposition rate or quantification after extracting silver or an alloy having silver as a main component that is present per unit area. When the film thickness of the conductive pattern portion 17 is higher than 9 nm, the absorptive component or reflective component in that film thickness increases, and thus the transmittance lowers. On the other hand, when the film thickness of the conductive pattern portion 17 is less than 4 nm, conductivity at that film thickness is insufficient, and therefore undesirable. The total light transmittance of the conductive pattern portion 17 is more preferably 60% or more, and most preferably 70% or more. Meanwhile, the total light transmittance can be measured by preparing an aperture according to line width of the pattern portion. Alternatively, it can be also obtained by measuring the pattern portion of a solid prepared similarly. When an alloy having silver as a main component is used for the conductive pattern portion 17 having a translucency of the present invention, the content of silver in the alloy is preferably 50% by mass or more, and more preferably 60% by mass or more, from the viewpoint of obtaining the translucency described above and the conductivity described below.

The conductivity of the conductive pattern portion 17 is, in terms of sheet resistance of a solid portion produced similarly, preferably 50Ω/□ (square) or less, and more preferably 20Ω/□ or less.

In the present invention, in view of the fact that the conductive pattern hardly interferes the visibility because the conductive pattern portion 17 also has a translucency, the pattern line width can be designed suitably in accordance with an antenna, electromagnetic shielding performance, or the like. For example, the pattern line width can be between 10 μm and 10 mm, and preferably between 100 μm and 1 mm.

The conductive pattern portion 17 with a translucency is a layer which is formed by using silver or an alloy having silver as a main component, and the conductive pattern portion 17 is formed as a film on at least part of the base layer 15. Examples of the method for forming a film of the conductive pattern portion 17 include a method of using dry process like a vapor deposition method (resistance heating, EB method, or the like), a sputtering method, and a CVD method. Among them, the vapor deposition method is most preferably employed in the present invention. The conductive pattern portion 17 having a translucency is characterized in that, because it is formed as a film on top of the base layer 15, it has sufficient conductivity even without having a high temperature annealing treatment after film forming. However, if necessary, it may be the one obtained by performing a high temperature annealing treatment or the like after film forming.

Examples of the alloy having silver (Ag) as a main component, which constitutes the conductive pattern portion 17, include silver magnesium (AgMg), silver copper (AgCu), silver palladium (AgPd), silver palladium copper (AgPdCu), and silver indium (AgIn).

If necessary, the conductive pattern portion 17 described above may also have a constitution in which a layer of silver or an alloy having silver as a main component is divided into several layers and then laminated.

As for the method for forming a film of the conductive pattern portion 17 with a desired shape, a method of forming by vapor deposition method after preparing a mask with desired shape is most convenient, and it can be most desirably used.

As a method described above, a method of forming a pattern by using a common photolithography process after forming layer of silver or an alloy having silver as a main component, or, a method of pattern-printing of a composition containing a silver-removing agent on an area other than a conductive pattern portion followed by washing or the like can be also used. Among them, since the method of pattern-printing of a composition containing a silver-removing agent on an area other than a conductive pattern portion followed by washing is a simple process, it is a preferred pattern forming method.

As a composition of the silver-removing agent, a bleaching fixing agent which is used for a process of developing photosensitive materials for silver halide color photography can be desirably used.

As a bleaching agent used for the bleaching and fixing agent, a well-known bleaching agent can be used. However, organocomplex salt of iron (III) (for example, complex salt of aminopolycarboxylic acid) or organic acid such as citric acid, tartaric acid, or malic acid, persulfate, and hydrogen peroxide are preferable.

Among them, the organocomplex salt of iron (III) is particularly preferable from the viewpoint of quick treatment and prevention of environmental pollution. In particular, an iron complex of aminopolycarboxylic acid is preferable. Examples of the aminopolycarboxylic acid or salts thereof that are useful for forming an organocomplex salt of iron (III) include ethylene diaminesuccinic acid (SS form), N-(2-ethyl carboxylate)-L-asparaginic acid, betaalanine diacetic acid, and methylimino diacetic acid which have a biodegradability, and ethylene diamine tetraacetic acid, diehtylene triamine pentaaccetic acid, 1,3-diaminopropane tetraacetic acid, propylene diamine tetraacetic acid, nitrilotriacetic acid, cyclohexane diamine tetraacetic acid, imino diacetic acid, and glycol ether diamine tetraacetic acid, and also the compound represented by General Formula (I) or (II) of European Patent Publication No. 0789275. Those compounds can be any one of sodium, potassium, lithium, or ammonium salt. Among those compounds, ethylene diaminesuccinic acid (SS form), N-(2-ethyl carboxylate)-L-asparaginic acid, betaalanine diacetic acid, ethylene diamine tetraacetic acid, 1,3-diaminopropane tetraacetic acid, and methylimino diacetic acid are preferably in iron (III) complex salt form. Those ferric ion complex salts can be used in the form of complex salt or a ferric iron complex salt can be formed in a solvent by using ferric sulfate, ferric chloride, ferric nitrate, ferric sulfate ammonium, or ferric phosphate and a chelating agent like aminopolycarboxylic acid. The chelating agent can be used in an excess amount compared to the amount for forming a ferric iron ion complex salt. The addition amount of aminopolycarboxylic acid iron complex of iron (III) is 0.01 to 1.0 mol/liter, preferably 0.05 to 0.50 mol/liter, more preferably 0.10 to 0.50 mol/liter, and even more preferably 0.15 to 0.40 mol/liter.

The fixing agent used for a bleaching and fixing agent is a well-known fixing agent, a well-known water soluble silver halide dissolving agent including thiosulfate such as sodium thiosulfate or ammonium thiosulfate, thiocyanate such as sodium thiocyanate and ammonium thiocyanate, a thioether compound such as ethylene bisthioglycolic acid or 3,6-dithia-1-8-octane diol, and thioureas, and they can be used either singly or a mixture of two or more types. A special bleaching and fixing agent including a combination of a fixing agent described in Japanese Patent Application Laid-Open No. 55-155354 and a large amount of halide like potassium halide can be also used. In the present invention, use of thiosulfate, in particular ammonium thiosulfate, is preferable. The amount of the fixing agent per liter is preferably 0.3 to 2 mol, and more preferably in the range of 0.5 to 1.0 mol.

The pH range of the bleaching and fixing agent used in the present invention is preferably from 3 to 8, and particularly preferably from 4 to 7. To adjust pH, hydrochloric acid, sulfuric acid, nitric acid, bicarbonate salt, ammonia, caustic potassium, caustic soda, sodium carbonate, and potassium carbonate, or the like can be added, if necessary.

Other various defoaming agents or surfactant, and an organic solvent like polyvinyl pyrrolidone and methanol, or the like can be included in the bleaching and fixing agent. The bleaching and fixing agent preferably contains, as a preservative, a compound for releasing sulfite ions such as sulfite (for example, sodium sulfite, potassium sulfite, and ammonium sulfite), bisulfite (for example, ammonium bisulfite, sodium bisulfite, and potassium bisulfite), or meta bisulfite (for example, potassium metabisulfite, sodium metabisulfite, and ammonium metabisulfite) or arylsulfinic acid such as p-toluene sulfinic acid or m-carboxybenzene sulfinic acid. Those compounds are preferably contained at 0.02 to 1.0 mol/liter approximately, in terms of sulfite ions or sulfinic acid ions.

As a preservative, ascorbic acid, or carbonyl bisulfite adduct, or a carbonyl compound or the like can be added in addition to those described above. Further, a buffer agent, a chelating agent, a defoaming agent, an anti-fungal agent or the like may be added, if necessary.

It is preferable that the silver removing agent further contains a water soluble binder. Specific examples of the water soluble binder which is desirably used include ethylene-vinyl alcohol copolymer, polyvinyl alcohol, sodium polyacryalte, carbohydrates, or derivatives thereof. Examples of the carbohydrates or derivatives thereof include water soluble cellulose derivative and water soluble natural polymer. The water soluble cellulose derivative indicates a cellulose derivative such as methyl, hydroxyethyl, sodium carboxymethyl [sodium salt of carboxy methyl cellulose (hereinbelow, referred to as CMC)], or carboxy methyl. The water soluble natural polymer indicates starch, starch glue material, soluble starch, or dextrin, or the like. Among them, being easily soluble in water, CMC is preferable. Molecular weight of the water soluble binder can be arbitrarily selected based on required viscosity.

Examples of the method for pattern printing of a composition containing a silver removing agent include a printing method such as relief (letter print) printing, stencil (screen) printing, lithographic (off-set) printing, intaglio (gravure) printing, spray printing, and inkjet printing. In particular, it is preferably performed by gravure printing or screen printing. When the composition containing a silver removing agent of the present invention is used for pattern-printing of an area other than the conductive pattern portion of the present invention and subsequently a layer of silver or an alloy having silver as a main component in non-pattern portion is removed by washing treatment, a pattern can be formed.

<Translucent Electromagnetic Shield Member, Translucent Frequency Selective Electromagnetic Shield Member, and Translucent Antenna Member>

Another embodiment of the present invention relates to a translucent electromagnetic shield member, which is characterized in the translucent electromagnetic shield member obtained by using the translucent conductive patterned member of the aforementioned embodiment. Another embodiment of the present invention relates to a translucent frequency selective electromagnetic shield member, which is characterized in the translucent frequency selective electromagnetic shield member obtained by using the translucent conductive patterned member of the aforementioned embodiment. Still another embodiment of the present invention relates to a translucent antenna member, which is characterized in the translucent antenna member obtained by using the translucent conductive patterned member of the aforementioned embodiment.

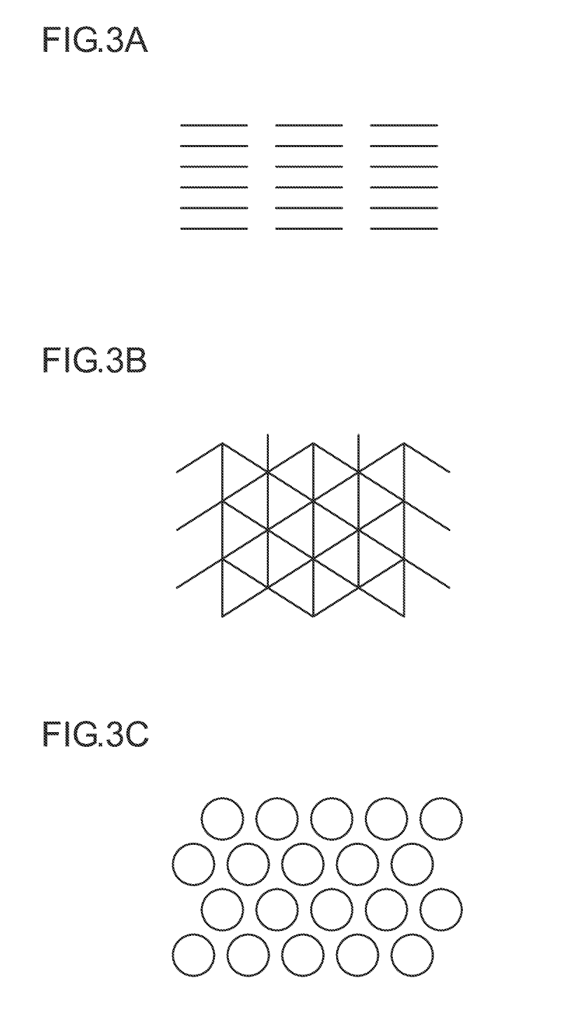

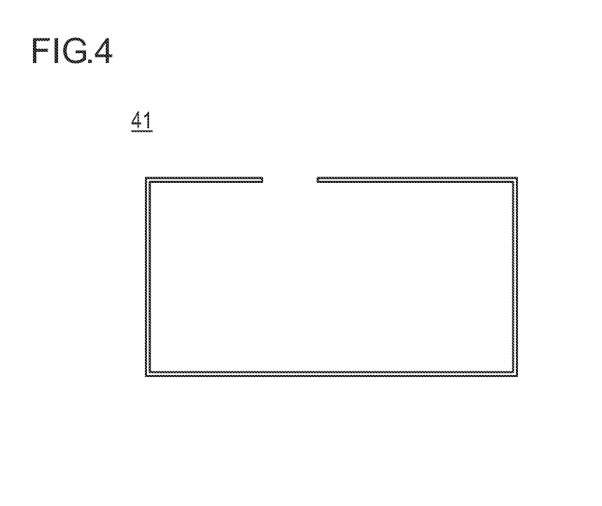

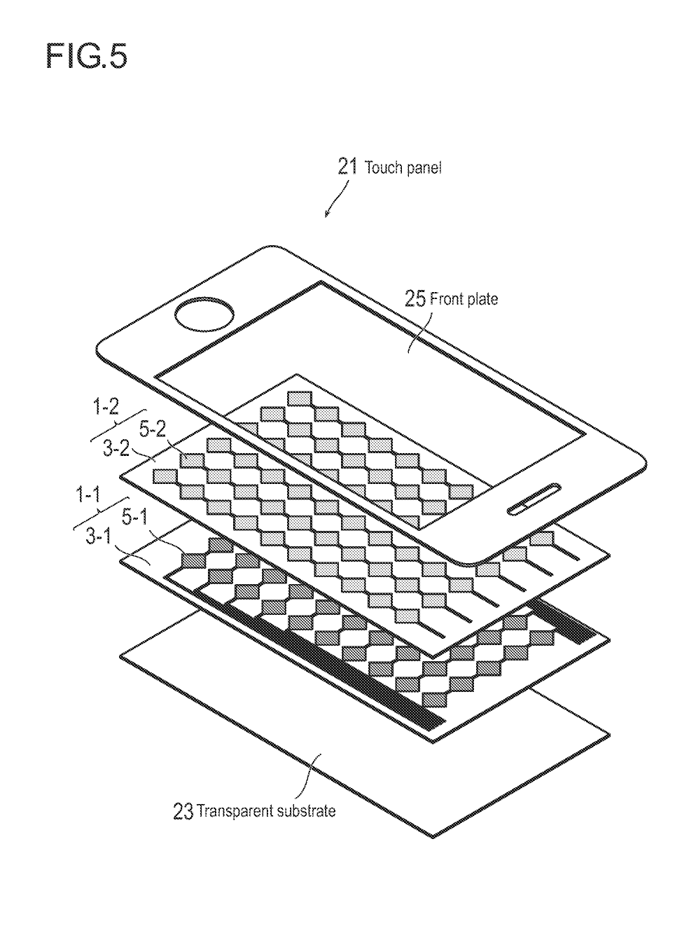

Explanations are given with regard to the shape (and use) of the conductive pattern portion 17 of the conductive patterned member 11 having a translucency of the present invention. In FIGS. 3A to 3C, several exemplary shapes of the conductive pattern portion are shown. In FIG. 4, as a shape (and its use) of the conductive pattern portion, an exemplary antenna pattern with an open end (an example of a translucent antenna member formed by using the translucent conductive patterned member) is shown. The shape (and its use) of the conductive pattern portion is not particularly limited, and it can be suitably determined depending on the use like electromagnetic shield (translucent electromagnetic shield member formed by using the translucent conductive patterned member) or a transparent antenna (translucent antenna member formed by using the translucent conductive patterned member). As an example, use as a translucent frequency selective electromagnetic shield member formed by using the translucent frequency selective electromagnetic shield member is described hereinbelow.

(Application to Translucent Frequency Selective Electromagnetic Shield Member)

When a conductive specimen is in the air and incident radio wave is applied to the plane, in a conductive portion (conductive pattern portion) with linear shape, the length of one side (electrical length) elongated from the center, is determined to be ¼ wavelength of the radio wave to be shielded (for a single shape, ½ wavelength) while having an open end shape for example, and the conductive portion is resonated to the wavelength to be shielded, the electromagnetic wave can be attenuated by reflection and scattering.

In case of having a closed ring shape (for example, a polygonal shape like rectangular shape or a circular shape (see, FIG. 3C)) instead of an open end shape, the peripheral length (electrical length) needs to be the same as the wavelength of the electromagnetic wave to be shielded.

By arranging either laterally or sterically the line-shaped conductive pattern portion at a pre-determined interval in the space or on a non-conductive material by taking the electromagnetic field reflecting equivalent area (scattering opening area) or electromagnetic field reflecting equivalent volume (scattering opening volume) of the line-shaped conductive portion (conductive pattern portion) into consideration (for example, a conductive pattern obtained by arranging laterally at a pre-determined interval a line-shaped (straight line shape) conductive portion with a pre-determined length as illustrated in FIG. 3A), the electromagnetic wave with the resonated frequency can be attenuated and shielded.

A small conductive pattern which is patterned like several examples of the shape of the conductive pattern portion of FIGS. 3A to 3C (see, FIGS. 3A and 3C) can shield specific frequency by specifying the length of the small conductive pattern. As a result, electromagnetic waves with other wavelength are allowed to pass through so that only specific electromagnetic wave can be shielded without shielding wireless or television radio waves, which requires collection of information from outside.

(Application to Translucent Electromagnetic Shield Member)

In case of electromagnetic shielding not requiring wavelength selectivity, in particular, a mesh pattern can be used as a shape of the conductive pattern portion (see, FIG. 1A and FIG. 5). The shape of the conductive pattern portion can be also a mesh-like pattern including a geometric figure combining a triangle (see, FIG. 3B), a quadrangle such as a square, a rectangle, a rhomboid, a parallelogram, or a trapezoid, a (regular) hexagon, a (regular) octagon, or the like.

(Application to Translucent Antenna Member)

When using for a television, a radio, a receiver antenna of a wireless LAN, an antenna for receiving and transmitting by a contactless IC card, or an antenna for a wireless tag, the shape of the conductive pattern portion can be suitably determined based on the frequency to receive. For example, with a pattern formed as a circulating whirlpool-shaped coil, a loop antenna is formed. Such antenna is suitable for receiving of AM frequency band.

Other antenna pattern includes a linear pattern in which length of one side corresponds to ¼ wavelength frequency of a target radio wave (for example, see the square-shaped antenna pattern 41 with an open end illustrated in FIG. 4). It can be designed as an antenna for FM frequency band or TV frequency band. Meanwhile, when it is used for such antenna pattern, one end or both ends of the pattern are connected to a power supply.

<Touch Panel>

Another embodiment of the present invention relates to a touch panel, which is characterized in that the touch panel is obtained by using the translucent conductive patterned member of the aforementioned embodiment as a transparent electrode for a touch panel.

(Constitution for Providing a Bilayer Transparent Electrode Using the Translucent Conductive Patterned Member of the Embodiment of the Present Invention on a Transparent Substrate)

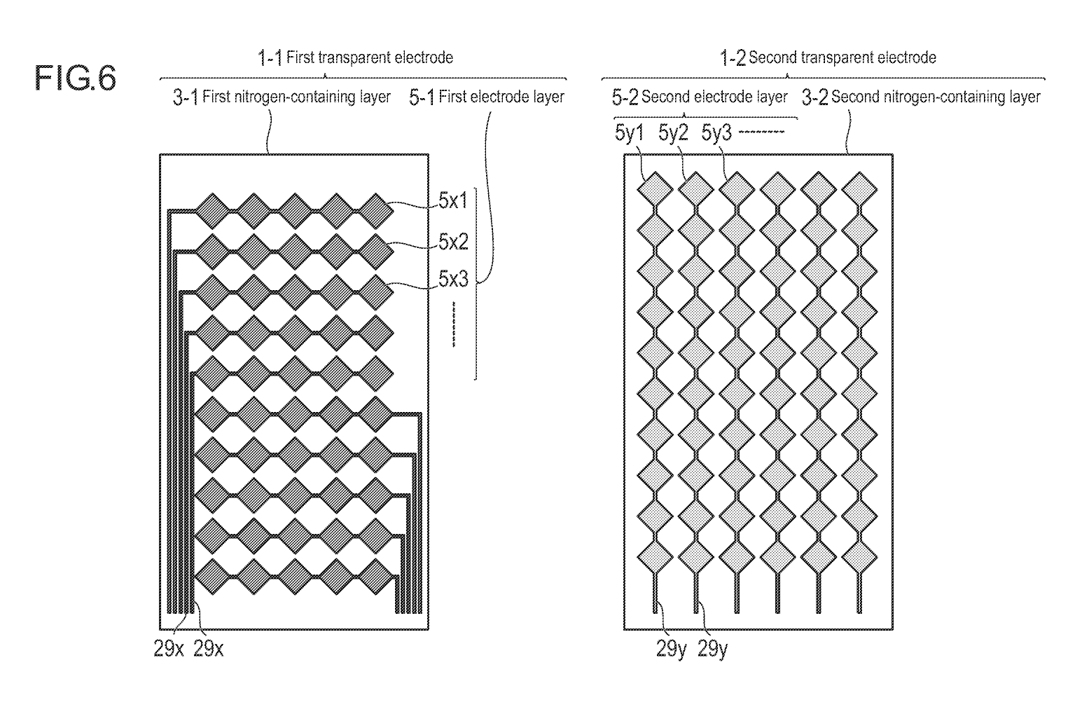

FIG. 5 is a perspective view illustrating an outline constitution of the touch panel 21 in which the translucent conductive patterned member of the embodiment of the present invention is used as the transparent electrodes 1-1 and 1-2 for a touch panel. FIG. 6 is a planar view of two pieces of the transparent electrode 1-1 and 1-2 (a translucent conductive patterned member of the embodiment of the present invention) for illustrating the electrode configuration of the touch panel 21.

The touch panel 21 illustrated in FIGS. 5 and 6 is a projection type capacitive touch panel. In the touch panel 21, the first transparent electrode 1-1 using the translucent conductive patterned member and the second transparent electrode 1-2 using the translucent conductive patterned member are arranged in the order on top of one main plane of the transparent substrate 23 and the top part is covered with the front plate 25.

The first transparent electrode (translucent conductive patterned member) 1-1 has the first nitrogen-containing layer (base layer) 3-1 and the first electrode layer (conductive pattern portion) 5-1 provided on the first nitrogen-containing layer 3-1. The first electrode layer 5-1 is an electrode layer which is provided in the first transparent electrode 1-1 for a touch panel, and the first electrode layer 5-1 is constituted as plural x electrode pattern 5x1, 5x2, . . . that are patterned on the first nitrogen-containing layer 3-1 (see, FIG. 6). Each x electrode pattern 5x1, 5x2, . . . is arranged in parallel embodiment while maintaining an interval between them, in which each is provided in elongated state in x direction. Each x electrode pattern 5x1, 5x2, . . . has a shape (shape of conductive pattern portion) that is obtained by connecting the pattern portions of diamond shape, which are arranged in x direction, linearly in x direction at the top part of the diamond.

Further, x wire 29x is connected to the end of each of x electrode pattern 5x1, 5x2, . . . . The x wire 29x is wired in the periphery region on the transparent substrate 23 and the x wire 29x is drawn to the peripheral end of the transparent substrate 23. Similar to x electrode pattern 5x1, 5x2, each x wire 29x can be constituted as the first electrode layer 5-1 which has silver as a main component, or constituted as an electrode layer that is separately formed.

The second transparent electrode (translucent conductive patterned member) 1-2 is configured by having the second nitrogen-containing layer (base layer) 3-2 and the second electrode layer (conductive pattern portion) 5-2 provided on the second nitrogen-containing layer 3-2. The second electrode layer 5-2 is an electrode layer which is formed by being provided in the second transparent electrode 1-2 for a touch panel, and the second electrode layer 5-2 is constituted as plural y electrode pattern 5y1, 5y2, . . . that are patterned on the second nitrogen-containing layer 3-2 (see, FIG. 6). Each y electrode pattern 5y1, 5y2, . . . is arranged in parallel embodiment while maintaining an interval between them, in which each is provided in elongated state in y direction so as to be perpendicular to x electrode pattern 5x1, 5x2, . . . . Each y electrode pattern 5y1, 5y2, . . . has a shape (shape of conductive pattern portion) that is obtained by connecting the pattern portions of diamond shape, which are arranged in y direction, linearly in y direction at the top part of the diamond.

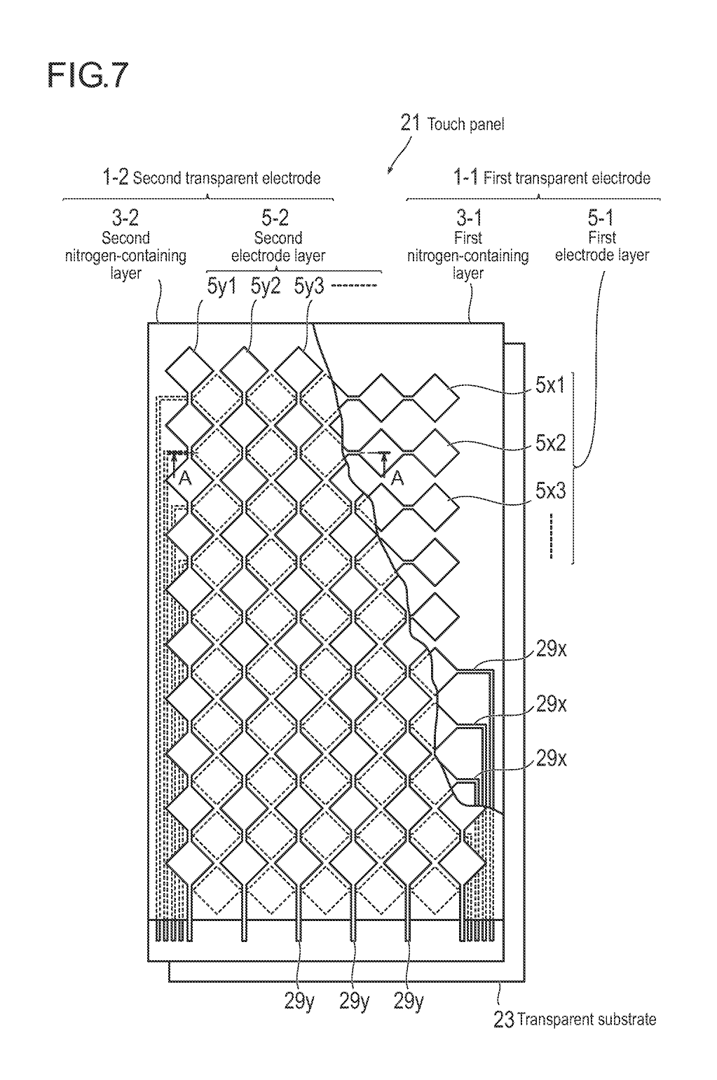

As illustrated in FIG. 7, the diamond-shaped pattern portion constituting each y electrode pattern 5y1, 5y2, . . . is arranged on a position which does not allow any overlap when viewed from a plane of the diamond-shaped pattern portion constituting each x electrode pattern 5x1, 5x2, . . . so that the diamond-shaped pattern portion can occupy as much area as possible within a range of having no overlap. Accordingly, a constitution is achieved in which x electrode pattern 5x1, 5x2, . . . , constituted as the first electrode layer 5-1 and y electrode pattern 5y1, 5y2, . . . , constituted as the second electrode layer 5-2 are hardly visible in the center area of the transparent substrate 23.

Only at the connection part of the diamond-shaped electrode pattern, each y electrode pattern 5y1, 5y2, . . . is laminated with each x electrode pattern 5x1, 5x2, . . . . The second nitrogen-containing layer 3-2 is sandwiched between the laminated portions, and accordingly, a state in which the electric insulation between x electrode pattern 5x1, 5x2, . . . and y electrode pattern 5y1, 5y2, . . . is ensured is obtained.

Further, y wire 29y is connected to the end of each of y electrode pattern 5y1, 5y2, . . . . The y wire 29y is wired in the periphery region on the transparent substrate 23 and the y wire 29y is drawn to the peripheral end of the transparent substrate 23, side by side with x wire 29x. Similar to y electrode pattern 5y1, 5y2, each y wire 29y can be constituted as the second electrode layer 5-2 which has silver as a main component, or constituted as an electrode layer that is separately formed.

Meanwhile, there is a constitution in which x wire 29x and y wire 29y drawn to the peripheral end of the transparent substrate 23 are connected with a flexible print substrate or the like.

(Front Plate 25)

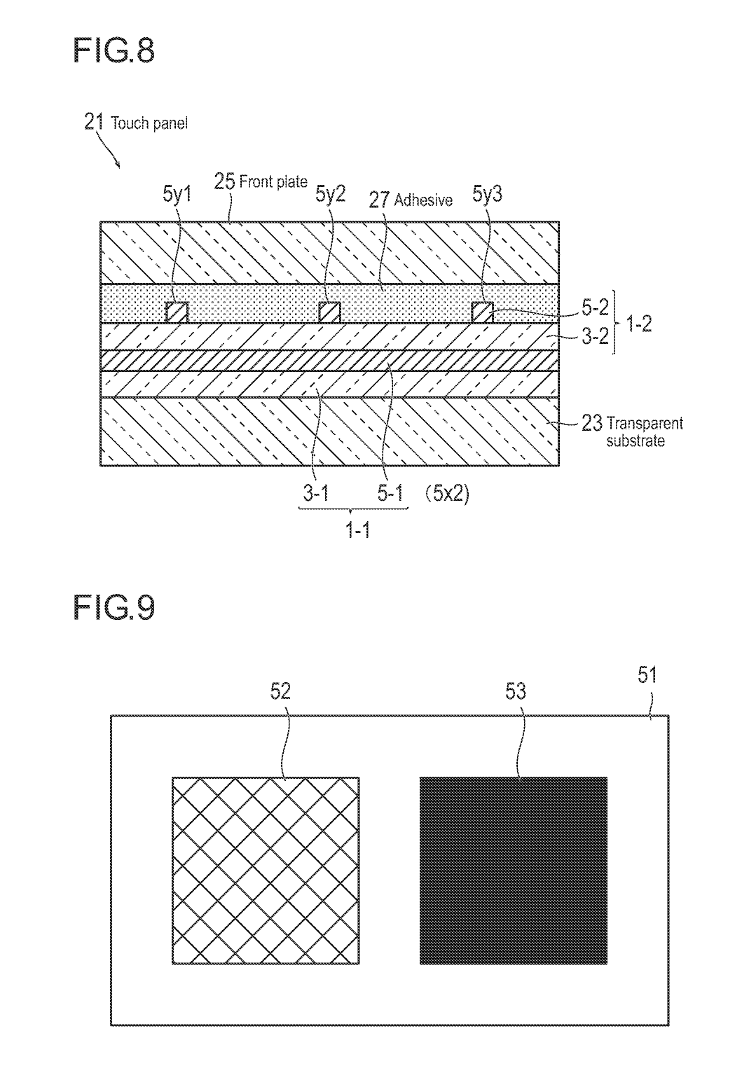

The front plate 25 illustrated in FIG. 5 and FIG. 8 is a board in which the portion corresponding to the input position of the touch panel 21 receives pressure. The front plate 25 is a board having an optical transparency and the same material as the transparent substrate 23 is used. Further, for the front plate 25, a material having optical properties as required can be selected and used. The front plate 25 is bonded to the second transparent electrode 1-2 via the adhesive (layer) 27, for example (see, FIG. 8). The adhesive 27 is not particularly limited in terms of material, as long as it has an optical transparency.

Further, the front plate 25 is provided with a light shielding film to cover the periphery of the transparent substrate 23 so as to prevent visible recognition of x wire 29x drawn from x electrode pattern 5x1, 5x2, . . . and y wire 29y drawn from y electrode pattern 5y1, 5y2, . . . , from the front plate 25 side.

(Operation of Touch Panel)

For operating the touch panel 21 described above, voltage is applied from a flexible print substrate or the like connected with x wire 29x and y wire 29y to x electrode pattern 5x1, 5x2, . . . and y electrode pattern 5y1, 5y2, . . . . In such state, when the surface of the front plate 25 is touched by a finger or touch pen, capacitance in each portion present in the touch panel 21 changes and the capacitance is exhibited as a change in voltage of x electrode pattern 5x1, 5x2, . . . and y electrode pattern 5y1, 5y2, . . . . This change varies according to the distance from the point of touch by a finger or a touch pen, and the change is the strongest at the point of touch by the finger or the touch pen. For such reasons, the location addressed as x electrode pattern 5x1, 5x2, . . . and y electrode pattern 5y1, 5y2, . . . , which shows the highest voltage change, is detected as a position touched by the finger or the touch pen.

Meanwhile, in the translucent conductive patterned member 11 having a laminate structure including the base layer 15 and the conductive pattern portion 17 having a translucency, which is formed as a film on at least part of the base layer, and an application member thereof (translucent electromagnetic shield member, translucent frequency selective electromagnetic shield member, translucent antenna member, and touch panel), the top part of the conductive pattern portion 17 having a translucency may be covered with a protective film (not illustrated) or laminated with a separate conductive layer (not illustrated). In such case, in order to avoid any inhibition of the optical transparency of translucent conductive patterned member 11 or an application member thereof, the protective film and the conductive layer preferably have an optical transparency. Further, there can be also a constitution in which a layer as required is provided underneath the base layer 15, between the base layer 15 and the base 13 (for example, the protective layer 14 illustrated in FIGS. 2A and 2B).

The region other than the conductive pattern portion 17 of the translucent conductive patterned member 11 or an application member thereof (translucent electromagnetic shield member, translucent frequency selective electromagnetic shield member, translucent antenna member, and touch panel) preferably has an optical transparency. Further, since the conductive pattern portion 17 also has a translucency, the member 11 is also expected to have a high optical transparency. Specifically, the total light transmittance of the translucent conductive patterned member 11 is preferably 70% or higher, more preferably 75% or higher, and most preferably 80% or higher. As described herein, the total light transmittance of the translucent conductive patterned member 11 can be obtained as follows. Specifically, by measuring the total light transmittance of a 3 cm×3 cm (width x length) sample using HAZE METER NDH5000 (manufactured by Nihon Denshoku, Tokyo, Japan), the total light transmittance of a translucent conductive patterned member can be obtained.

### EXAMPLES

Hereinbelow, the present invention is described by way of examples, but the present invention is not limited to them. Meanwhile, the description of “%” used in the examples indicates “% by mass”, unless described specifically otherwise.

[Manufacture of Translucent Conductive Patterned Member 101 (Sample 101)]

A commercially available transparent PET substrate (Cosmo Shine A4100, manufactured by Toyo Boseki, K.K., film thickness of 100 μm) was fixed in a substrate holder of a commercially available apparatus for vacuum vapor deposition such that a base layer and a silver layer are provided on a surface not having an easy sliding layer. The following TPD was put into a resistance heating board made of tantalum, then, the substrate holder and the heating board were installed in the first vacuum bath of the apparatus for vacuum vapor deposition. Silver (Ag) was put into a resistance heating board made of tungsten and installed in the second vacuum bath.

In the same state, the first vacuum bath was de-pressurized to 4×10⁻⁴ Pa first, the heating board holding TPD was heated with electric current, and a base layer including TPD with film thickness of 25 nm was formed on the substrate at vapor deposition rate of 0.1 nm/sec to 0.2 nm/sec. Herein, the film thickness of the base layer was measured by using a quartz vibration type film thickness meter (ditto for the followings).

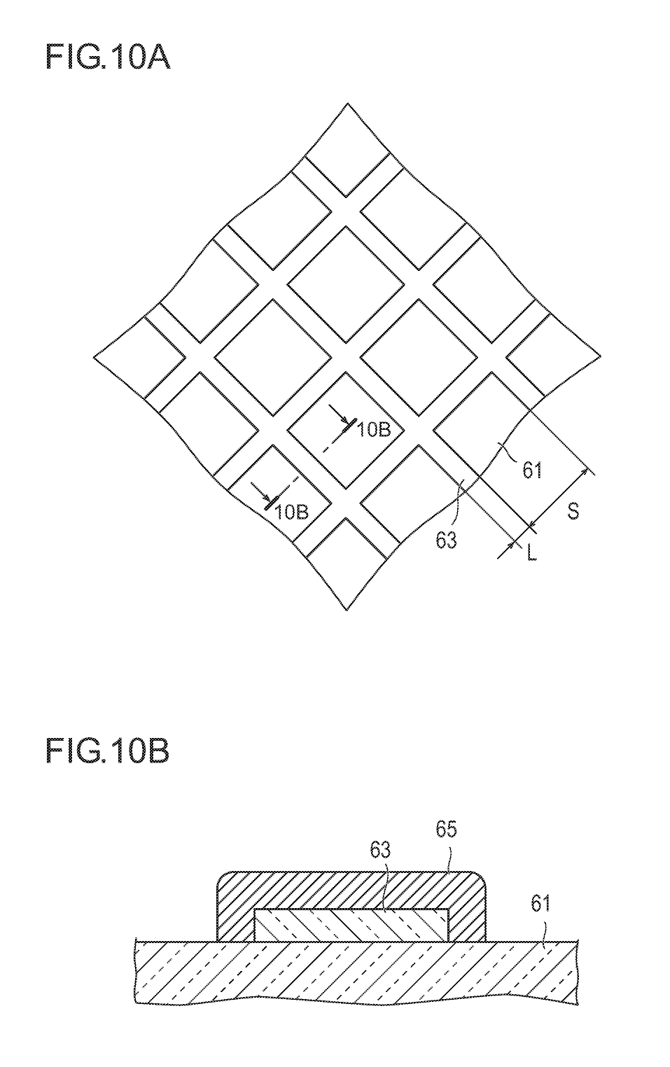

Next, the substrate formed with a base layer as a film was transferred to the second vacuum bath while the substrate still remained in a vacuum state and a separately prepared aluminum mask (see, FIG. 9) was applied on the substrate side formed with a base layer as a film. The second vacuum bath was de-pressurized to 4×10⁻⁴ Pa first, the heating board holding silver was heated with electric current, thereby, a conductive pattern portion including silver with film thickness of 8 nm was formed at vapor deposition rate of 0.1 nm/sec to 0.2 nm/sec. As a result, the translucent conductive patterned member 101 (Sample 101) having a laminate structure including the base layer and the conductive pattern portion formed on part of the top of the base layer was obtained. Meanwhile, the silver film thickness described herein means film thickness calculated from the deposition amount of silver under the assumption that silver is formed as an even film (ditto for the followings). FIG. 9 is a planar schematic diagram illustrating the mesh-shaped conductive pattern portion 52 of Sample 101 having a translucency and including silver which was formed on the base layer (not illustrated) including TPD as provided on the PET base 51 by using an aluminum mask pattern, and the solid portion 53 having a translucency for evaluation, which includes silver. Herein, the size of the

PET substrate 51 used was 5 cm×9 cm. The mesh-shaped conductive pattern portion 52 had a size of 3 cm×3 cm, and the mesh pattern with L/S=1 mm/4 mm was used as a pattern shape. FIG. 10A is a planar schematic diagram for describing L/S of the mesh-shaped (lattice-shaped) pattern portion. Herein, as illustrated in FIG. 10A, L/S represents Line (pattern line width; L)/Space (mesh opening width; S) of the mesh-shaped pattern portion 63 formed on top of the base layer 61. The solid portion 53 for evaluation of FIG. 9 is formed for evaluating the total light transmittance and conductivity, and the size was the same as the size of the mesh-shaped conductive pattern portion 52, 3 cm×3 cm. Meanwhile, the aluminum mask pattern was an opposite (negative) pattern of FIG. 9.

Meanwhile, the base layer material (TPD) of Sample 101 is a compound containing nitrogen as the following structure.

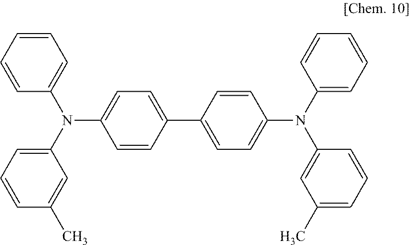 [SMILES: Cc1cccc(N(c2ccccc2)c2ccc(-c3ccc(N(c4ccccc4)c4cccc(C)c4)cc3)cc2)c1]

[Manufacture of Translucent Conductive Patterned Members 102 to 109 (Samples 102 to 109)]

The translucent conductive patterned members 102 to 109 (Samples 102 to 109) were manufactured in the same manner as Sample 101 except that the base layer material and silver film thickness were modified to those described in Table 1.

Meanwhile, as described below, the base layer material (porphyrin derivative) of Sample 102 is a compound containing a hetero cycle as the following structure in which a nitrogen atom is contained as a hetero atom.

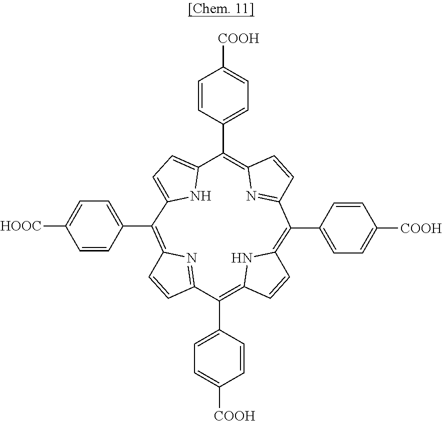 [SMILES: O=C(O)c1ccc(-c2c3nc(c(-c4ccc(C(=O)O)cc4)c4ccc([nH]4)c(-c4ccc(C(=O)O)cc4)c4nc(c(-c5ccc(C(=O)O)cc5)c5ccc2[nH]5)C=C4)C=C3)cc1]

Further, the base layer material (Compound 99) of Sample 103, the base layer material (Compound 94) of Sample 104, the base layer material (Compound 10) of Samples 105 to 108, and the base layer material (Compound 112) of Sample 109 have a structure which has been shown above as a base layer material. Among them, Compound 99 corresponds to General Formula (1), Compound 94 corresponds to General Formula (2), Compound 10 has a pyridine group and also corresponds to General Formula (3), and Compound 112 corresponds to General Formula (1).

[Manufacture of Translucent Conductive Patterned Member 110 (Sample 110)]

First, on the same PET substrate as Sample 101, the following anchor layer coating liquid 1 was coated using a spin coater while controlling the revolution number to have dry film thickness of 30 nm, followed by a drying treatment at 120° C. for 10 minutes.

<Anchor Layer Coating Liquid 1>

| | |
|---|---|
| Toluene | 83 g |
| Methyl ethyl ketone | 15 g |
| Polymethyl methacrylate | 2 g |

Next, a coating liquid obtained by dissolving 0.75 g of the above Compound 112 in 100 g of 2,2,3,3-tetrafluoro-1-propanol was coated using a spin coater under the conditions of 30 seconds at 1500 rpm. Next, the resultant was heated for 30 minutes to have substrate surface temperature of 120° C., and thus abase layer including Compound 112 was obtained. The film thickness of the base layer was 25 nm.

Next, the substrate formed with a base layer was fixed in a substrate holder of a commercially available apparatus for vacuum vapor deposition, and after adding silver to a heating board made of tungsten, the substrate was installed in a vacuum bath of the apparatus for vacuum vapor deposition. Next, without using the mask which was used in Sample 101, the vacuum bath was de-pressurized to 4×10⁻⁴ Pa, the heating board holding silver with electric current, then, a conductive layer including silver with film thickness of 8 nm was formed on the substrate at vapor deposition rate of 0.1 nm/sec to 0.2 nm/sec. Meanwhile, the film thickness of the conductive layer including silver, which is described herein, means a film thickness calculated from the deposition amount of silver under the assumption that silver formed an even film.

Further, the viscosity of the following silver removing agent BF-1 was controlled to be 10000 cp by using Na carboxy methyl cellulose (manufactured by SIGMA-ALDRICH Co. LLC.; C5013, hereinbelow abbreviated as CMC), by using a polyester mesh for screen printing formed with a printing pattern that was opposite to the mask used for Sample 101, screen printing was performed such that the coating film thickness on the conductive layer was 30 μm. After the printing, it was left for 1 minute followed by a washing treatment to manufacture the translucent conductive patterned member 110 (Sample 110).

<Preparation of Silver Removing Agent BF-1>

| | |
|---|---|
| Ferric ammonium ethylenediamine tetraacetate | 60 g |
| Ethylenediamine tetraacetate | 2 g |
| Sodium metabisulfite | 15 g |
| Ammonium thiosulfate | 70 g |
| Maleic acid | 5 g |

After adjusting to 1 L with pure water, pH was adjusted to 5.5 with sulfuric acid or ammonia water to prepare the silver removing agent BF-1.

[Manufacture of Translucent Conductive Patterned Member 111 (Sample 111)]

The translucent conductive patterned member 111 (Sample 111) was manufactured in the same manner as Sample 107 except that, after de-pressurization of the second vacuum bath to 4×10⁻⁴ Pa, the vapor deposition rate was controlled such that ratio of copper to silver was 3% by mass (silver:copper=100:3 (mass ratio)) by heating independently the heating board holding silver and the heating board containing copper by separately applying electric current, and the conductive pattern portion including silver and copper with film thickness of 8 nm was formed.

[Manufacture of Translucent Conductive Patterned Member 112 (Sample 112)]

The translucent conductive patterned member 112 (Sample 112) was manufactured in the same manner as Sample 107 except that a transparent alkali-free glass substrate was used instead of the PET substrate.

[Manufacture of Comparative Samples 201 to 203]

The Samples 201 to 203 were manufactured in the same manner as Sample 101 except that no base layer was formed and the silver film thickness was modified to those described in Table 1.

[Manufacture of Comparative Sample 204]

On a surface not having an easy sliding layer of a commercially available transparent PET substrate (Cosmo Shine A4100, manufactured by Toyo Boseki, K.K., film thickness of 100 μm), a 40 nm of ITO thin film layer including oxide of indium and tin was formed by using direct current magnetron sputtering method. To form the ITO thin film layer, a calcined product of indium oxide and tin oxide [In₂O₃:SnO₂=90:10 (mass ratio)] was used as a target and argon and oxygen mixture gas (total pressure of 266 mPa, oxygen partial pressure of 5 mPa) was used as sputtering gas.

Subsequently, by using a commercially available apparatus for vacuum vapor deposition, the aluminum mask which was the same as that of Sample 101 was put on a substrate surface on which the ITO thin film layer was formed. After de-pressurization to 4×10⁻⁴ Pa, the heating board holding silver was heated by applying electric current. As a result, a conductive pattern portion including silver with film thickness of 15 nm was formed at vapor deposition rate of 0.1 nm/sec to 0.2 nm/sec. Further, a 89 nm of ITO thin film layer was formed as described above, and the comparative example 204 was manufactured.

[Manufacture of Comparative Sample 205]

[Manufacture of Member Having Conductive Pattern Portion without Translucency by Plating Method]

<Manufacture of Coating Preparation 1>

2.1 mmol of polyoxyethylene alkyl ether-based non-ionic surface active agent (EMULGEN 409P, manufactured by Kao Corporation) was dissolved in 100 mL of ion exchange water, and subsequently added with 21.2 mmol of pyrrole monomer. After stirring for 30 minutes and addition of 50 mL (corresponding to 6 mmol) of 0.12 M aqueous solution of ammonium persulfate, the reaction was allowed to occur for 1 hour at 20° C. (polymerization rate of 52%, average particle diameter of 86 nm). Subsequently, 25 mL of dihydroterpineol was added and stirred for 4 hours. Upon the completion of stirring, the organic phase was collected and washed several times with ion exchange water to obtain dispersion of reducing polypyrrole fine particles with a reducing ability, which was dispersed in dihydroterpineol.

The solid matter of the reducing polypyrrole fine particles in dihydroterpineol obtained from above was about 1.3% by mass. Herein, by adding 1 part by mass of Super Beckamine J-820: melamine-based (manufactured by DIC corporation) per 1 part by mass of the reducing polypyrrole fine particles, the coating preparation 1 was prepared.

On a surface having an easy sliding layer of a commercially available transparent PET substrate (Cosmo Shine A4100, manufactured by Toyo Boseki, K.K., film thickness of 100 μm), the coating preparation 1 was printed by using a commercially available gravure printer so that the coating had a lattice shape in which L/S=100 μm/500 μm, film thickness was 100 nm, and opening ratio was 70%. After that, the resultant was placed in a drying oven at 120° C. and dried for 10 minutes. The film formed with a coating layer of the coating preparation 1 was impregnated in an aqueous solution of 0.02% palladium chloride—0.01% hydrochloric acid for 7 minutes at 35° C. and washed with tap water. Next, the film was impregnated for 5 minutes at 35° C. in ATS Add Copper IW bath (manufactured by Okuno Chemical Industries Co., Ltd.), which was an electroless copper plating bath, for copper plating with film thickness of 100 nm, thus obtaining Comparative Sample 205. FIG. 10A is a planar schematic diagram for describing L/S of the mesh-shaped (lattice-shaped) pattern portion. FIG. 10B is a cross-sectional schematic diagram of FIG. 10A (after plating) along the line 10B-10B for illustrating the constitution of the pattern portion of Comparative Sample 205. Herein, as illustrated in FIG. 10A, L/S represents Line (pattern line width; L)/Space (mesh opening width; S) of the lattice-shaped (mesh-shaped) pattern portion 63 of the coating layer of the coating preparation 1 (lattice-shaped print), which was formed on top of the PET substrate 61 (easy sliding layer). With regard to the cross-sectional configuration of Comparative Sample 205 after plating, as illustrated in FIG. 10B, the cross-sectional configuration was that: the lattice-shaped (mesh-shaped) pattern portion 63 of the coating layer (lattice-shaped print) of the coating preparation 1 with film thickness of 100 nm was formed on the PET substrate (easy sliding layer) 61 and the copper plating (layer) 65 with film thickness of 100 nm was formed on a surface (lateral surface and top surface) of the pattern portion 63. With regard to a method to measure a film thickness of the coating layer (lattice-shaped print) of the coating preparation 1, a thin specimen of the sample was produced by using a focused ion beam (FIB) processing apparatus, and by observation using a transmission type electron microscope (TEM), the film thickness was obtained.

(FIB Processing)

Apparatus: SMI2050 manufactured by Seiko Instruments Inc.

Ions for processing: (Ga 30 kV)

Sample thickness: 200 nm

### (TEM Observation)

Apparatus: JEM2000FX manufactured by JEOL Ltd.

(acceleration voltage: 200 kV)

Time for irradiation with electron beam: 30 seconds.

[Manufacture of Comparative Sample 206]

The Comparative Sample 206 was manufactured in the same manner as Sample 101 except that the following spiro-DPVBi was used as a base material.

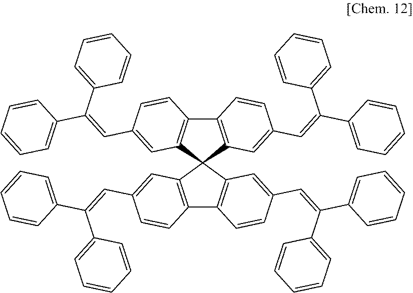

<Evaluation>

Total light transmittance and conductivity of the conductive pattern portion having a translucency were obtained by examining the solid portion of the conductive film for evaluation with translucency, which had size of 3 cm×3 cm and was formed on the sample.

The sheet resistance value (surface resistivity) and total light transmittance were measured by using a resistivity meter (LORESTA GP (MCP-T610 type), manufactured by Dia Instrument Co., Ltd.) and HAZE METER NDH5000 (manufactured by Tokyo Denshoku), respectively. The obtained results are given in Table 1.

<Evaluation of Electromagnetic Shield>

The average value of the measurement results obtained in the frequency range of 10 MHz to 1 GHz by using KEC method was obtained, and the electromagnetic shield property was evaluated according to the following index (evaluation criteria). The evaluation results are given in Table 1.

◯; 15 db or more

Δ; 10 or more and less than 15

ΔX; 5 or more and less than 10

X; less than 5.

<Evaluation of Visibility>

On a table-top Schaukasten, the sample was placed and observed at a distance of 50 cm. The visibility was evaluated according to the following index (evaluation criteria). The evaluation results are given in Table 1.

◯; Pattern is not visible

◯Δ; Pattern can be visible with careful observation

Δ; Pattern can be visible but not at problematic level

X; Pattern is clearly visible at problematic level

TABLE 1

| | | | | | | | | | Pattern portion | | | | |
|---|---|---|---|---|---|---|---|---|---|---|---|---|---|
| | | | | | | | Calcu- | | Sheet | | Translucent patterned member | | |
| | | | | | | | lated | | resis- | Trans- | | | Member- |
| | | | | | | | film | | tance | mit- | Vis- | Electro- | penetrat- |
| | | | Sub- | | Method for | Metal | thick- | Patterning | value | tance | ibil- | magnetic | ing ratio |
| Sample | | | strate | Base | installation | species | ness | method | (Ω/□) | (%) | ity | shield | (%) |
| 201 | No base | Compar- | PET | Non | | Silver | 8 | Mask vapor | Impos- | 52 | ∘Δ | x | 74 |
| | 8 nm | ison | | | | | | deposition | sible to | | | | |
| | | | | | | | | | measure | | | | |
| 202 | No base | Compar- | PET | Non | | Silver | 10 | Mask vapor | 450 | 42 | Δ | x | 72 |
| | 10 nm | ison | | | | | | deposition | | | | | |
| 203 | No base | Compar- | PET | Non | | Silver | 15 | Mask vapor | 52 | 38 | x | Δx | 69 |
| | 15 nm | ison | | | | | | deposition | | | | | |
| 204 | ITO/Ag | Compar- | PET | ITO | Sputtering | Silver | 15 | Mask vapor | 47 | 35 | x | Δ | 68 |
| | (15 nm)/ | ison | | | | | | deposition | | | | | |
| | ITO | | | | | | | | | | | | |
| 205 | Plating | Compar- | PET | No | | Copper | (100) | — | 2 | 0 | x | ∘ | 56 |
| | 100 nm | ison | | | | | | | | | | | |
| 206 | spiro- | Compar- | PET | spiro- | Vapor | Silver | 8 | Mask vapor | Impos- | 54 | ∘Δ | x | 75 |
| | DPVBi | ison | | DPVB1 | deposition | | | deposition | sible to | | | | |
| | | | | | | | | | measure | | | | |
| 101 | TPD | Present | PET | TPD | Vapor | Silver | 8 | Mask vapor | 43 | 55 | ∘Δ | Δ | 76 |
| | 8 nm | invention | | | deposition | | | deposition | | | | | |
| 102 | Porphyrin | Present | PET | Porphyrin | Vapor | Silver | 8 | Mask vapor | 32 | 59 | ∘Δ | Δ | 77 |
| | 8 nm | invention | | derivative | deposition | | | deposition | | | | | |
| 103 | Com- | Present | PET | Com- | Vapor | Silver | 8 | Mask vapor | 13 | 66 | ∘ | ∘ | 80 |
| | pound 94 | invention | | pound 94 | deposition | | | deposition | | | | | |
| | 8 nm | | | | | | | | | | | | |
| 104 | Com- | Present | PET | Com- | Vapor | Silver | 8 | Mask vapor | 17 | 64 | ∘ | ∘ | 79 |
| | pound 99 | invention | | pound 99 | deposition | | | deposition | | | | | |
| | 8 nm | | | | | | | | | | | | |
| 105 | Com- | Present | PET | Com- | Vapor | Silver | 3 | Mask vapor | 48 | 76 | ∘ | Δ | 83 |
| | pound 10 | invention | | pound 10 | deposition | | | deposition | | | | | |
| | 3 nm | | | | | | | | | | | | |
| 106 | Com- | Present | PET | Com- | Vapor | Silver | 5 | Mask vapor | 14 | 72 | ∘ | ∘ | 82 |
| | pound 10 | invention | | pound 10 | deposition | | | deposition | | | | | |
| | 5 nm | | | | | | | | | | | | |
| 107 | Com- | Present | PET | Com- | Vapor | Silver | 8 | Mask vapor | 11 | 71 | ∘ | ∘ | 81 |
| | pound 10 | invention | | pound 10 | deposition | | | deposition | | | | | |
| | 8 nm | | | | | | | | | | | | |
| 108 | Com- | Present | PET | Com- | Vapor | Silver | 10 | Mask vapor | 9 | 57 | ∘Δ | ∘ | 76 |
| | pound 10 | invention | | pound 10 | deposition | | | deposition | | | | | |
| | 10 nm | | | | | | | | | | | | |
| 109 | Vapor | Present | PET | Com- | Vapor | Silver | 8 | Mask vapor | 15 | 62 | ∘ | ∘ | 79 |
| | deposition | invention | | pound 112 | deposition | | | deposition | | | | | |
| | of Com- | | | | | | | | | | | | |
| | pound 112 | | | | | | | | | | | | |
| | 8 nm | | | | | | | | | | | | |
| 110 | Coating of | Present | PET | Com- | Coating | Silver | 8 | Removal of | 19 | 62 | ∘ | ∘ | 78 |
| | Com- | invention | | pound 112 | | | | silver | | | | | |
| | pound 112 | | | | | | | | | | | | |
| | 8 nm/ | | | | | | | | | | | | |
| | Removal | | | | | | | | | | | | |
| | of silver | | | | | | | | | | | | |
| 111 | Com- | Present | PET | Com- | Vapor | Silver/ | 8 | Mask vapor | 10 | 71 | ∘ | ∘ | 81 |
| | pound 10 | invention | | pound 10 | deposition | Copper | | deposition | | | | | |
| | 8 nm | | | | | | | | | | | | |
| | alloy | | | | | | | | | | | | |
| 112 | Com- | Present | Glass | Com- | Vapor | Silver | 8 | Mask vapor | 6 | 70 | ∘ | ∘ | 83 |
| | pound 10 | invention | | pound 10 | deposition | | | deposition | | | | | |
| | 8 nm | | | | | | | | | | | | |

### Example 2

### Manufacture of Frequency Selective Electromagnetic Shield Member

A frequency selective electromagnetic shield member was manufactured in the same manner as Sample 107 except that the mask pattern was changed to a photomask which was formed such that the unit length of a linear antenna element was 79 mm, the line width was 40 μm, and the interval between linear antenna element was 300 μm (the photomask (negative) pattern has an opposite pattern to the linear antenna pattern of FIG. 3A). As a result, the reflection characteristics near 2 G (1.90 GHz; wavelength of 158 mm) was confirmed.

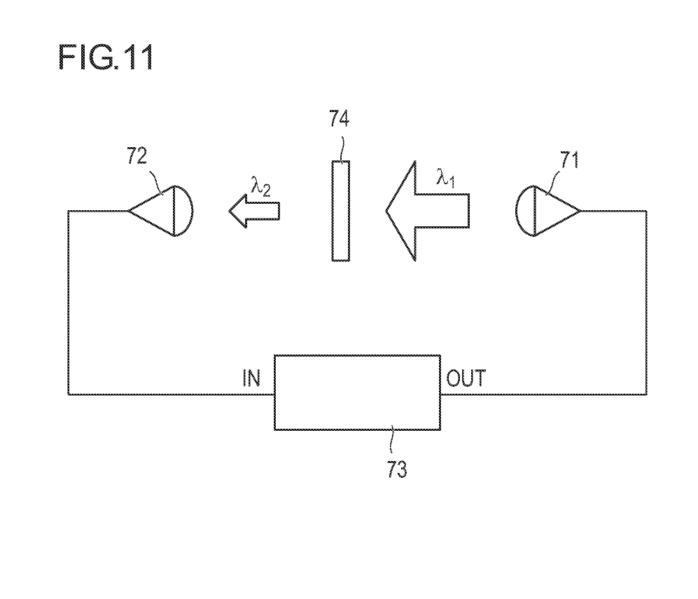

Meanwhile, as a method for evaluating the reflection characteristics, the attenuation rate was evaluated according to the following method. FIG. 11 is a schematic diagram illustrating the arrangement of an apparatus for evaluation of attenuation rate. To a couple of the dielectric lens 71 and 72 disposed to face each other as illustrated in FIG. 11, the vector network analyzer (8150B manufactured by HP Company) 73 was connected, and by placing the frequency selective electromagnetic shield member 74 prepared from above between them, evaluation was made based on the attenuation rate (dB) at frequency of 1.90 GHz (wavelength of 158 mm). In the drawing, the incident electromagnetic wave to Sample 74 was expressed as 2 and the transmitted electromagnetic wave from Sample 74 was expressed as λ₂.

### Example 3

### Manufacture of Translucent Antenna Member

A translucent antenna member was manufactured in the same manner as Sample 107 except that the mask pattern was changed to a photomask which was formed to have an opposite (negative) pattern to the rectangular antenna pattern 41 with line width of 2 mm and size of 70 mm×130 mm illustrated in FIG. 4. The translucent antenna member can be used for a contactless IC card or a wireless tag.

### Example 4

### Manufacture of Electrode Pattern for Translucent Touch Panel

The electrode patterns (translucent conductive patterned members) 5-1 and 5-2 for a translucent touch panel were manufactured in the same manner as Sample 107 except that the mask pattern was changed such that two pieces of a transparent electrode for a touch panel, 5-1 and 5-2 illustrated in FIGS. 5 to 7, could be formed. Two pieces of the electrode pattern for translucent touch panel were overlapped with each other to manufacture a touch panel of simple type. The visibility was good and touch durability was also good.

The present application is based on Japanese Patent Application No. 2012-094984 which has been filed on Apr. 18, 2012, and the disclosure is herein incorporated by reference in its entirety.

### REFERENCE SIGNS LIST

1-1 FIRST TRANSPARENT ELECTRODE FOR TOUCH PANEL,
1-2 SECOND TRANSPARENT ELECTRODE FOR TOUCH PANEL,
3-1 FIRST NITROGEN-CONTAINING LAYER,
3-2 SECOND NITROGEN-CONTAINING LAYER
5-1 FIRST ELECTRODE LAYER,
5-2 SECOND ELECTRODE LAYER,
5x1, 5x2, . . . EACH x ELECTRODE PATTERN,
5y1, 5y2, . . . EACH y ELECTRODE PATTERN,
11 TRANSLUCENT CONDUCTIVE PATTERNED MEMBER,
13 SUBSTRATE (HAVING RELEASING PROPERTY),
14 PROTECTIVE LAYER,
15 BASE LAYER,
17 CONDUCTIVE PATTERN PORTION HAVING TRANSLUCENCY,
18 ADHESIVE LAYER,
19 SUBSTRATE BODY,
21 TOUCH PANEL,
23 TRANSPARENT SUBSTRATE,
23 FRONT PLATE,
25 ADHESIVE (LAYER)
29x x WIRE,
29y y WIRE,
41 RECTANGULAR ANTENNA PATTERN,
51 PET SUBSTRATE,
52 CONDUCTIVE PATTERN PORTION HAVING TRANSLUCENCY,
53 SOLID PORTION HAVING TRANSLUCENCY,
61 BASE LAYER OR PET SUBSTRATE (EASY SLIDING LAYER),
63 (CONDUCTIVE) PATTERN PORTION (HAVING TRANSLUCENCY),
71, 72 DIELECTRIC LENS,
73 VECTOR NETWORK ANALYZER,
74 SELECTIVE ELECTROMAGNETIC SHIELD FILM SAMPLE,
λ₁ INCIDENT ELECTROMAGNETIC WAVE,
λ₂ TRANSMITTED ELECTROMAGNETIC WAVE.

1. A translucent conductive patterned member comprising:
a base layer formed by using a compound containing a nitrogen atom; and
a conductive pattern portion having a translucency formed on at least one part of the base layer by using silver or an alloy containing silver as a main component.

2. The translucent conductive patterned member according to claim 1, wherein a film thickness of the conductive pattern portion is 4 nm or more and 9 nm or less.

3. The translucent conductive patterned member according to claim 1, wherein the compound containing a nitrogen atom has a hetero cycle having the nitrogen atom as a hetero atom.

4. The translucent conductive patterned member according to claim 1, wherein the compound containing a nitrogen atom has a group having a pyridine ring.

5. The translucent conductive patterned member according to claim 1, wherein the compound containing a nitrogen atom has a compound represented by the following General Formula (1);
[Chem. 1]
(Ar1)n1-Y1 General Formula (1)
wherein, in General Formula (1), n1 is an integer of 1 or more, Y1 represents a substituent group when n1 is 1 or a simple bonding arm or a linking group of valency of n1 when n1 is 2 or more, Ar1 represents a group represented by the following General Formula (A), and when n1 is 2 more, plural Ar1 may be the same or different from each other, meanwhile, the compound represented by General Formula (1) has, in the molecule, at least two condensed aromatic heterocycles that are formed by condensation of three or more rings 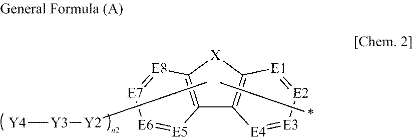
wherein, in General Formula (A), X represents —N(R)—, —O—, —S—, or —Si(R)(R′)—, E1 to E8 represent —C(R1)= or —N═, and R, R′ and R1 represent hydrogen atom, a substituent group, or a linking site to Y1, * represents a linking site to Y1, Y2 represents a simple bonding arm or a divalent linking group, each of Y3 and Y4 represents a group derived from a 5-membered or 6-membered aromatic ring, respectively, in which at least one of Y3 and Y4 represents a group derived from an aromatic heterocycle containing a nitrogen atom as a ring-forming atom, n2 represents an integer of from 1 to 4.

6. The translucent conductive patterned member according to claim 5, wherein the compound represented by General Formula (1) is a compound represented by the following General Formula (2); 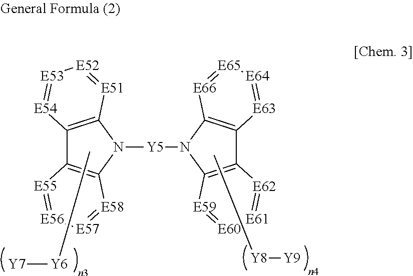
wherein, in General Formula (2), Y5 represents an arylene group, a heteroarylene group, or a divalent linking group including a combination thereof, each of E51 to E66 represents —C(R3)= or —N═ and R3 represents hydrogen atom or a substituent group, each of Y6 to Y9 represents a group derived from an aromatic hydrocarbon ring or a group derived from an aromatic heterocycle, and at least one of Y6 and Y7 and at least one of Y8 and Y9 represent a group derived from an aromatic heterocycle containing an N atom, n3 and n4 represent an integer of from 0 to 4, in which n3+n4 is an integer of 2 or more.

7. The translucent conductive patterned member according to claim 6, wherein the compound represented by General Formula (2) is a compound represented by the following General Formula (3); 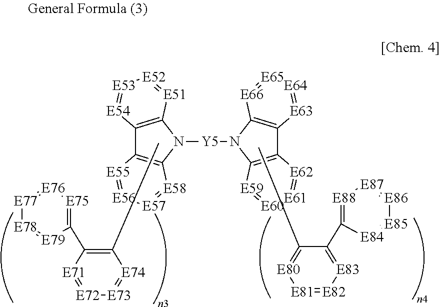
wherein, in General Formula (3), Y5 represents an arylene group, a heteroarylene group, or a divalent linking group including a combination thereof, each of E51 to E66 and E71 to E88 represents —C(R3)= or —N═ and R3 represents hydrogen atom or a substituent group, meanwhile, at least one of E71 to E79 and at least one of E80 to E88 represent —N═, n3 and n4 represent an integer of from 0 to 4, in which n3+n4 is an integer of 2 or more.

8. The translucent conductive patterned member according to claim 1, being formed on a transparent resin film.

9. A method for manufacturing a translucent conductive patterned member comprising a base layer formed by using a compound containing a nitrogen atom and a conductive pattern portion having a translucency formed on at least one part of the base layer by using silver or an alloy containing silver as a main component,
wherein a silver or alloy layer containing silver as a main component is formed on the base layer by a vapor deposition method.

10. A method for manufacturing a translucent conductive patterned member comprising a base layer formed by using a compound containing a nitrogen atom and a conductive pattern portion having a translucency formed on at least one part of the base layer by using silver or an alloy containing silver as a main component,
wherein a silver or alloy layer containing silver as a main component, which is formed on the base layer, is formed as the conductive pattern portion by a vapor deposition method using a mask with formed pattern.

11. A method for manufacturing a translucent conductive patterned member comprising a base layer formed by using a compound containing a nitrogen atom and a conductive pattern portion having a translucency formed on at least one part of the base layer by using silver or an alloy containing silver as a main component,
wherein a silver or alloy layer containing silver as a main component is formed on the base layer, a silver removing liquid is pattern-printed on a region other than the conductive pattern portion, and a conductive pattern portion is formed by subsequently washing.

12. A translucent electromagnetic shield member obtained by using the translucent conductive patterned member according to claim 1.

13. A translucent frequency selective electromagnetic shield member obtained by using the translucent conductive patterned member according to claim 1.

14. A translucent antenna member obtained by using the translucent conductive patterned member according to claim 1.
